(19) United States
(12) Patent Application Publication
(10) Pub. No.: US 2026/0063990 A1
(43) Pub. Date: Mar. 5, 2026

(54) RESIST COMPOSITION AND PATTERN FORMATION METHOD USING THE SAME

(71) Applicant: Samsung Electronics Co., Ltd., Suwon-si (KR)

(72) Inventors: Haengdeog KOH, Suwon-si (KR); Sunyoung LEE, Suwon-si (KR); Jiyoun LEE, Suwon-si (KR); Jinwon JEON, Suwon-si (KR); Jungha CHAE, Suwon-si (KR)

(73) Assignee: Samsung Electronics Co., Ltd., Suwon-si (KR)

(21) Appl. No.: 19/062,708

(22) Filed: Feb. 25, 2025

(30) Foreign Application Priority Data
Sep. 3, 2024 (KR) 10-2024-0119557

(51) Int. Cl. G03F 7/004; G03F 7/32

(52) U.S. Cl. CPC G03F 7/0042; G03F 7/0045; G03F 7/0048; G03F 7/325

(57) ABSTRACT

Provided are a resist composition including an organometallic compound represented by Formula 1 and an additive represented by Formula 2, and a pattern formation method using the same:

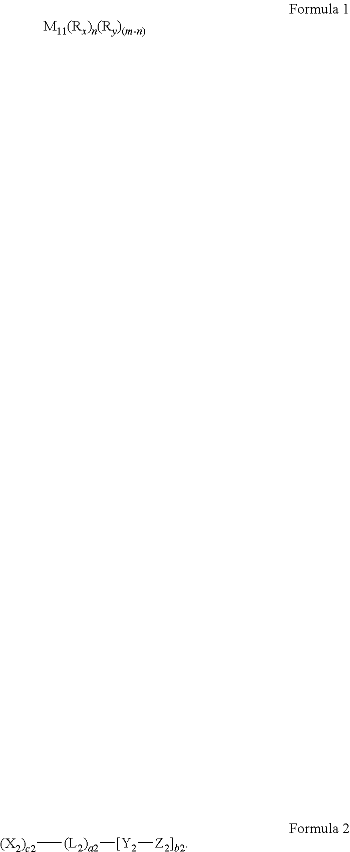

Descriptions of M₁₁, Rₓ, R_{y}, n, m, X₂, Y₂, Z₂, L₂, a2, b2, and c2 in Formulae 1 and 2 are provided in the specification.

### CROSS-REFERENCE TO RELATED APPLICATION

This application is based on and claims priority under 35 USC § 119 to Korean Patent Application No. 10-2024-0119557, filed on Sep. 3, 2024, in the Korean Intellectual Property Office, the disclosure of which is incorporated by reference herein in its entirety.

### BACKGROUND

### 1. Field

The inventive concepts relate to resist compositions and pattern formation methods using the same.

### 2. Description of the Related Art

In semiconductor manufacturing, resists having physical properties that change in response to light are being used to form fine patterns. Among these resists, chemically amplified resists have been widely used. In the case of chemically amplified resists, an acid formed through a reaction between light (e.g., incident light having a particular intensity and/or wavelength) and a photoacid generator reacts with a base resin again to change the solubility of the base resin with respect to a developer, thereby enabling patterning.

### SUMMARY

Some example embodiments provide a resist composition which has improved storage stability, wherein the resist composition is configured to change one or more properties even with low doses of exposure to incident light (e.g., exposure to a small amount and/or intensity of light), where the resist composition is configured to provide patterns of improved resolution. Some example embodiments provide a pattern formation method using the resist composition. Such a resist composition may have a composition which has improved storage stability, wherein the resist composition is configured to change one or more physical properties even by exposure to incident light (e.g., high-energy rays), in order to overcome limitations of chemically amplified resists which may cause a formed acid to diffuse to an unexposed region, such that the resist composition reduces, minimizes, or prevents the likelihood of a reduction in uniformity of patterns or an increase in surface roughness based on avoiding such formed acid diffusion, while simultaneously providing improved resist composition chemical stability (and thereby reduced, minimized, or prevented risk of chemical deterioration) in normal usage environments at room temperature and/or while simultaneously changing physical properties even by exposure to a small amount (e.g., small intensity) of incident light (e.g., high-energy rays).

Additional aspects will be set forth in part in the description which follows and, in part, will be apparent from the description, or may be learned by practice of the presented embodiments of the inventive concepts.

According to some example embodiments of the inventive concepts, a resist composition includes an organometallic compound represented by Formula 1 and an additive represented by Formula 2:

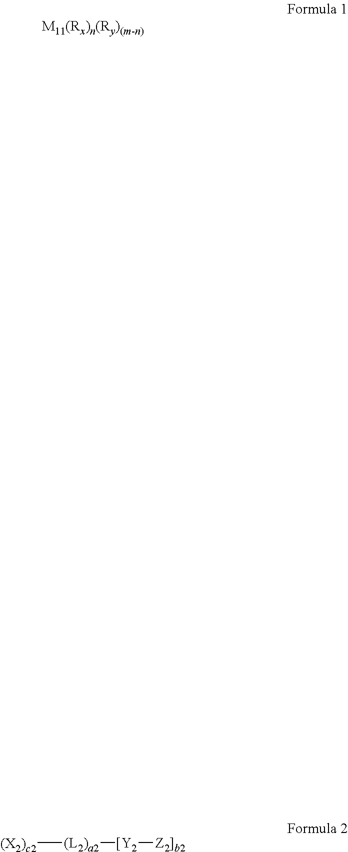

wherein, in Formulae 1 and 2,
M₁₁ may be indium (In), tin (Sn), antimony (Sb), tellurium (Te), thallium (Tl), lead (Pb), bismuth (Bi), or polonium (Po),
Rₓ may be *—X₁—Y₁,
R_{y} may be *-(L₁)ₐ₁-(R₁)_{b1},
n may be an integer from 1 to 6,
m may be an integer from 1 to 6,
m-n may be 0 or more,
Formula 1 may optionally include a plurality of Rₓ based on n being greater than 1, the plurality of Rₓ identical to or different from each other,
Formula 1 may optionally include a plurality of R_{y} based on m-n being greater than 1, the plurality of R_{y} identical to or different from each other,
X₁ may be O, OC(═O), C(═O)O, OS(═O), S(═O)O, OS(═O)₂, S(═O)₂O, S, SC(═O), or C(═O)S,
Y₁ may be hydrogen, deuterium, or a linear, branched, or cyclic C₁-C₃₀ monovalent hydrocarbon group that optionally includes a heteroatom,
L₁ may be a linear, branched, or cyclic C₁-C₃₀ divalent hydrocarbon group that optionally includes a heteroatom,
a1 may be an integer from 0 to 4,
R₁ may be a linear, branched, or cyclic C₁-C₃₀ monovalent hydrocarbon group that optionally includes a heteroatom,
b1 may be an integer from 1 to 4, wherein Formula 1 may optionally include a plurality of R₁ based on b1 being greater than 1, two adjacent groups among the plurality of R₁ optionally bonded to each other to form a ring,
X₂ may be OH, SH, C(═O)OH, S(═O)OH, S(═O)₂OH, or P(═O)(OH)₂,
c2 may be an integer from 1 to 4,
each L₂ may independently be a linear, branched, or cyclic C₁-C₃₀ divalent hydrocarbon group that optionally includes a heteroatom,
a2 may be an integer from 0 to 4,
Y₂—Z₂ may be a photo-reactive unit,
b2 may be an integer from 1 to 4, and
* is a bonding site to a neighboring atom.

In Formula 1, M₁₁ may be Sn, Sb, Te, or Bi.

In Formula 1, X₁ may be O, OC(═O), C(═O)O, S, SC(═O), or C(═O)S, and Y₁ may be selected from: hydrogen, deuterium, a C₁-C₃₀ alkyl group, a C₁-C₃₀ halogenated alkyl group, a C₁-C₃₀ alkoxy group, a C₁-C₃₀ alkylthio group, a C₁-C₃₀ halogenated alkoxy group, a C₁-C₃₀ halogenated alkylthio group, a C₃-C₃₀ cycloalkyl group, a C₃-C₃₀ cycloalkoxy group, a C₃-C₃₀ cycloalkylthio group, a C₃-C₃₀ heterocycloalkyl group, a C₂-C₃₀ alkenyl group, a C₃-C₃₀ cycloalkenyl group, a C₃-C₃₀ heterocycloalkenyl group, a C₂-C₃₀ alkynyl group, a C₆-C₃₀ aryl group, a C₆-C₃₀ aryloxy group, a C₆-C₃₀ arylthio group, a C₇-C₃₀ arylalkyl group, a C₁-C₃₀ heteroaryl group, a C₁-C₃₀ heteroaryloxy group, a C₁-C₃₀ heteroarylthio group, and a C₂-C₃₀ heteroarylalkyl group. Each of the C₁-C₃₀ alkyl group, the C₁-C₃₀ halogenated alkyl group, the C₁-C₃₀ alkoxy group, the C₁-C₃₀ alkylthio group, the C₁-C₃₀ halogenated alkoxy group, the C₁-C₃₀ halogenated alkylthio group, the C₃-C₃₀ cycloalkyl group, the C₃-C₃₀ cycloalkoxy group, the C₃-C₃₀ cycloalkylthio group, the C₃-C₃₀ heterocycloalkyl group, the C₂-C₃₀ alkenyl group, the C₃-C₃₀ cycloalkenyl group, the C₃-C₃₀ heterocycloalkenyl group, the C₂-C₃₀ alkynyl group, the C₆-C₃₀ aryl group, the C₆-C₃₀ aryloxy group, the C₆-C₃₀ arylthio group, the C₇-C₃₀ arylalkyl group, the C₁-C₃₀ heteroaryl group, the C₁-C₃₀ heteroaryloxy group, the C₁-C₃₀ heteroarylthio group, and the C₂-C₃₀ heteroarylalkyl group may be unsubstituted or substituted with deuterium, a halogen, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or any combination thereof.

In Formula 1, L₁ may be a single bond, a substituted or unsubstituted C₁-C₃₀ alkylene group, a substituted or unsubstituted C₃-C₃₀ cycloalkylene group, a substituted or unsubstituted C₃-C₃₀ heterocycloalkylene group, a substituted or unsubstituted C₂-C₃₀ alkenylene group, a substituted or unsubstituted C₃-C₃₀ cycloalkenylene group, a substituted or unsubstituted C₃-C₃₀ heterocycloalkenylene group, a substituted or unsubstituted C₆-C₃₀ arylene group, or a substituted or unsubstituted C₁-C₃₀ heteroarylene group, a1 may be 0, 1, or 2, and R₁ may be selected from a C₁-C₃₀ alkyl group, a C₃-C₃₀ cycloalkyl group, a C₃-C₃₀ heterocycloalkyl group, a C₂-C₃₀ alkenyl group, a C₃-C₃₀ cycloalkenyl group, a C₃-C₃₀ heterocycloalkenyl group, a C₂-C₃₀ alkynyl group, a C₆-C₃₀ aryl group, a C₇-C₃₀ arylalkyl group, a C₁-C₃₀ heteroaryl group, and a C₂-C₃₀ heteroarylalkyl group. Each of the C₁-C₃₀ alkyl group, the C₃-C₃₀ cycloalkyl group, the C₃-C₃₀ heterocycloalkyl group, the C₂-C₃₀ alkenyl group, the C₃-C₃₀ cycloalkenyl group, the C₃-C₃₀ heterocycloalkenyl group, the C₂-C₃₀ alkynyl group, the C₆-C₃₀ aryl group, the C₇-C₃₀ arylalkyl group, the C₁-C₃₀ heteroaryl group, and the C₂-C₃₀ heteroarylalkyl group may be unsubstituted or substituted with deuterium, a halogen, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or any combination thereof.

The organometallic compound represented by Formula 1 may be selected from Group I:

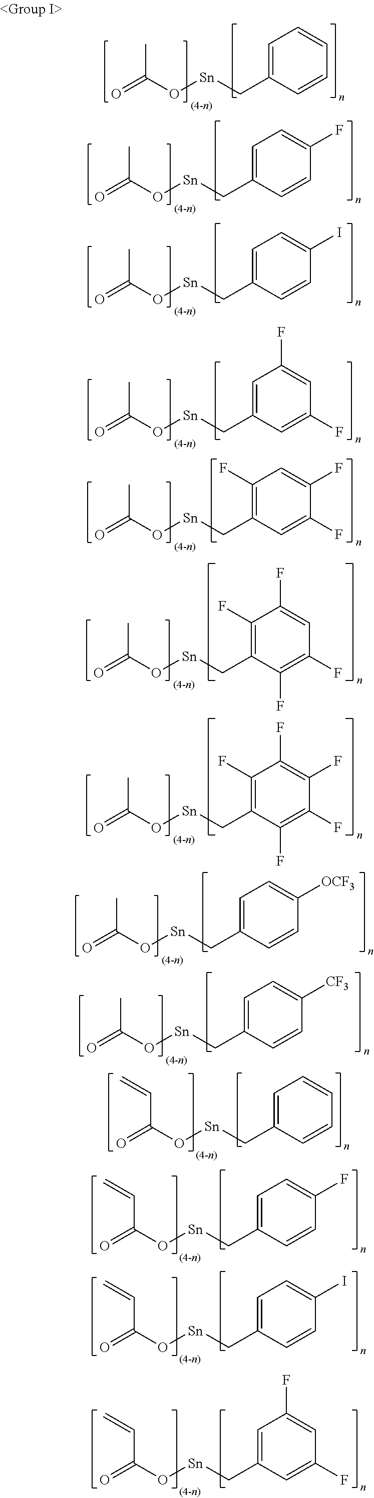

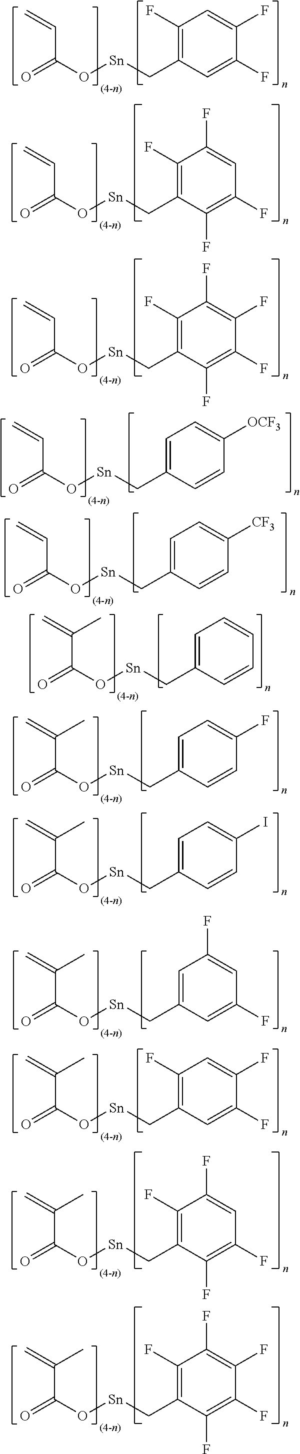

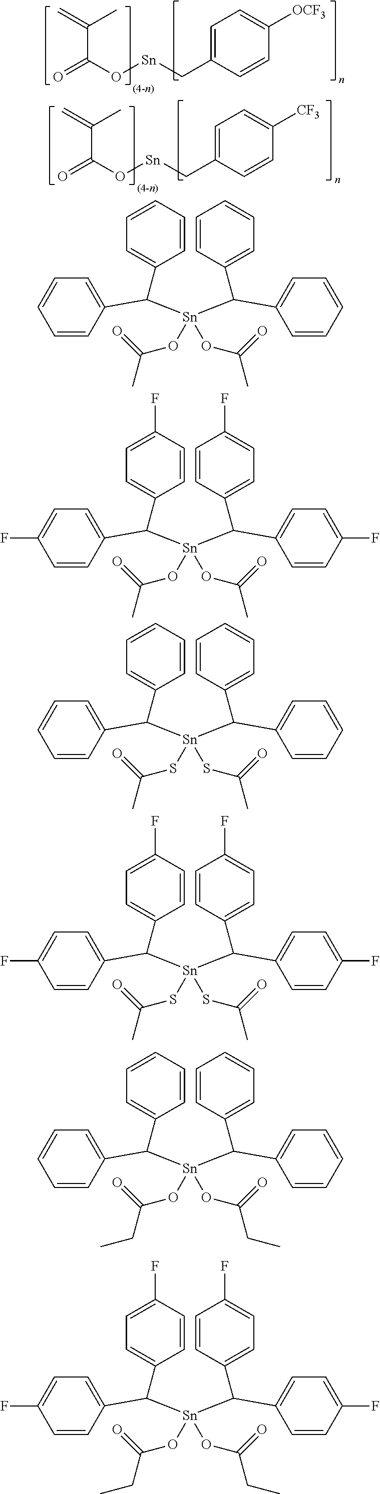

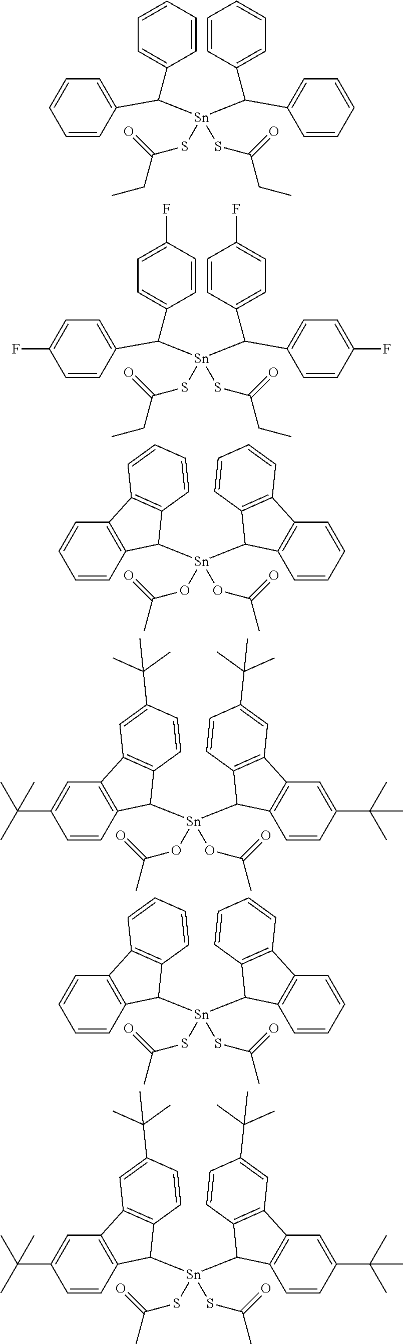

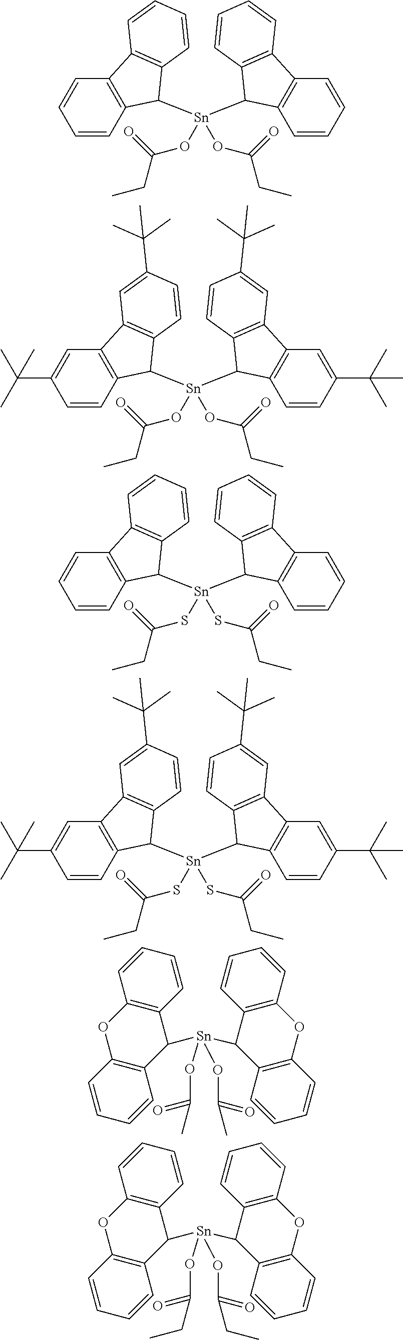

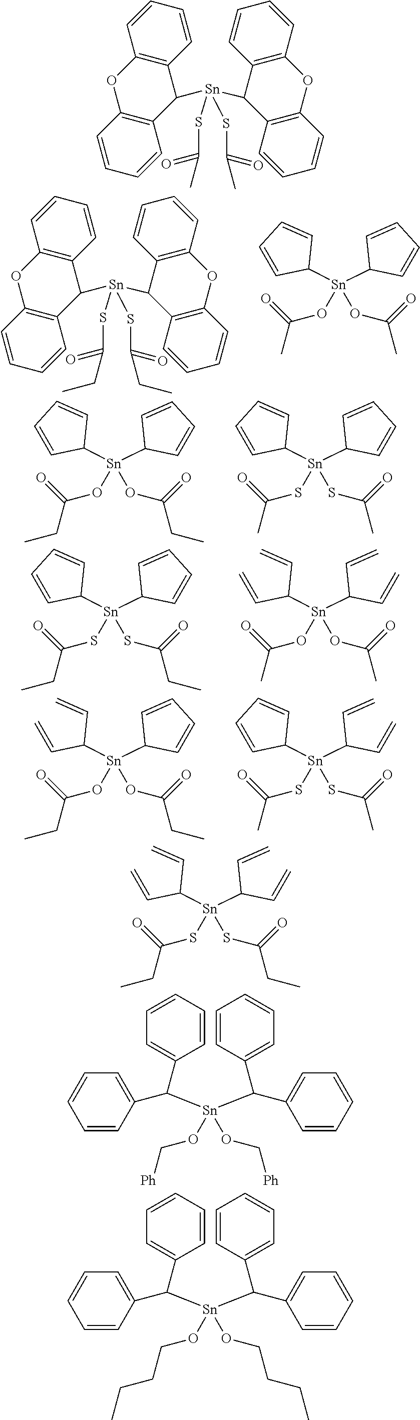

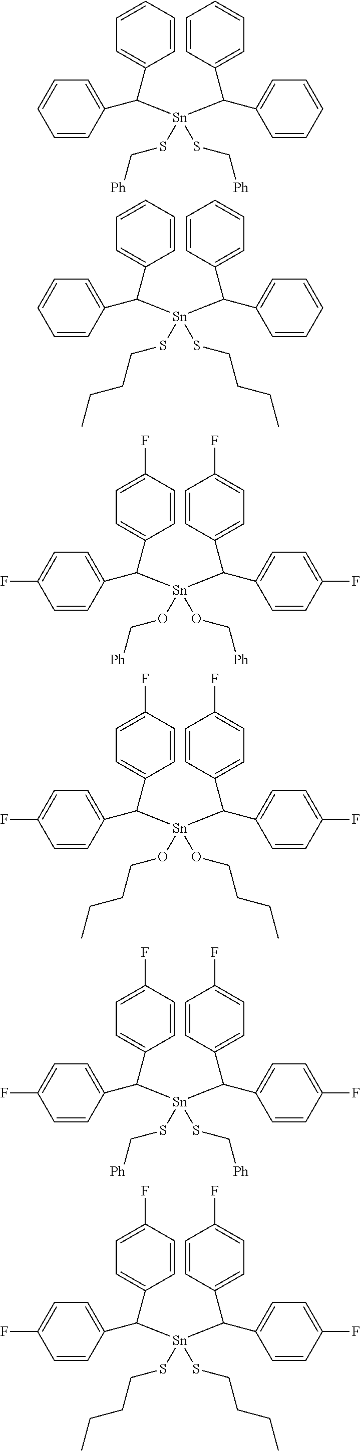

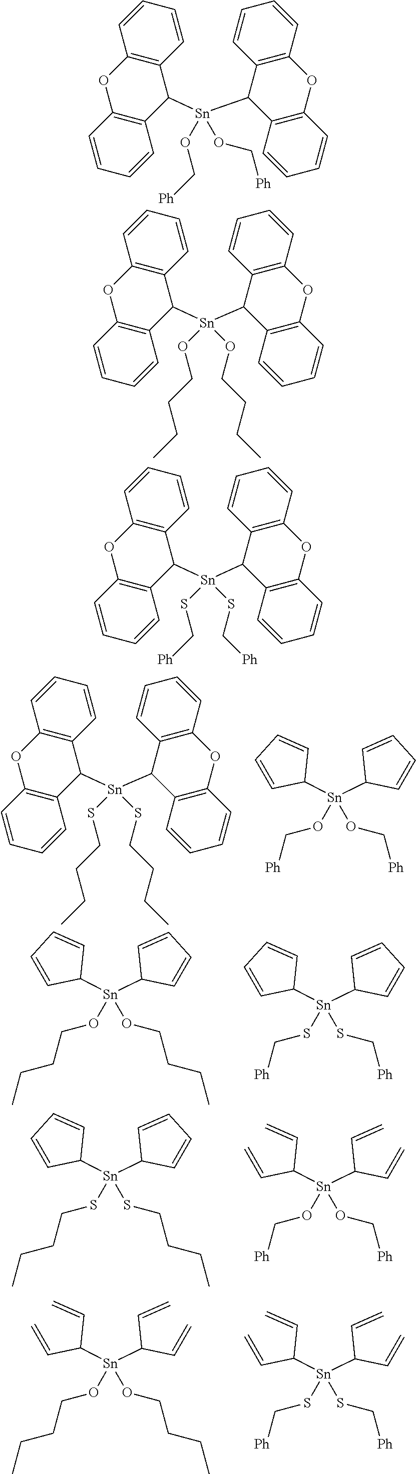

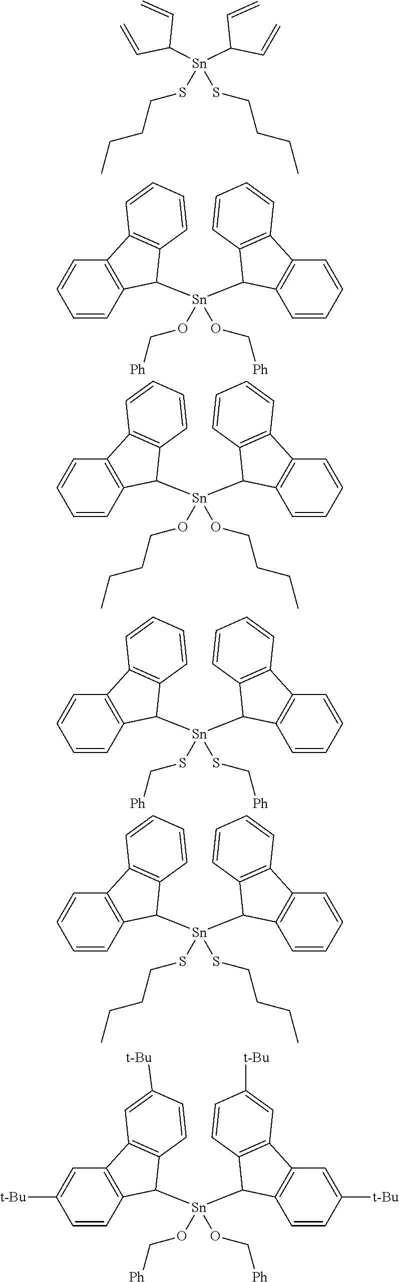

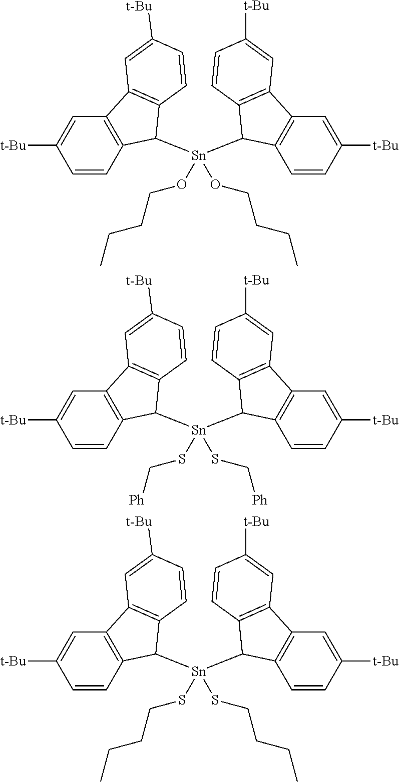

wherein n in Group I is an integer from 0 to 3.

In Formula 2, X₂ may be OH or C(═O)OH.

In Formula 2, (L₂)ₐ₂ may be represented by any one of Formulae 5-1 to 5-7:

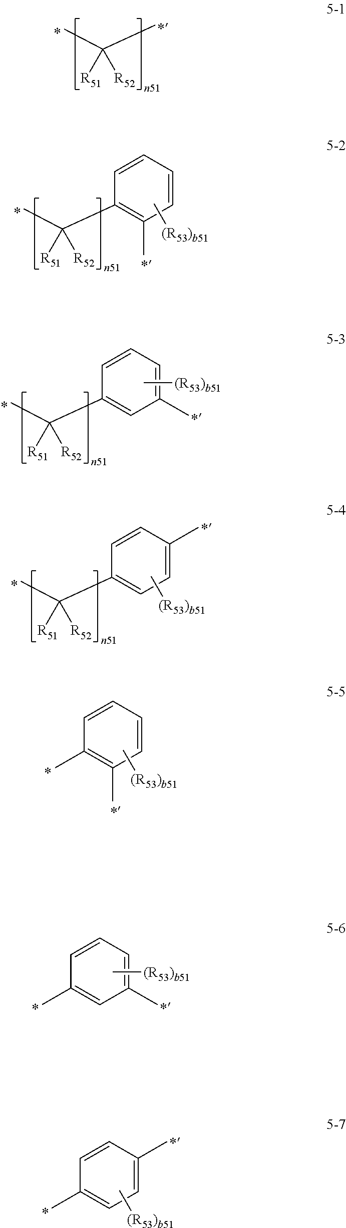

wherein, in Formulae 5-1 to 5-7, R₅₁ to R₅₃ may each independently be hydrogen, deuterium, a halogen, a hydroxyl group, a cyano group, a C₁-C₄ alkyl group, or a C₁-C₄ halogenated alkyl group, b51 may be an integer from 1 to 4, n51 may be an integer from 1 to 4, and * and *′ each indicate a binding site to a neighboring atom of Formula 2.

In Formula 2, Y₂ may be OC(═O), C(═O)O, OS(═O)₂, or S(═O)₂O, Z₂ may be *—C(R₂)(R₃)(R₄), *—C(R₂)═N(R₃), *—N═C(R₂)(R₃), or *—N(R₂)(R₃), R₂ to R₄ may each independently be hydrogen, deuterium, a halogen, a cyano group, a nitro group, a hydroxyl group, —C(═O)R₅, —C(R₅)═NR₆, —ORS, —S(═O)R₅, —S(═O)₂R₅, —S(═O)₂OR₅, a substituted or unsubstituted C₁-C₃₀ alkyl group, a substituted or unsubstituted C₁-C₃₀ halogenated alkyl group, a substituted or unsubstituted C₁-C₃₀ alkoxy group, a substituted or unsubstituted C₁-C₃₀ alkylthio group, a substituted or unsubstituted C₁-C₃₀ halogenated alkoxy group, a substituted or unsubstituted C₁-C₃₀ halogenated alkylthio group, a substituted or unsubstituted C₃-C₃₀ cycloalkyl group, a substituted or unsubstituted C₃-C₃₀ cycloalkoxy group, a substituted or unsubstituted C₃-C₃₀ cycloalkylthio group, a substituted or unsubstituted C₃-C₃₀ heterocycloalkyl group, a substituted or unsubstituted C₃-C₃₀ heterocycloalkoxy group, a substituted or unsubstituted C₃-C₃₀ heterocycloalkylthio group, a substituted or unsubstituted C₂-C₃₀ alkenyl group, a substituted or unsubstituted C₂-C₃₀ alkenyloxy group, a substituted or unsubstituted C₂-C₃₀ alkenylthio group, a substituted or unsubstituted C₃-C₃₀ cycloalkenyl group, a substituted or unsubstituted C₃-C₃₀ cycloalkenyloxy group, a substituted or unsubstituted C₃-C₃₀ cycloalkenylthio group, a substituted or unsubstituted C₃-C₃₀ heterocycloalkenyl group, a substituted or unsubstituted C₃-C₃₀ heterocycloalkenyloxy group, a substituted or unsubstituted C₃-C₃₀ heterocycloalkenylthio group, a substituted or unsubstituted C₂-C₃₀ alkynyl group, a substituted or unsubstituted C₂-C₃₀ alkynyloxy group, a substituted or unsubstituted C₂-C₃₀ alkynylthio group, a substituted or unsubstituted C₆-C₃₀ aryl group, a substituted or unsubstituted C₆-C₃₀ aryloxy group, a substituted or unsubstituted C₆-C₃₀ arylthio group, a substituted or unsubstituted C₁-C₃₀ heteroaryl group, a substituted or unsubstituted C₁-C₃₀ heteroaryloxy group, or a substituted or unsubstituted C₁-C₃₀ heteroarylthio group, R₅ and R₆ may each independently be hydrogen, deuterium, a hydroxyl group, a substituted or unsubstituted C₁-C₃₀ alkyl group, a substituted or unsubstituted C₁-C₃₀ halogenated alkyl group, a substituted or unsubstituted C₁-C₃₀ alkoxy group, a substituted or unsubstituted C₁-C₃₀ alkylthio group, a substituted or unsubstituted C₁-C₃₀ halogenated alkoxy group, a substituted or unsubstituted C₁-C₃₀ halogenated alkylthio group, a substituted or unsubstituted C₃-C₃₀ cycloalkyl group, a substituted or unsubstituted C₃-C₃₀ cycloalkoxy group, a substituted or unsubstituted C₃-C₃₀ cycloalkylthio group, a substituted or unsubstituted C₃-C₃₀ heterocycloalkyl group, a substituted or unsubstituted C₃-C₃₀ heterocycloalkoxy group, a substituted or unsubstituted C₃-C₃₀ heterocycloalkylthio group, substituted or unsubstituted C₂-C₃₀ alkenyl group, a substituted or unsubstituted C₂-C₃₀ alkenyloxy group, a substituted or unsubstituted C₂-C₃₀ alkenylthio group, a substituted or unsubstituted C₃-C₃₀ cycloalkenyl group, a substituted or unsubstituted C₃-C₃₀ cycloalkenyloxy group, a substituted or unsubstituted C₃-C₃₀ cycloalkenylthio group, a substituted or unsubstituted C₃-C₃₀ heterocycloalkenyl group, a substituted or unsubstituted C₃-C₃₀ heterocycloalkenyloxy group, a substituted or unsubstituted C₃-C₃₀ heterocycloalkenylthio group, a substituted or unsubstituted C₂-C₃₀ alkynyl group, a substituted or unsubstituted C₂-C₃₀ alkynyloxy group, a substituted or unsubstituted C₂-C₃₀ alkynylthio group, a substituted or unsubstituted C₆-C₃₀ aryl group, a substituted or unsubstituted C₆-C₃₀ aryloxy group, a substituted or unsubstituted C₆-C₃₀ arylthio group, a substituted or unsubstituted C₁-C₃₀ heteroaryl group, a substituted or unsubstituted C₁-C₃₀ heteroaryloxy group, or a substituted or unsubstituted C₁-C₃₀ heteroarylthio group, and * is a bonding site to a neighboring atom of Formula 2.

The additive represented by Formula 2 may be selected from Group II:

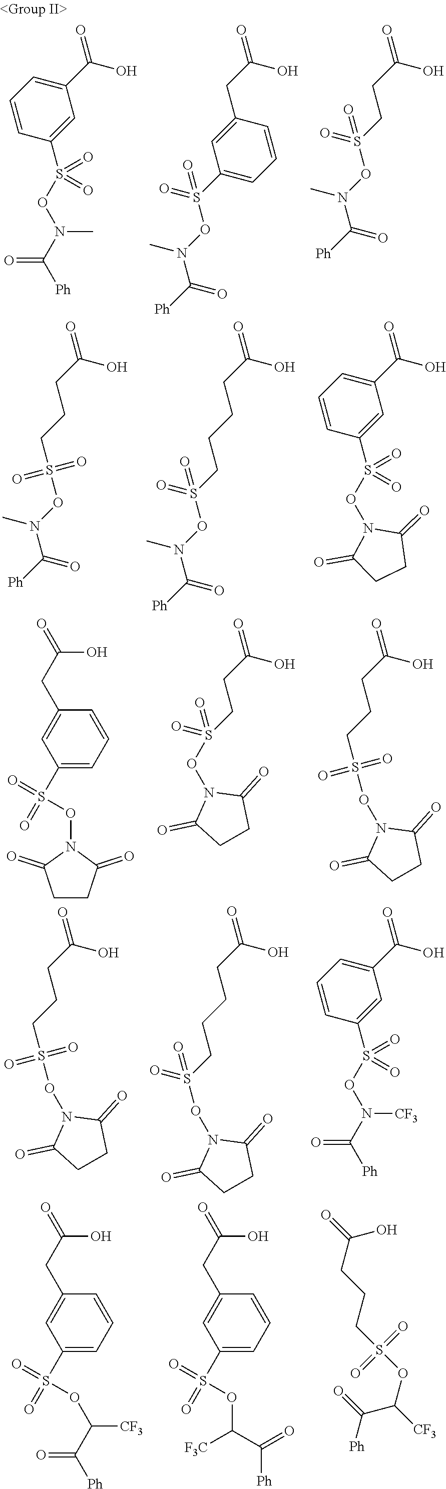

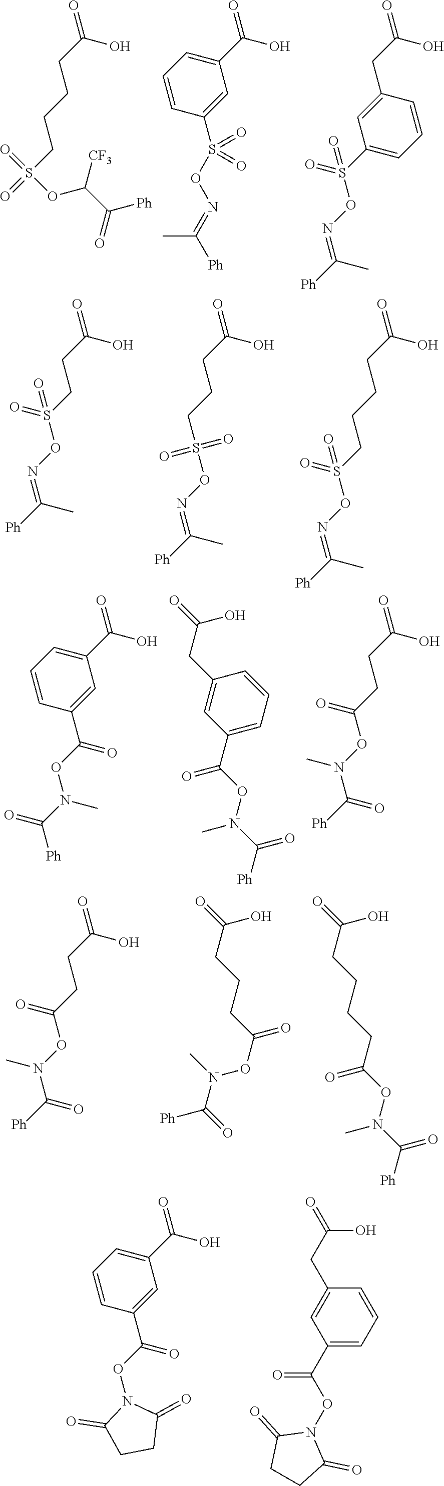

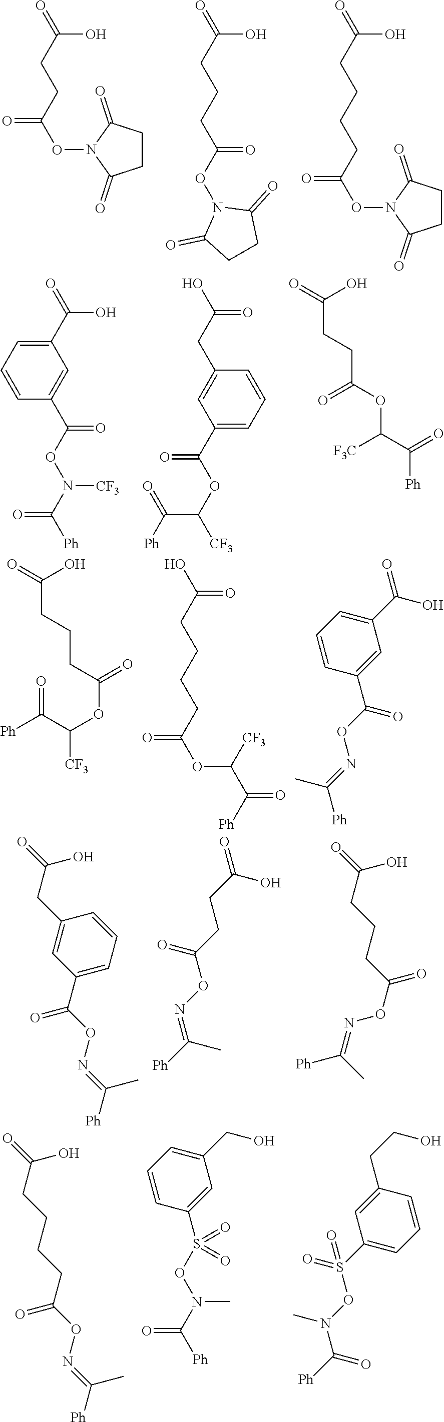

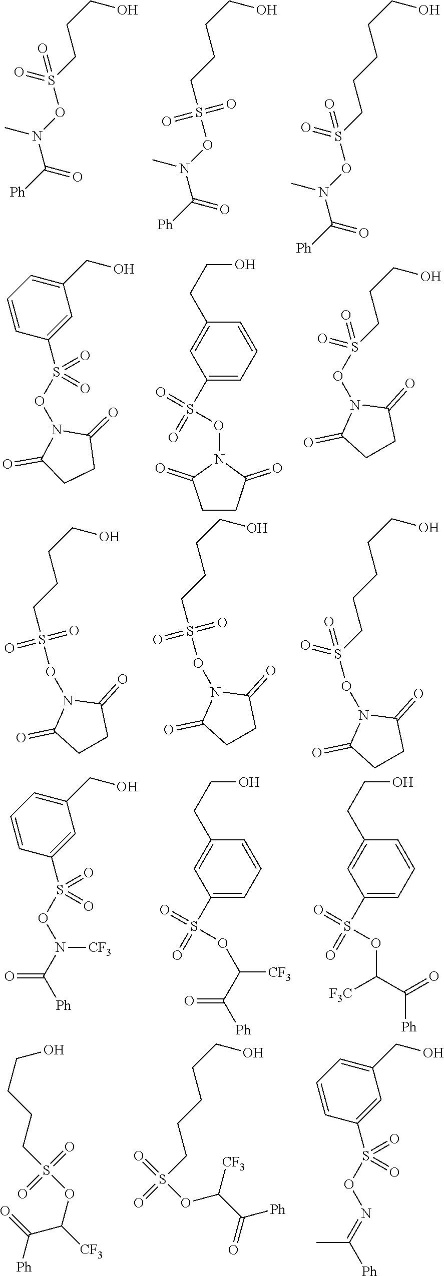

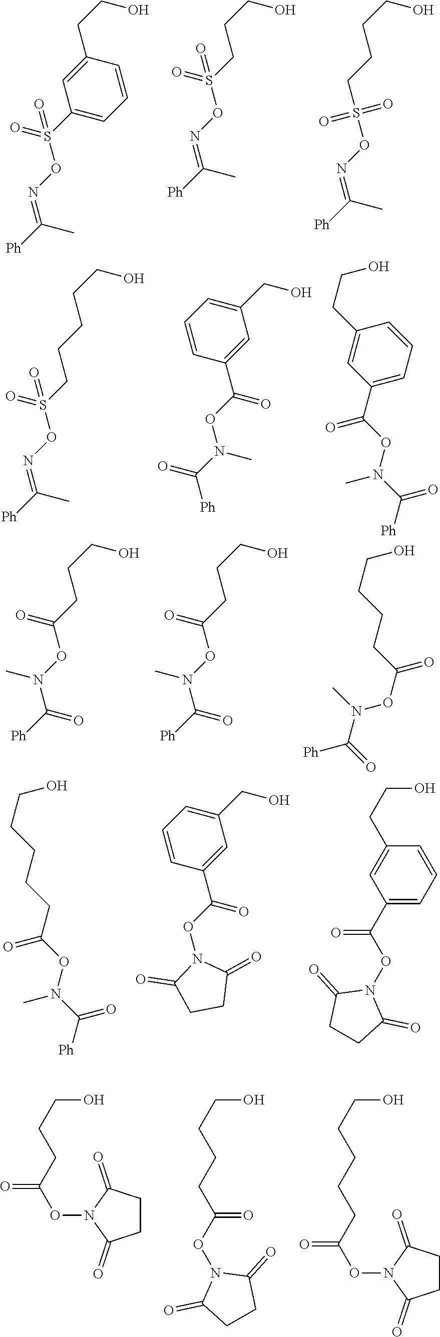

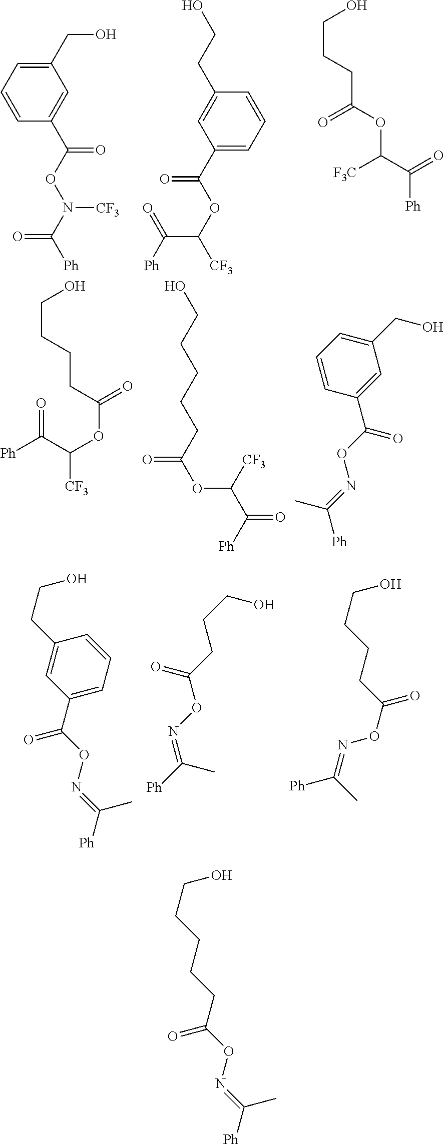

wherein Ph in Group II is a phenyl group.

The additive may be included in the resist composition in an amount of about 0.1 parts by weight to about 100,000 parts by weight, based on 100 parts by weight of the organometallic compound.

The resist composition may further include a solvent.

The solvent may be a polar aprotic solvent.

The solvent may be selected from ketone-based solvents, ester-based solvents, and any combination thereof.

The solvent may be selected from linear ketone solvents, cyclic ketone solvents, polyhydric alcohol-containing ethercarboxylate solvents, lactone solvents, acetate ester solvents, and any combination thereof.

The solvent may be methyl ethyl ketone, cyclopentanone, cyclohexanone, cycloheptanone, propylene glycol monomethyl ether acetate, γ-butyrolactone, δ-valerolactone, n-butyl acetate, or any combination thereof.

According to some example embodiments, a pattern formation method may include forming a resist film by applying the resist composition of claim 1 onto a substrate; exposing at least a portion of the resist film to high-energy rays to form an exposed resist film; and developing the exposed resist film based on using a developer.

The exposing may be performed based on irradiating at least one of ultraviolet rays, deep ultraviolet rays (DUV), extreme ultraviolet rays (EUV), X-rays, γ-rays, electron beams (EBs), or α-rays.

Based on the exposing at least the portion of the resist film, the exposed resist film may include an exposed portion and an unexposed portion. A difference between a water contact angle of the unexposed portion and a water contact angle of the exposed portion may be 25° or more.

Based on the exposing at least the portion of the resist film, the exposed resist film may include an exposed portion and an unexposed portion. The developer may include distilled water, an alkaline developer, or any combination thereof. The developing the exposed resist film may include removing the exposed portion.

Based on the exposing at least the portion of the resist film, the exposed resist film may include an exposed portion and an unexposed portion. The developer may include an organic solvent. The developing the exposed resist film may include removing the unexposed portion.

### BRIEF DESCRIPTION OF THE DRAWINGS

The above and other aspects, features, and advantages of certain example embodiments of the inventive concepts will be more apparent from the following description taken in conjunction with the accompanying drawings, in which:

FIG. 1 is a flowchart illustrating a pattern formation method according to some example embodiments;

FIGS. 2A, 2B, and 2C are side cross-sectional views showing a pattern formation method according to some example embodiments;

FIGS. 3A, 3B, 3C, 3D, and 3E are side cross-sectional views illustrating a method of forming a patterned structure, according to some example embodiments;

FIGS. 4A, 4B, 4C, 4D, and 4E are side cross-sectional views showing a method of forming a semiconductor device, according to some example embodiments;

FIG. 5 shows the results of Fourier transform infrared spectroscopy (FT-IR) analysis of compound M1, compound A1, a mixture of compound M1 and compound A1, and compound X1; and

FIGS. 6A, 6B, 6C, and 6D and FIG. 7 show changes in film thickness after development according to dose of Examples 1-1, 1-2, 2-1, and Comparative Examples 1-1 and 1-2, respectively.

### DETAILED DESCRIPTION

Reference will now be made in detail to some example embodiments, some of which are illustrated in the accompanying drawings, wherein like reference numerals refer to like elements throughout. In this regard, some example embodiments may have different forms and should not be construed as being limited to the descriptions set forth herein. Accordingly, some example embodiments are merely described below, by referring to the drawings, to explain aspects thereof. As used herein, the term “and/or” includes any and all combinations of one or more of the associated listed items. Expressions such as “at least one of,” when preceding a list of elements, modify the entire list of elements and do not modify the individual elements of the list.

The inventive concepts may have various modified versions thereof and could be embodied in several different forms. Specific example embodiments will be illustrated in the drawings and described in detail in the specification. However, it should be understood that this is not intended to limit the inventive concepts to the particular forms disclosed, but on the contrary, the intention is to cover all modifications, equivalents, and alternatives falling within the spirit and scope of the inventive concepts. In describing the inventive concepts, when it is determined that the specific description of the known related art unnecessarily obscures the gist of the inventive concepts, the detailed description thereof will be omitted.

The use of the term “the” and similar demonstratives may correspond to both the singular and the plural. Operations constituting methods may be performed in any suitable order unless otherwise indicated herein or otherwise clearly contradicted by context, and are not necessarily limited to the stated order.

The use of all illustrations or illustrative terms in some example embodiments is simply to describe the technical ideas in detail, and the scope of the present inventive concepts is not limited by the illustrations or illustrative terms unless they are limited by claims.

Regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

Although the terms “first,” “second,” “third,” and the like may be used herein to describe various elements, these terms are only used to distinguish one element from another and the order, type, or the like of the elements are not limited thereby.

In this specification, when a portion of a layer, film, region, plate, or the like is described as being “on” or “above” another portion, it may include not only the meaning of “immediately on/under/to the left/to the right in a contact manner,” but also the meaning of “on/under/to the left/to the right in a non-contact manner.”

An expression used in the singular encompasses the expression of the plural, unless it has a clearly different meaning in the context. Unless explicitly described to the contrary, it is to be understood that the terms such as “including” and “having” are intended to indicate the existence of the features, numbers, steps, actions, components, parts, ingredients, materials, or combinations thereof disclosed in the specification and are not intended to preclude the possibility that one or more other features, numbers, steps, actions, components, parts, ingredients, materials, or combinations thereof may exist or may be added.

Whenever a range of values is recited, the range includes all values that fall within the range as if expressly written, and the range further includes the boundaries of the range. Thus, a range of “X to Y” includes all values between X and Y and also includes X and Y.

As used herein, “Cₓ-C_{y}” or “Cx to Cy” means that a number (e.g., quantity) of carbons constituting a substituent is x to y, wherein x and y may each be any natural number. For example, “C₁-C₆” and “C1 to C6” means that a number of carbons constituting the substituent is 1 to 6, and “C₆-C₂₀” and C6 to C20” means that a number of carbons constituting the substituent is 6 to 20.“ ” “ ” “ ”

The term “monovalent hydrocarbon group” used herein refers to a monovalent residue derived from an organic compound including carbon and hydrogen or a derivative thereof, and specific examples thereof include a linear or branched alkyl group (for example, a methyl group, an ethyl group, a propyl group, an isopropyl group, a butyl group, an isobutyl group, a sec-butyl group, a tert-butyl group, a pentyl group, a neopentyl group, a hexyl group, a heptyl group, a 2-ethylhexyl group, and a nonyl group); a monovalent saturated cycloaliphatic hydrocarbon group (a cycloalkyl group) (for example, a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a 1-adamantyl group, a 2-adamantyl group, a 1-adamantylmethyl group, a norbornyl group, a norbornylmethyl group, a tricyclodecanyl group, a tetracyclododecanyl group, a tetracyclododecanylmethyl group, and a dicyclohexylmethyl group); a monovalent unsaturated aliphatic hydrocarbon group (an alkenyl group or an alkynyl group) (for example, an allyl group); a monovalent unsaturated cycloaliphatic hydrocarbon group (a cycloalkenyl group) (for example, 3-cyclohexenyl); an aryl group (for example, a phenyl group, a 1-naphthyl group, and a 2-naphthyl group); an arylalkyl group (for example, a benzyl group and a diphenylmethyl group); a heteroatom-including monovalent hydrocarbon group (for example, a tetrahydrofuranyl group, a methoxymethyl group, an ethoxymethyl group, a methylthiomethyl group, an acetamidemethyl group, a trifluoroethyl group, a (2-methoxyethoxy)methyl group, an acetoxymethyl group, a 2-carboxy-1-cyclohexyl group, a 2-oxopropyl group, a 4-oxo-1-adamantyl group, and a 3-oxocyclohexyl group), or a combination thereof. Additionally, some of hydrogens in these groups may be substituted with a moiety including a heteroatom (e.g., one or more heteroatoms) such as oxygen, sulfur, nitrogen, phosphorous or halogen atoms, or some of carbons in these groups may be replaced by a moiety including a heteroatom (e.g., one or more heteroatoms) such as oxygen, sulfur, nitrogen or phosphorous, and thus these groups may include a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylate anhydride moiety, or the like.

The term “divalent hydrocarbon group” as used herein is a divalent residue and refers to a system in which any one hydrogen atom of the monovalent hydrocarbon group is replaced by a binding site to an adjacent atom. The divalent hydrocarbon group may include, for example, a linear or branched alkylene group, a cycloalkylene group, an alkenylene group, an alkynylene group, a cycloalkylene group, an arylene group, a group in which some carbon atoms thereof are replaced with a heteroatom, and the like.

The term “alkyl group” as used herein refers to a linear or branched saturated aliphatic monovalent hydrocarbon group, and examples thereof are a methyl group, an ethyl group, a propyl group, an isobutyl group, a sec-butyl group, a tert-butyl group, a pentyl group, an iso-amyl group, and a hexyl group. The term “alkylene group” as used herein refers to a linear or branched saturated aliphatic divalent hydrocarbon group, and examples thereof may include a methylene group, an ethylene group, a propylene group, a butylene group, and an isobutylene group.

The term “halogenated alkyl group” as used herein refers to a group in which at least one substituent of an alkyl group is substituted with a halogen atom, and examples thereof include CF₃. In this regard, the halogen atom may be F, Cl, Br or I.

The term “alkoxy group” as used herein refers to a monovalent group represented by formula —OA₁₀₁, wherein A₁₀₁ is an alkyl group. Examples thereof are a methoxy group, an ethoxy group, an isopropyloxy group, and the like.

The term “alkylthio group” as used herein refers to a monovalent group represented by formula —SA₁₀₁, wherein A₁₀₁ is an alkyl group.

The term “halogenated alkoxy group” as used herein refers to a group in which one or more hydrogen atoms of an alkoxy group are substituted with a halogen atom, and specific examples thereof include —OCF₃ and the like.

The term “halogenated alkylthio group” as used herein refers to a group in which one or more hydrogen atoms of an alkylthio group are substituted with a halogen atom, and specific examples thereof include —SCF₃ and the like.

The term “cycloalkyl group” as used herein refers to a monovalent saturated hydrocarbon cyclic group, and specific examples thereof include monocyclic groups such as a cyclopropyl group, a cyclobutyl group, a cyclopentyl group, a cyclohexyl group, and a cycloheptyl group, and polycyclic condensed cyclic groups such as a norbornyl group and an adamantyl group. The term “cycloalkylene group” as used herein refers to a divalent saturated hydrocarbon cyclic group, and specific examples thereof include a cyclopentylene group, a cyclohexylene group, an adamantylene group, an adamantylmethylene group, a norbornylene group, a norbornylmethylene group, a tricyclodecanylene group, a tetracyclododecanylene group, a tetracyclododecanylmethylene group, a dicyclohexylmethylene group, and the like.

The term “cycloalkoxy group” as used herein refers to a monovalent group represented by formula —OA₁₀₂, wherein A₁₀₂ is a cycloalkyl group. Examples thereof are a cyclopropoxy group, a cyclobutoxy group, and the like.

The term “cycloalkylthio group” as used herein refers to a monovalent group represented by formula —SA₁₀₂, where A₁₀₂ is a cycloalkyl group.

The term “heterocycloalkyl group” as used herein refers to a cycloalkyl group in which some carbon atoms are substituted with a moiety including a heteroatom, such as oxygen, sulfur, or nitrogen, and the heterocycloalkyl group may include, for example, an ether bond, an ester bond, a sulfonate ester bond, a carbonate, a lactone ring, a sultone ring, or a carboxylic anhydride moiety. The term “heterocycloalkylene group” as used herein refers to a group in which some carbon atoms of the cycloalkylene group are substituted with a moiety including a heteroatom such as oxygen, sulfur, or nitrogen.

The term “heterocycloalkoxy group” as used herein refers to a monovalent group represented by formula —OA₁₀₃, wherein A₁₀₃ is a heterocycloalkyl group.

The term “heterocycloalkylthio group” as used herein refers to a monovalent group represented by formula —SA₁₀₃, wherein A₁₀₃ is a heterocycloalkyl group.

The term “alkenyl group” as used herein refers to a linear or branched unsaturated aliphatic hydrocarbon monovalent group including one or more carbon-carbon double bonds. The term “alkenylene group” as used herein refers to a linear or branched unsaturated aliphatic hydrocarbon divalent group including one or more carbon-carbon double bonds.

The term “alkenyloxy group” as used herein refers to a monovalent group having a formula of —OA₁₀₄, wherein A₁₀₄ is an alkenyl group.

The term “cycloalkenyl group” as used herein refers to a monovalent unsaturated hydrocarbon cyclic group including at least one carbon-carbon double bond. The term “cycloalkenylene group” as used herein refers to a divalent unsaturated hydrocarbon cyclic group including at least one carbon-carbon double bond.

The term “cycloalkenyloxy group” as used herein refers to a monovalent group having a formula of —OA₁₀₅, where A₁₀₅ is a cycloalkenyl group.

The term “heterocycloalkenyl group” as used herein refers to a group in which some carbon atoms of the cycloalkenyl group are replaced by a moiety including a heteroatom (e.g., one or more heteroatoms), such as oxygen, sulfur, or nitrogen. The term “heterocycloalkenylene group” as used herein refers to a cycloalkenylene group in which some carbon atoms are substituted with a moiety including a heteroatom (e.g., one or more heteroatoms), such as oxygen, sulfur, or nitrogen.

The term “heterocycloalkenyloxy group” as used herein refers to a monovalent group having a formula of —OA₁₀₆, wherein A₁₀₆ is a heterocycloalkenyl group.

The term “alkynyl group” as used herein refers to a linear or branched monovalent unsaturated aliphatic hydrocarbon group including one or more carbon-carbon triple bonds.

The term “alkynyloxy group” as used herein refers to a monovalent group having a formula of —OA₁₀₇, wherein A₁₀₇ is an alkynyl group.

The term “aryl group” as used herein refers to a monovalent group including a carbocyclic aromatic system, and examples thereof include a phenyl group, a naphthyl group, an anthracenyl group, a phenanthrenyl group, a pyrenyl group, and a chrysenyl group. The term “arylene group” as used herein refers to a divalent group including a carbocyclic aromatic system.

The term “aryloxy group” as used herein refers to a monovalent group represented by formula —OA₁₀₄, where A₁₀₄ is an aryl group.

The term “arylthio group” as used herein refers to a monovalent group represented by formula —SA₁₀₄, where A₁₀₄ is an aryl group.

The term “heteroaryl group” as used herein refers to a monovalent group including a heterocyclic aromatic system, and examples thereof include a pyridinyl group, a pyrimidinyl group, and a pyrazinyl group. The term “heteroarylene group” as used herein refers to a divalent group including a heterocyclic aromatic system.

The term “heteroaryloxy group” as used herein refers to a monovalent group represented by formula —OA₁₀₅, where A₁₀₅ is a heteroaryl group.

The term “heteroarylthio group” as used herein refers to a monovalent group represented by formula —SA₁₀₅, where A₁₀₅ is a heteroaryl group.

The term “arylalkyl group” as used herein refers to a group in which an alkyl group is substituted with a monovalent group having a carbocyclic aromatic system, and specific examples include a benzyl group, a diphenylmethyl group, etc.

The term “heteroarylalkyl group” as used herein refers to a group in which an alkyl group is substituted with a monovalent group having a heterocyclic aromatic system.

The term “heterocyclic group” as used herein refers to a monocyclic or polycyclic group having 1 to 60 carbon atoms including at least one heteroatom, and is a group that includes a monovalent group, a divalent group, and a trivalent group.

The term “substituent” as used herein includes deuterium, a halogen atom, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, or a C₁-C₂₀ heteroarylthio group;
a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, and a C₁-C₂₀ heteroarylthio group, each substituted with deuterium, a halogen, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, a C₁-C₂₀ heteroarylthio group, and any combination thereof; or any combination thereof.

As used herein, when a definition is not otherwise provided, “aromatic ring” refers to a functional group in which all atoms in the cyclic functional group have a p-orbital, and wherein these p-orbitals are conjugated.

Hereinafter, some example embodiments will be described in detail with reference to the accompanying drawings, wherein like reference numerals denote substantially the same or corresponding components throughout the drawings, and a redundant description thereof will be omitted. In the drawings, the thicknesses of layers and regions are exaggerated for clarity. Also, in the drawings, the thicknesses of some layers and regions are exaggerated for convenience of description. Meanwhile, some example embodiments set forth herein are merely examples and various changes may be made therein.

### [Resist Composition]

A resist composition according to some example embodiments includes an organometallic compound represented by Formula 1 and an additive represented by Formula 2:

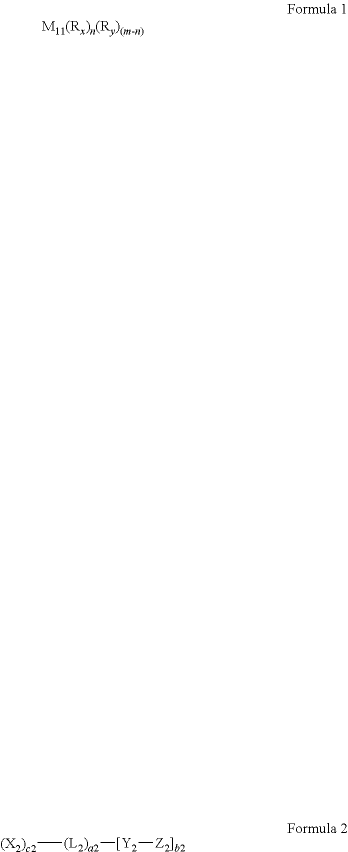

wherein, in Formulae 1 and 2,
M₁₁ may be indium (In), tin (Sn), antimony (Sb), tellurium (Te), thallium (Tl), lead (Pb), bismuth (Bi), or polonium (Po),
Rₓ may be *—X₁—Y₁,
R_{y} may be *-(L₁)ₐ₁-(R₁)_{b1},
n may be an integer from 1 to 6 (inclusively),
m may be an integer from 1 to 6 (inclusively),
m-n is 0 or more,
in example embodiments where n>1 such that Formula 1 includes a plurality of Rₓ, the plurality of Rₓ may be identical to or different from each other (e.g., Formula 1 optionally includes a plurality of Rₓ based on n being greater than 1, the plurality of Rₓ identical to or different from each other),
in example embodiments where (m-n)>1 such that Formula 1 includes a plurality of R_{y}, the plurality of R_{y} may be identical to or different from each other (e.g., Formula 1 optionally includes a plurality of R_{y} based on m-n being greater than 1, the plurality of R_{y} identical to or different from each other),
X₁ may be O, OC(═O), C(═O)O, OS(═O), S(═O)O, OS(═O)₂, S(═O)₂O, S, SC(═O), or C(═O)S,
Y₁ may be hydrogen, deuterium, or a linear, branched, or cyclic C₁-C₃₀ monovalent hydrocarbon group that optionally includes a heteroatom (e.g., one or more heteroatoms),
L₁ may be a linear, branched, or cyclic C₁-C₃₀ divalent hydrocarbon group that optionally includes a heteroatom (e.g., one or more heteroatoms),
a1 may be an integer from 0 to 4 (inclusively),
R₁ may be a linear, branched, or cyclic C₁-C₃₀ monovalent hydrocarbon group that optionally includes a heteroatom (e.g., one or more heteroatoms), and in example embodiments where (b1)>1 such that Formula R_{y} includes a plurality of R₁, two adjacent groups among the plurality of R₁ may optionally bond to each other to form a ring (e.g., Formula 1 optionally includes a plurality of R₁ based on b1 being greater than 1, two adjacent groups among the plurality of R₁ optionally bonded to each other to form a ring),
b1 may be an integer from 1 to 4 (inclusively),
X₂ may be OH, SH, C(═O)OH, S(═O)OH, S(═O)₂OH, or P(═O)(OH)₂,
c2 may be an integer from 1 to 4 (inclusively),
each L₂ may independently be a linear, branched, or cyclic C₁-C₃₀ divalent hydrocarbon group that optionally includes a heteroatom (e.g., one or more heteroatoms),
a2 may be an integer from 0 to 4 (inclusively),
Y₂—Z₂ may be a photo-reactive unit,
B2 may be an integer from 1 to 4 (inclusively), and
* is a bonding site to a neighboring atom of Formula 1.

The molecular weight of the organometallic compound may be about 3000 g/mol or less. In some example embodiments, the molecular weight of the organometallic compound may be about 2000 g/mol or less.

In some example embodiments, M₁₁ of Formula 1 may be Sn, Sb, Te, or Bi. In some example embodiments, in Formula 1, M₁₁ may be Sn.

In Formula 1, m refers to a valency of M₁₁.

In some example embodiments, in Formula 1, n may be an integer from 1 to 4.

In some example embodiments, m in Formula 1 may be an integer from 1 to 4.

In some example embodiments, in Formula 1, n may be an integer from 1 to 4, m may be an integer from 1 to 4, and M₁₁ may be Sn.

In some example embodiments, in Formula 1, the bond between M₁₁ and Rₓ may be an M₁₁-oxygen single bond or an M₁₁-sulfur single bond. In some example embodiments, in Formula 1, the bond between M₁₁ and Rₓ may be an M₁₁-oxygen single bond.

In some example embodiments, in Formula 1, the bond between M₁₁ and R_{y} may be an M₁₁-carbon single bond.

In some example embodiments, in Formula 1, X₁ may be O, OC(═O), C(═O)O, S, SC(═O), or C(═O)S.

In some example embodiments, Y₁ in Formula 1 may each independently be selected from: hydrogen, deuterium, a C₁-C₃₀ alkyl group, a C₁-C₃₀ halogenated alkyl group, a C₁-C₃₀ alkoxy group, a C₁-C₃₀ alkylthio group, a C₁-C₃₀ halogenated alkoxy group, a C₁-C₃₀ halogenated alkylthio group, a C₃-C₃₀ cycloalkyl group, a C₃-C₃₀ cycloalkoxy group, a C₃-C₃₀ cycloalkylthio group, a C₃-C₃₀ heterocycloalkyl group, a C₂-C₃₀ alkenyl group, a C₃-C₃₀ cycloalkenyl group, a C₃-C₃₀ heterocycloalkenyl group, a C₂-C₃₀ alkynyl group, a C₆-C₃₀ aryl group, a C₆-C₃₀ aryloxy group, a C₆-C₃₀ arylthio group, a C₇-C₃₀ arylalkyl group, a C₁-C₃₀ heteroaryl group, a C₁-C₃₀ heteroaryloxy group, a C₁-C₃₀ heteroarylthio group, and a C₂-C₃₀ heteroarylalkyl group. Each of the C₁-C₃₀ alkyl group, the C₁-C₃₀ halogenated alkyl group, the C₁-C₃₀ alkoxy group, the C₁-C₃₀ alkylthio group, the C₁-C₃₀ halogenated alkoxy group, the C₁-C₃₀ halogenated alkylthio group, the C₃-C₃₀ cycloalkyl group, the C₃-C₃₀ cycloalkoxy group, the C₃-C₃₀ cycloalkylthio group, the C₃-C₃₀ heterocycloalkyl group, the C₂-C₃₀ alkenyl group, the C₃-C₃₀ cycloalkenyl group, the C₃-C₃₀ heterocycloalkenyl group, the C₂-C₃₀ alkynyl group, the C₆-C₃₀ aryl group, the C₆-C₃₀ aryloxy group, the C₆-C₃₀ arylthio group, the C₇-C₃₀ arylalkyl group, the C₁-C₃₀ heteroaryl group, the C₁-C₃₀ heteroaryloxy group, the C₁-C₃₀ heteroarylthio group, and the C₂-C₃₀ heteroarylalkyl group may be unsubstituted or substituted with deuterium, a halogen, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy, a C₁-C₂₀ heteroarylthio group, or any combination thereof.

In some example embodiments, Y₁ may each independently be selected from: hydrogen; deuterium; and a C₁-C₃₀ alkyl group, a C₁-C₃₀ halogenated alkyl group, a C₃-C₃₀ cycloalkyl group, a C₂-C₃₀ alkenyl group, a C₃-C₃₀ cycloalkenyl group, a C₃-C₃₀ heterocycloalkenyl group, a C₂-C₃₀ alkynyl group, a C₆-C₃₀ aryl group, a C₇-C₃₀ arylalkyl group, a C₁-C₃₀ heteroaryl group, and a C₂-C₃₀ heteroarylalkyl group, each unsubstituted or substituted with deuterium, a halogen, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a C₁-C₂₀ alkyl group, a C₁-C₂₀ halogenated alkyl group, a C₃-C₂₀ cycloalkyl group, a C₆-C₂₀ aryl group, or any combination thereof.

In some example embodiments, Y₁ in Formula 1 may be selected from: hydrogen; deuterium; and a C₁-C₃₀ alkyl group, a C₃-C₃₀ cycloalkyl group, a C₂-C₃₀ alkenyl group, a C₃-C₃₀ cycloalkenyl group, a C₂-C₃₀ alkynyl group, and a C₆-C₃₀ aryl group, each unsubstituted or substituted with deuterium, a halogen, or any combination thereof.

In particular, Y₁ in Formula 1 may be selected from: hydrogen; deuterium; and a methyl group, an ethyl group, an n-propyl group, an iso-propyl group, an n-butyl group, a sec-butyl group, an iso-butyl group, a tert-butyl group, a cyclopentyl group, a cyclohexyl group, an ethenyl group, a cyclopentenyl group, a cyclopentadienyl group, a cyclohexenyl group, a cyclohexadienyl group, an ethynyl group, a phenyl group, and a naphthyl group, each unsubstituted or substituted with deuterium, a halogen, a methyl group, an ethyl group, a phenyl group, a naphthyl group, or any combination thereof.

In some example embodiments, L₁ in Formula 1 may be a single bond, a substituted or unsubstituted C₁-C₃₀ alkylene group, a substituted or unsubstituted C₃-C₃₀ cycloalkylene group, a substituted or unsubstituted C₃-C₃₀ heterocycloalkylene group, a substituted or unsubstituted C₂-C₃₀ alkenylene group, a substituted or unsubstituted C₃-C₃₀ cycloalkenylene group, a substituted or unsubstituted C₃-C₃₀ heterocycloalkenylene group, a substituted or unsubstituted C₆-C₃₀ arylene group, or a substituted or unsubstituted C₁-C₃₀ heteroarylene group.

In some example embodiments, L₁ in Formula 1 may be selected from: a single bond, and a C₁-C₃₀ alkylene group, a C₃-C₃₀ cycloalkylene group, a C₃-C₃₀ heterocycloalkylene group, a C₂-C₃₀ alkenylene group, a C₃-C₃₀ cycloalkenylene group, a C₃-C₃₀ heterocycloalkenylene group, a C₆-C₃₀ arylene group, and a C₁-C₃₀ heteroarylene group. Each of the C₁-C₃₀ alkylene group, the C₃-C₃₀ cycloalkylene group, the C₃-C₃₀ heterocycloalkylene group, the C₂-C₃₀ alkenylene group, the C₃-C₃₀ cycloalkenylene group, the C₃-C₃₀ heterocycloalkenylene group, the C₆-C₃₀ arylene group, and the C₁-C₃₀ heteroarylene group may be unsubstituted or substituted with deuterium, a halogen, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or any combination thereof.

In some example embodiments, L₁ in Formula 1 may be selected from a single bond; and a C₁-C₃₀ alkylene group and a C₆-C₃₀ arylene group, each unsubstituted or substituted with deuterium, a halogen, a hydroxyl group, a cyano group, a C₁-C₂₀ alkyl group, a C₁-C₂₀ halogenated alkyl group, or any combination thereof.

In some example embodiments, a1 in Formula 1 may be 0, 1, or 2.

In some example embodiments, R₁ in Formula 1 may be selected from a C₁-C₃₀ alkyl group, a C₃-C₃₀ cycloalkyl group, a C₃-C₃₀ heterocycloalkyl group, a C₂-C₃₀ alkenyl group, a C₃-C₃₀ cycloalkenyl group, a C₃-C₃₀ heterocycloalkenyl group, a C₂-C₃₀ alkynyl group, a C₆-C₃₀ aryl group, a C₇-C₃₀ arylalkyl group, a C₁-C₃₀ heteroaryl group, and a C₂-C₃₀ heteroarylalkyl group. Each of the C₁-C₃₀ alkyl group, the C₃-C₃₀ cycloalkyl group, the C₃-C₃₀ heterocycloalkyl group, the C₂-C₃₀ alkenyl group, the C₃-C₃₀ cycloalkenyl group, the C₃-C₃₀ heterocycloalkenyl group, the C₂-C₃₀ alkynyl group, the C₆-C₃₀ aryl group, the C₇-C₃₀ arylalkyl group, the C₁-C₃₀ heteroaryl group, and the C₂-C₃₀ heteroarylalkyl group may be unsubstituted or substituted with deuterium, a halogen, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or any combination thereof.

In some example embodiments, R₁ in Formula 1 may be selected from a C₁-C₃₀ alkyl group, a C₃-C₃₀ cycloalkyl group, a C₂-C₃₀ alkenyl group, a C₃-C₃₀ cycloalkenyl group, a C₂-C₃₀ alkynyl group, a C₆-C₃₀ aryl group, and a C₇-C₃₀ arylalkyl group. Each of the C₁-C₃₀ alkyl group, the C₃-C₃₀ cycloalkyl group, the C₂-C₃₀ alkenyl group, the C₃-C₃₀ cycloalkenyl group, the C₂-C₃₀ alkynyl group, the C₆-C₃₀ aryl group, and the C₇-C₃₀ arylalkyl group may be unsubstituted or substituted with deuterium, a halogen, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or any combination thereof.

In some example embodiments, R₁ in Formula 1 may be selected from any one of Formulae 3-1 to 3-21:

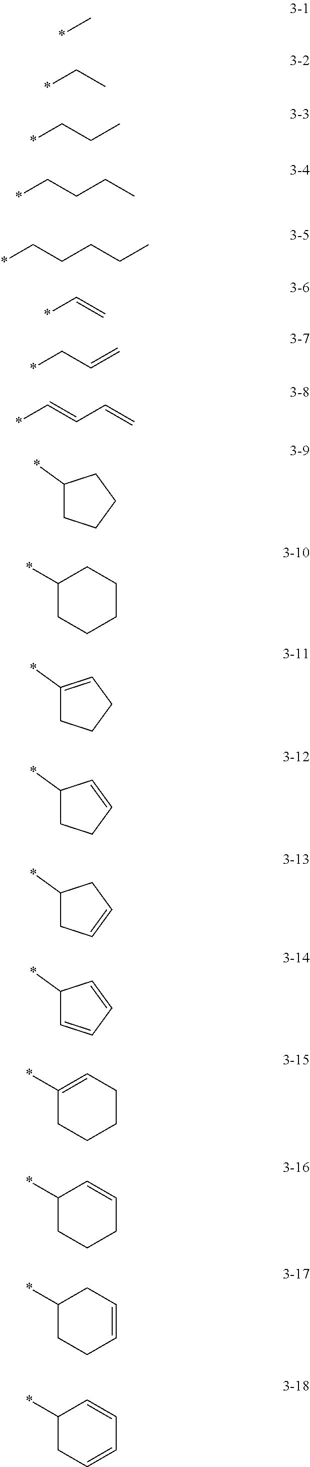

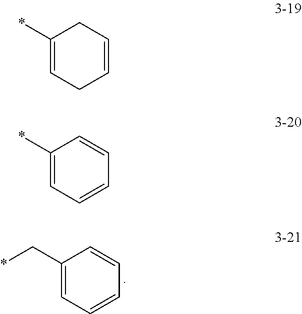

In Formulae 3-1 to 3-21,
at least one hydrogen may be present or may be optionally substituted with deuterium, a halogen, a cyano group, a nitro group, a carbonyl moiety, a C₁-C₂₀ alkyl group, a C₁-C₂₀ halogenated alkyl group, a C₃-C₂₀ cycloalkyl group, a C₆-C₂₀ aryl group, a C₁-C₂₀ heteroaryl group, or any combination thereof, and
* is a bonding site to a neighboring atom of Formula 1.

In Formula 1, b1 indicates the number (quantity) of substituents of R₁, and for example, b1 in Formula 1 may be 1 or 2.

Adjacent two of R₁ may optionally bond to each other to form a ring (e.g., in example embodiments where b1 is 2 or more).

In some example embodiments, in Formula 1, b1 may be 2 or more, and R₁ may be selected from a C₂-C₃₀ alkenyl group, a C₃-C₃₀ cycloalkenyl group, a C₂-C₃₀ alkynyl group, and a C₆-C₃₀ aryl group. Each of the C₂-C₃₀ alkenyl group, the C₃-C₃₀ cycloalkenyl group, the C₂-C₃₀ alkynyl group, and the C₆-C₃₀ aryl group may be unsubstituted or substituted with deuterium, a halogen, a cyano group, a nitro group, a carbonyl moiety, a C₁-C₂₀ alkyl group, a C₁-C₂₀ halogenated alkyl group, a C₃-C₂₀ cycloalkyl group, a C₆-C₂₀ aryl group, a C₁-C₂₀ heteroaryl group, or any combination thereof.

In some example embodiments, the organometallic compound represented by Formula 1 may be represented by one of Formulae 1-1 to 1-4:

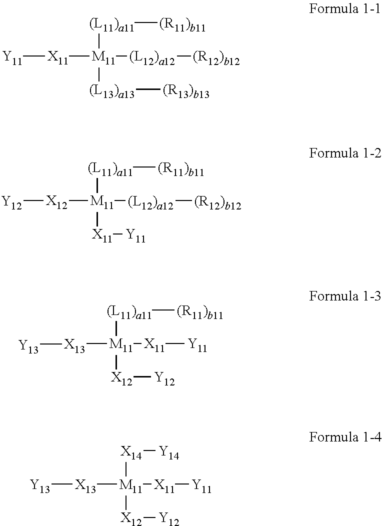

wherein, in Formulae 1-1 to 1-4,
M₁₁ is as described above with reference to Formula 1, such that M₁₁ may be indium (In), tin (Sn), antimony (Sb), tellurium (Te), thallium (Tl), lead (Pb), bismuth (Bi), or polonium (Po),
L₁₁ to L₁₃ are each independently as described in connection with L₁ in Formula 1, such that 11 to L₁₃ may each independently be a linear, branched, or cyclic C₁-C₃₀ divalent hydrocarbon group that optionally includes a heteroatom (e.g., one or more heteroatoms),
a11 to a13 are each independently as described in connection with a1 in Formula 1, such that a11 to a13 may each independently be an integer from 0 to 4,
R₁₁ to R₁₃ are each independently as described in connection with R₁ in Formula 1, such that R₁₁ to R₁₃ are each independently a linear, branched, or cyclic C₁-C₃₀ monovalent hydrocarbon group that optionally includes a heteroatom (e.g., one or more heteroatoms),
b11 to b13 are each independently as described in connection with b1 in Formula 1, such b11 to b13 are each independently an integer from 1 to 4, wherein two adjacent groups among a plurality of R₁₁ are optionally bonded to each other to form a ring based on b11 being greater than 1, two adjacent groups among a plurality of R₁₂ are optionally bonded to each other to form a ring based on b12 being greater than 1, and two adjacent groups among a plurality of R₁₃ are optionally bonded to each other to form a ring based on b13 being greater than 1.
X₁₁ to X₁₄ are each independently as described in connection with X₁ in Formula 1, such that X₁₁ to X₁₄ are each independently O, OC(═O), C(═O)O, OS(═O), S(═O)O, OS(═O)₂, S(═O)₂O, S, SC(═O), or C(═O)S, and
Y₁₁ to Y₁₃ are each independently as described in connection with Y₁ in Formula 1, such that Y₁₁ to Y₁₃ are each independently hydrogen, deuterium, or a linear, branched, or cyclic C₁-C₃₀ monovalent hydrocarbon group that optionally includes one or more heteroatoms.

In some example embodiments, the organometallic compound represented by Formula 1 may be selected from Group I:

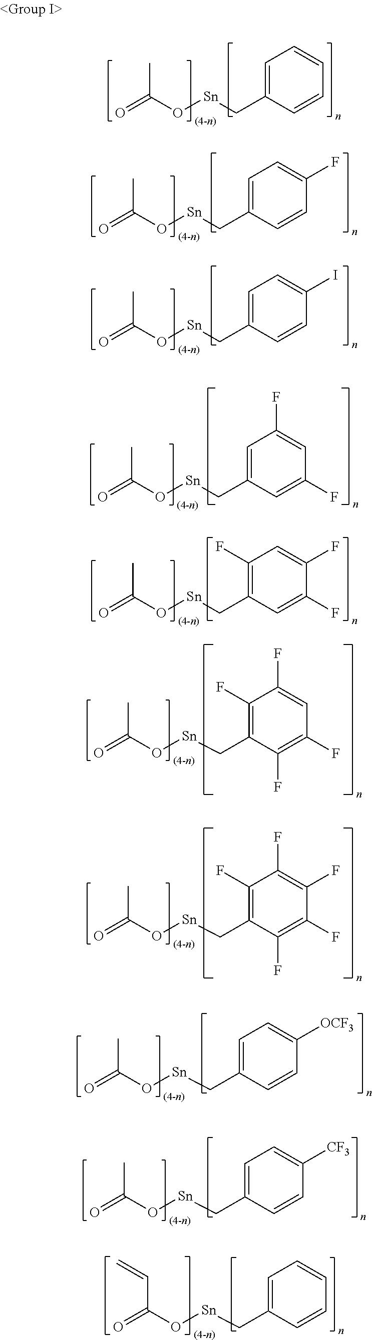

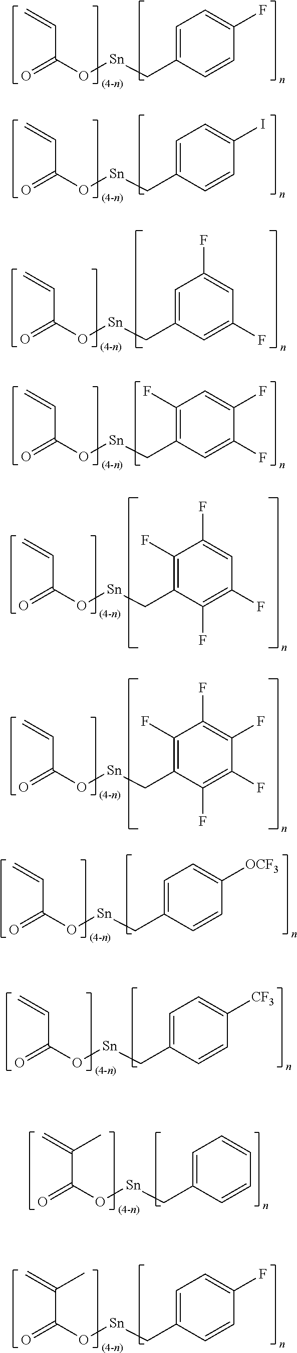

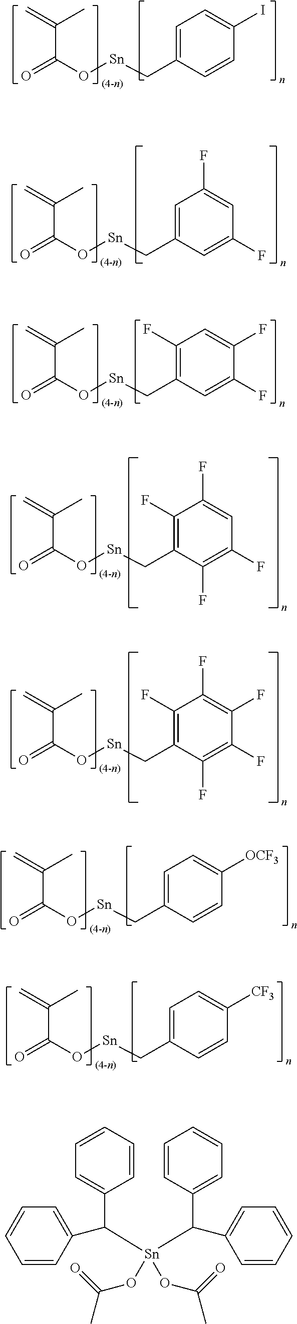

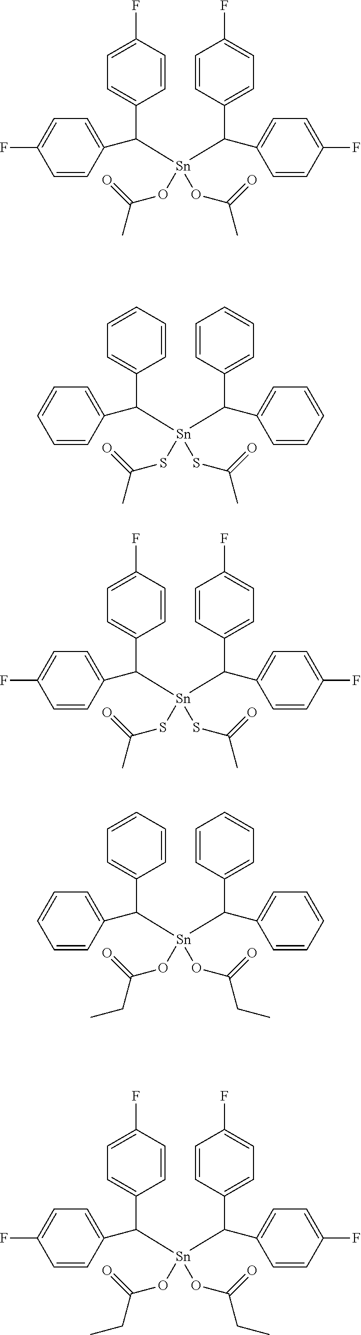

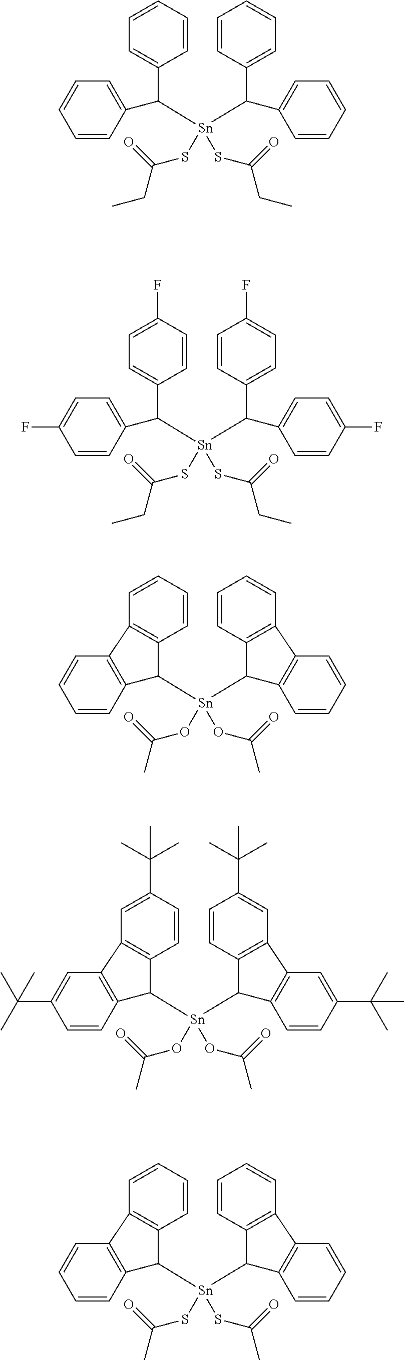 [SMILES: CCC(=O)[S][Sn]([S]C(=O)CC)([CH](c1ccccc1)c1ccccc1)[CH](c1ccccc1)c1ccccc1 ; CCC(=O)[S][Sn]([S]C(=O)CC)([CH](c1ccc(F)cc1)c1ccc(F)cc1)[CH](c1ccc(F)cc1)c1ccc(F)cc1 ; CC(=O)[O][Sn]([O]C(C)=O)([CH]1c2ccccc2-c2ccccc21)[CH]1c2ccccc2-c2ccccc21 ; CC(=O)[O][Sn]([O]C(C)=O)([CH]1c2ccc(C(C)(C)C)cc2-c2cc(C(C)(C)C)ccc21)[CH]1c2ccc(C(C)(C)C)cc2-c2cc(C(C)(C)C)ccc21 ; CC(=O)[S][Sn]([S]C(C)=O)([CH]1c2ccccc2-c2ccccc21)[CH]1c2ccccc2-c2ccccc21]

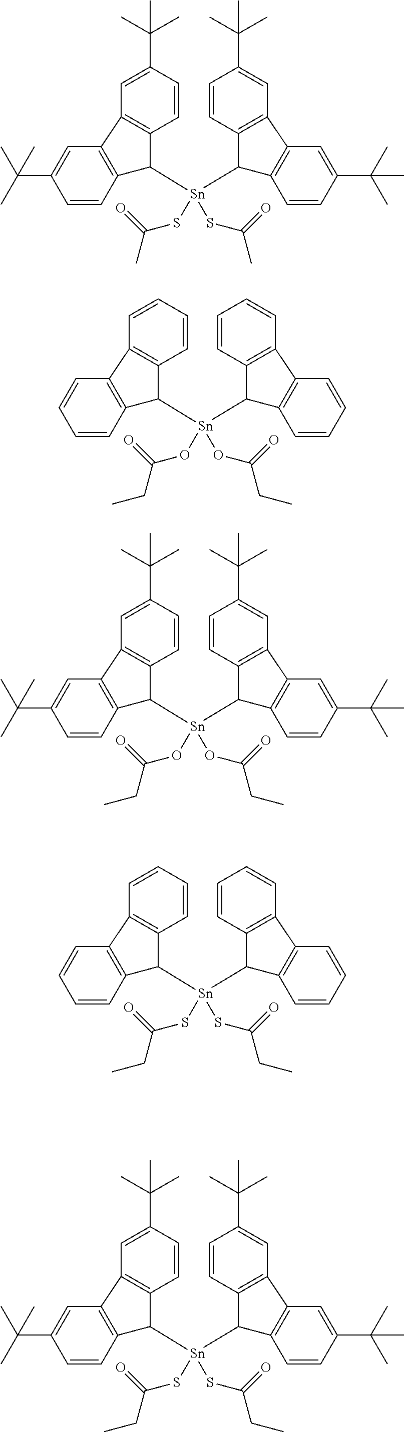

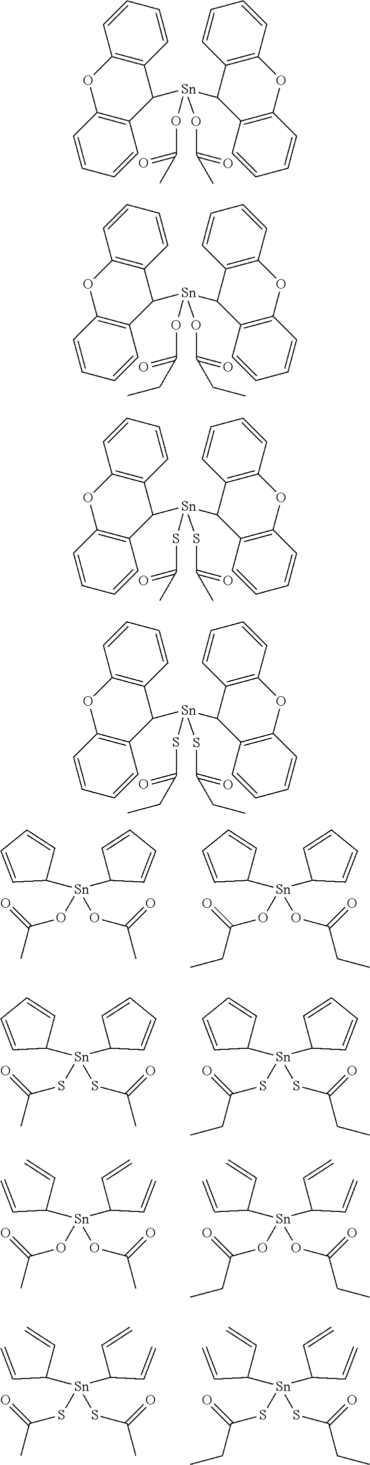

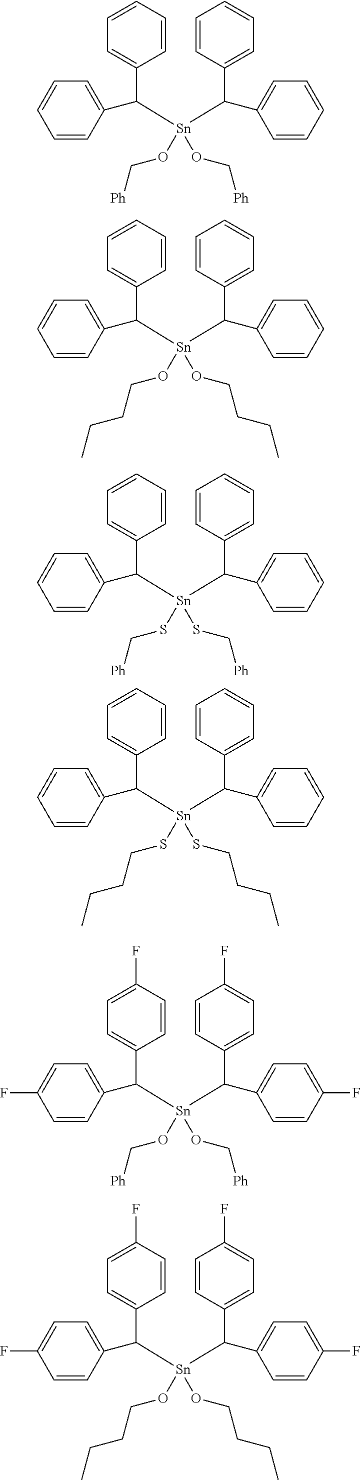

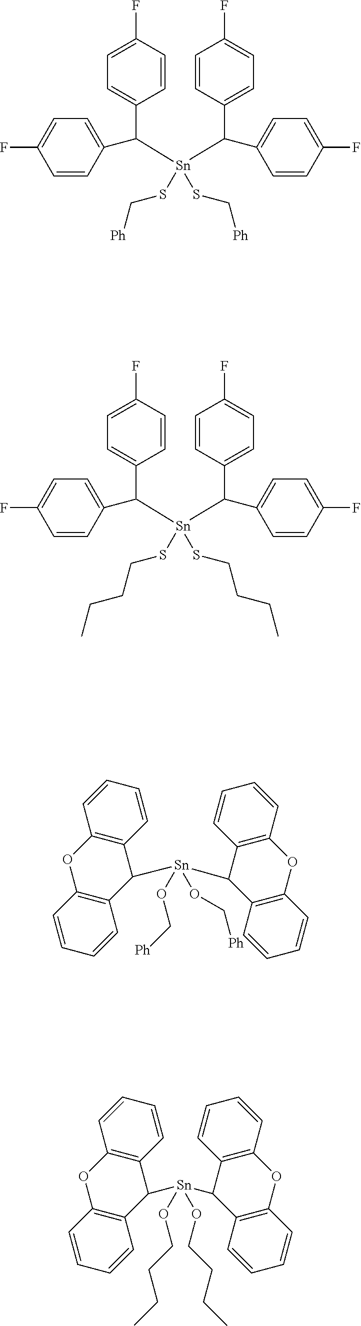 [SMILES: Fc1ccc([CH](c2ccc(F)cc2)[Sn]([S]Cc2ccccc2)([S]Cc2ccccc2)[CH](c2ccc(F)cc2)c2ccc(F)cc2)cc1 ; CCCC[S][Sn]([S]CCCC)([CH](c1ccc(F)cc1)c1ccc(F)cc1)[CH](c1ccc(F)cc1)c1ccc(F)cc1 ; c1ccc(C[O][Sn]([O]Cc2ccccc2)([CH]2c3ccccc3Oc3ccccc32)[CH]2c3ccccc3Oc3ccccc32)cc1 ; CCCC[O][Sn]([O]CCCC)([CH]1c2ccccc2Oc2ccccc21)[CH]1c2ccccc2Oc2ccccc21]

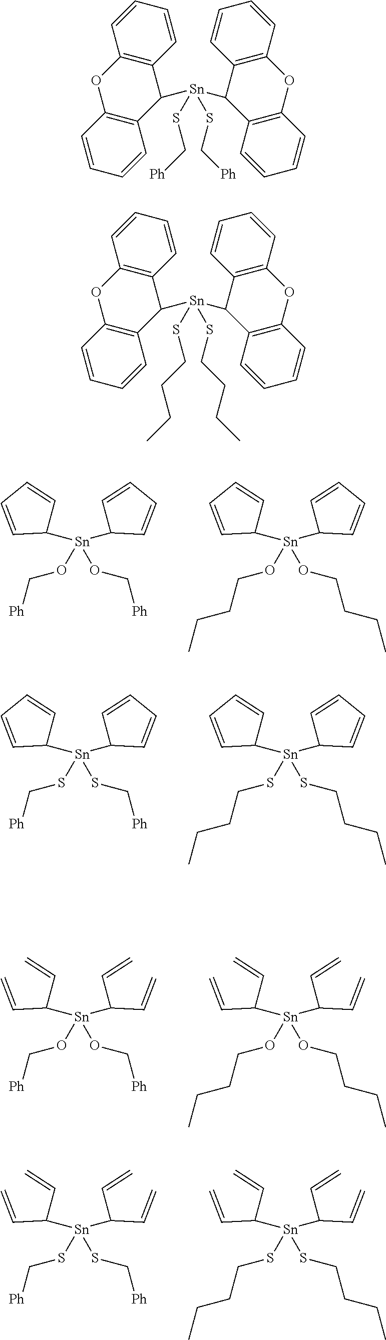

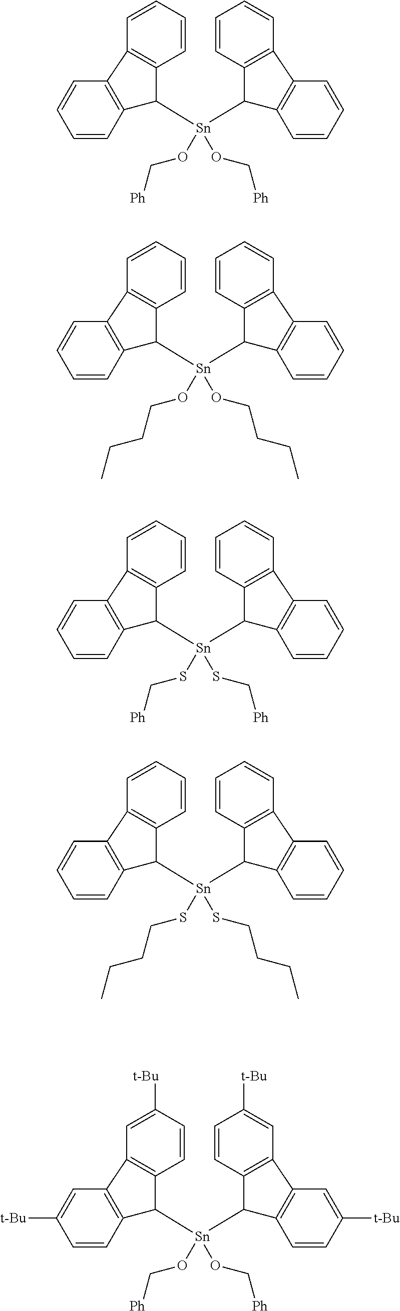

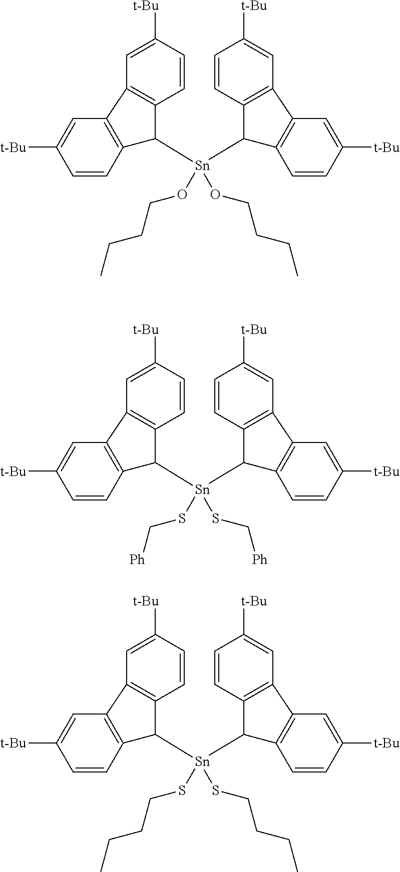

wherein n in Group I is an integer from 0 to 3 (inclusively).

In some example embodiments, n in Group I may be 2.

Any one type of the organometallic compound may be used, or a combination of two or more types of the organometallic compound may be used.

In some example embodiments, X₂ in Formula 2 may be OH or C(═O)OH.

In some example embodiments, c2 in Formula 2 may be 1.

L₂ in Formula 2 may be as described in connection with Li such that L₂ may be a linear, branched, or cyclic C₁-C₃₀ divalent hydrocarbon group that optionally includes one or more heteroatoms.

In some example embodiments, a2 in Formula 2 may be 1 or 2.

In some example embodiments, (L₂)ₐ₂ in Formula 2 may be represented by one of Formulae 5-1 to 5-7:

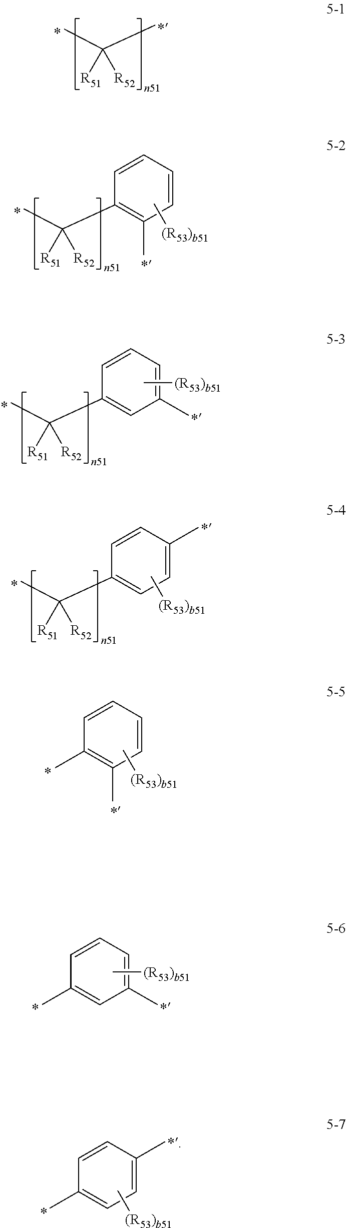

In Formulae 5-1 to 5-7,
R₅₁ to R₅₃ may each independently be hydrogen, deuterium, a halogen, a hydroxyl group, a cyano group, a C₁-C₄ alkyl group, or a C₁-C₄ halogenated alkyl group,
b51 may be an integer from 1 to 4 (inclusively),
n51 may be an integer from 1 to 4 (inclusively), and
* and *′ each indicate a binding site to a neighboring atom of Formula 2.

In some example embodiments, Y₂ in Formula 2 may be OC(═O), C(═O)O, OS(═O)₂, or S(═O)₂O.

In some example embodiments, Z₂ in Formula 2 may be *—C(R₂)(R₃)(R₄), *—C(R₂)═N(R₃), *—N═C(R₂)(R₃), or *—N(R₂)(R₃), wherein * is a bonding site to a neighboring atom of Formula 2.

In some example embodiments, in Formula 2, R₂ to R₄ may each independently be hydrogen, deuterium, a halogen, a cyano group, a nitro group, a hydroxyl group, —C(═O)R₅, —C(R₅)=NR₆, —ORS, —S(═O)R₅, —S(═O)₂R₅, —S(═O)₂OR₅, a substituted or unsubstituted C₁-C₃₀ alkyl group, a substituted or unsubstituted C₁-C₃₀ halogenated alkyl group, a substituted or unsubstituted C₁-C₃₀ alkoxy group, a substituted or unsubstituted C₁-C₃₀ alkylthio group, a substituted or unsubstituted C₁-C₃₀ halogenated alkoxy group, a substituted or unsubstituted C₁-C₃₀ halogenated alkylthio group, a substituted or unsubstituted C₃-C₃₀ cycloalkyl group, a substituted or unsubstituted C₃-C₃₀ cycloalkoxy group, a substituted or unsubstituted C₃-C₃₀ cycloalkylthio group, a substituted or unsubstituted C₃-C₃₀ heterocycloalkyl group, a substituted or unsubstituted C₃-C₃₀ heterocycloalkoxy group, a substituted or unsubstituted C₃-C₃₀ heterocycloalkylthio group, a substituted or unsubstituted C₂-C₃₀ alkenyl group, a substituted or unsubstituted C₂-C₃₀ alkenyloxy group, a substituted or unsubstituted C₂-C₃₀ alkenylthio group, a substituted or unsubstituted C₃-C₃₀ cycloalkenyl group, a substituted or unsubstituted C₃-C₃₀ cycloalkenyloxy group, a substituted or unsubstituted C₃-C₃₀ cycloalkenylthio group, a substituted or unsubstituted C₃-C₃₀ heterocycloalkenyl group, a substituted or unsubstituted C₃-C₃₀ heterocycloalkenyloxy group, a substituted or unsubstituted C₃-C₃₀ heterocycloalkenylthio group, a substituted or unsubstituted C₂-C₃₀ alkynyl group, a substituted or unsubstituted C₂-C₃₀ alkynyloxy group, a substituted or unsubstituted C₂-C₃₀ alkynylthio group, a substituted or unsubstituted C₆-C₃₀ aryl group, a substituted or unsubstituted C₆-C₃₀ aryloxy group, a substituted or unsubstituted C₆-C₃₀ arylthio group, a substituted or unsubstituted C₁-C₃₀ heteroaryl group, a substituted or unsubstituted C₁-C₃₀ heteroaryloxy group, or a substituted or unsubstituted C₁-C₃₀ heteroarylthio group, and
R₅ and R₆ may each independently be hydrogen, deuterium, a hydroxyl group, a substituted or unsubstituted C₁-C₃₀ alkyl group, a substituted or unsubstituted C₁-C₃₀ halogenated alkyl group, a substituted or unsubstituted C₁-C₃₀ alkoxy group, a substituted or unsubstituted C₁-C₃₀ alkylthio group, a substituted or unsubstituted C₁-C₃₀ halogenated alkoxy group, a substituted or unsubstituted C₁-C₃₀ halogenated alkylthio group, a substituted or unsubstituted C₃-C₃₀ cycloalkyl group, a substituted or unsubstituted C₃-C₃₀ cycloalkoxy group, a substituted or unsubstituted C₃-C₃₀ cycloalkylthio group, a substituted or unsubstituted C₃-C₃₀ heterocycloalkyl group, a substituted or unsubstituted C₃-C₃₀ heterocycloalkoxy group, a substituted or unsubstituted C₃-C₃₀ heterocycloalkylthio group, substituted or unsubstituted C₂-C₃₀ alkenyl group, a substituted or unsubstituted C₂-C₃₀ alkenyloxy group, a substituted or unsubstituted C₂-C₃₀ alkenylthio group, a substituted or unsubstituted C₃-C₃₀ cycloalkenyl group, a substituted or unsubstituted C₃-C₃₀ cycloalkenyloxy group, a substituted or unsubstituted C₃-C₃₀ cycloalkenylthio group, a substituted or unsubstituted C₃-C₃₀ heterocycloalkenyl group, a substituted or unsubstituted C₃-C₃₀ heterocycloalkenyloxy group, a substituted or unsubstituted C₃-C₃₀ heterocycloalkenylthio group, a substituted or unsubstituted C₂-C₃₀ alkynyl group, a substituted or unsubstituted C₂-C₃₀ alkynyloxy group, a substituted or unsubstituted C₂-C₃₀ alkynylthio group, a substituted or unsubstituted C₆-C₃₀ aryl group, a substituted or unsubstituted C₆-C₃₀ aryloxy group, a substituted or unsubstituted C₆-C₃₀ arylthio group, a substituted or unsubstituted C₁-C₃₀ heteroaryl group, a substituted or unsubstituted C₁-C₃₀ heteroaryloxy group, or a substituted or unsubstituted C₁-C₃₀ heteroarylthio group.

In some example embodiments, in Formula 2, R₂ to R₄ may each independently be selected from: hydrogen; deuterium; halogen; a cyano group; a nitro group; a hydroxyl group; —C(═O)R₅; —C(R₅)=NR₆; —S(═O)₂R₅; and a C₁-C₃₀ alkyl group, a C₃-C₃₀ cycloalkyl group, a C₂-C₃₀ alkenyl group, a C₃-C₃₀ cycloalkenyl group, a C₂-C₃₀ alkynyl group, a C₆-C₃₀ aryl group, and a C₇-C₃₀ arylalkyl group. Each of the cyano group; the nitro group; the hydroxyl group; —C(═O)R₅; —C(R₅)=NR₆; —S(═O)₂R₅; the C₁-C₃₀ alkyl group, the C₃-C₃₀ cycloalkyl group, the C₂-C₃₀ alkenyl group, the C₃-C₃₀ cycloalkenyl group, the C₂-C₃₀ alkynyl group, the C₆-C₃₀ aryl group, and the C₇-C₃₀ arylalkyl group may be unsubstituted or substituted with deuterium, a halogen, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or any combination thereof, and
R₅ and R₆ may each independently be: hydrogen; deuterium; a hydroxyl group; and a C₁-C₃₀ alkyl group, a C₃-C₃₀ cycloalkyl group, a C₂-C₃₀ alkenyl group, a C₃-C₃₀ cycloalkenyl group, a C₂-C₃₀ alkynyl group, a C₆-C₃₀ aryl group, and a C₇-C₃₀ arylalkyl group, each unsubstituted or substituted with deuterium, a halogen, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or any combination thereof.

In some example embodiments, in Formula 2, R₂ to R₄ may each independently selected from: hydrogen; deuterium; halogen; a cyano group; a nitro group; a hydroxyl group; —C(═O)R₅; —C(R₅)=NR₆; —S(═O)₂R₅; and a C₁-C₃₀ alkyl group, a C₃-C₃₀ cycloalkyl group, a C₂-C₃₀ alkenyl group, a C₃-C₃₀ cycloalkenyl group, a C₂-C₃₀ alkynyl group, a C₆-C₃₀ aryl group, and a C₇-C₃₀ arylalkyl group. Each of the cyano group; the nitro group; the hydroxyl group; —C(═O)R₅; —C(R₅)=NR₆; —S(═O)₂R₅; the C₁-C₃₀ alkyl group, the C₃-C₃₀ cycloalkyl group, the C₂-C₃₀ alkenyl group, the C₃-C₃₀ cycloalkenyl group, the C₂-C₃₀ alkynyl group, the C₆-C₃₀ aryl group, and the C₇-C₃₀ arylalkyl group may be unsubstituted or substituted with deuterium, a halogen, a cyano group, a nitro group, a carbonyl moiety, a C₁-C₂₀ alkyl group, a C₁-C₂₀ halogenated alkyl group, a C₃-C₂₀ cycloalkyl group, a C₆-C₂₀ aryl group, a C₁-C₂₀ heteroaryl group, or any combination thereof, and

R₅ and R₆ may each independently be selected from: hydrogen; deuterium; a hydroxyl group; and a C₁-C₃₀ alkyl group, a C₃-C₃₀ cycloalkyl group, a C₂-C₃₀ alkenyl group, a C₃-C₃₀ cycloalkenyl group, a C₂-C₃₀ alkynyl group, a C₆-C₃₀ aryl group, and a C₇-C₃₀ arylalkyl group, each unsubstituted or substituted with deuterium, a halogen, a cyano group, a nitro group, a carbonyl moiety, a C₁-C₂₀ alkyl group, a C₁-C₂₀ halogenated alkyl group, a C₃-C₂₀ cycloalkyl group, a C₆-C₂₀ aryl group, a C₁-C₂₀ heteroaryl group, or any combination thereof.

In some example embodiments, in Formula 2, R₂ to R₄ may each independently be selected from: hydrogen; deuterium; halogen; a cyano group; a nitro group; a hydroxyl group; —C(═O)R₅; —C(R₅)=NR₆; —S(═O)₂R₅; and one of Formulae 3-1 to 3-21, and
R₅ and R₆ may each independently be selected from: hydrogen; deuterium; a hydroxyl group; and one of Formulae 3-1 to 3-21:

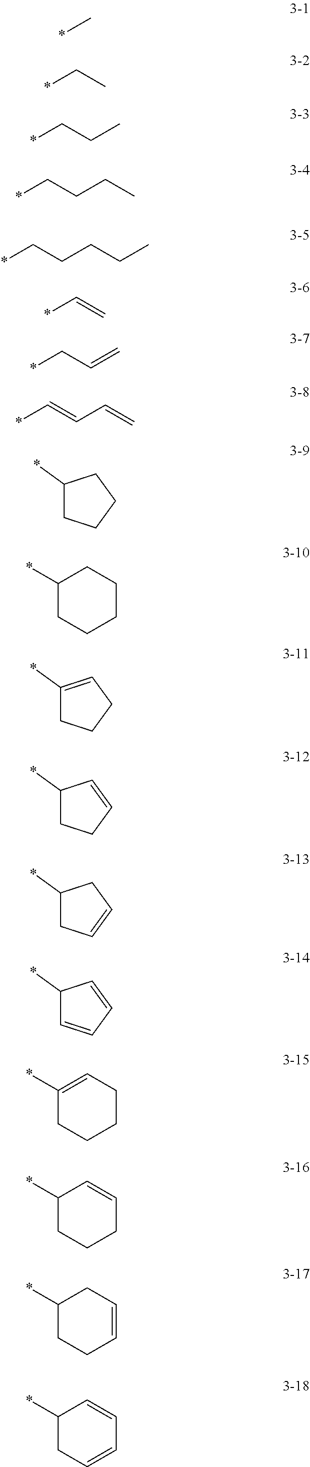

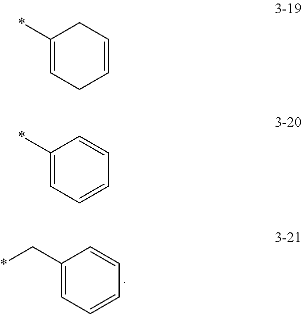

In Formulae 3-1 to 3-21,
at least one hydrogen may be present or may be optionally substituted with deuterium, a halogen, a cyano group, a nitro group, a carbonyl moiety, a C₁-C₂₀ alkyl group, a C₁-C₂₀ halogenated alkyl group, a C₃-C₂₀ cycloalkyl group, a C₆-C₂₀ aryl group, a C₁-C₂₀ heteroaryl group, or any combination thereof, and
* is a bonding site to a neighboring atom of Formula 2.

In some example embodiments, Z₂ in Formula 2 may be represented by one of Formulae 4-1 to 4-9:

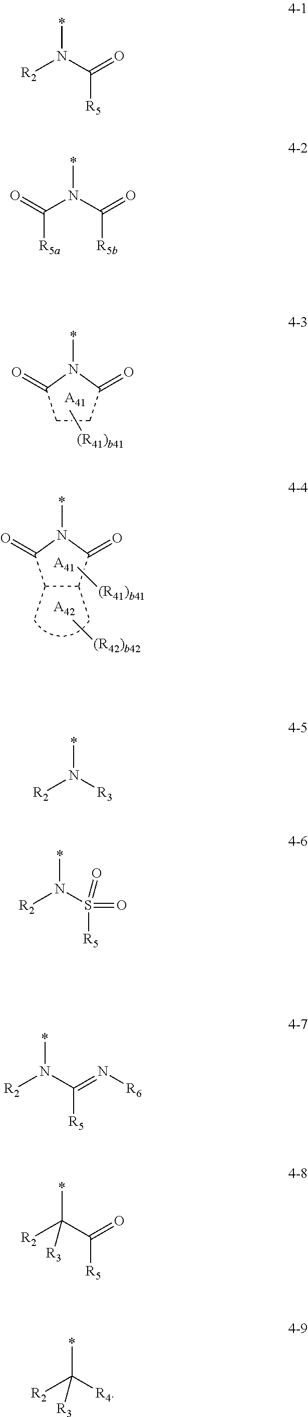

In Formulae 4-1 to 4-9,
R₂ to R₄ may each be independently selected from: hydrogen; deuterium; halogen; a cyano group; a nitro group, a hydroxyl group, a C₁-C₃₀ alkyl group, a C₃-C₃₀ cycloalkyl group, a C₂-C₃₀ alkenyl group, a C₃-C₃₀ cycloalkenyl group, a C₂-C₃₀ alkynyl group, a C₆-C₃₀ aryl group, and a C₇-C₃₀ arylalkyl group. Each of the C₁-C₃₀ alkyl group, the C₃-C₃₀ cycloalkyl group, the C₂-C₃₀ alkenyl group, the C₃-C₃₀ cycloalkenyl group, the C₂-C₃₀ alkynyl group, the C₆-C₃₀ aryl group, and the C₇-C₃₀ arylalkyl group may be unsubstituted or substituted with deuterium, a halogen, a cyano group, a nitro group, a carbonyl moiety, a C₁-C₂₀ alkyl group, a C₁-C₂₀ halogenated alkyl group, a C₃-C₂₀ cycloalkyl group, a C₆-C₂₀ aryl group, a C₁-C₂₀ heteroaryl group, or any combination thereof,
R₅, R₅ₐ and R_{5b} may each be independently selected from: hydrogen, deuterium, a C₁-C₃₀ alkyl group, a C₃-C₃₀ cycloalkyl group, a C₂-C₃₀ alkenyl group, a C₃-C₃₀ cycloalkenyl group, a C₂-C₃₀ alkynyl group, a C₆-C₃₀ aryl group, and a C₇-C₃₀ arylalkyl group. Each of the C₁-C₃₀ alkyl group, the C₃-C₃₀ cycloalkyl group, the C₂-C₃₀ alkenyl group, the C₃-C₃₀ cycloalkenyl group, the C₂-C₃₀ alkynyl group, the C₆-C₃₀ aryl group, and the C₇-C₃₀ arylalkyl group may be unsubstituted or substituted with deuterium, a halogen, a cyano group, a nitro group, a carbonyl moiety, a C₁-C₂₀ alkyl group, a C₁-C₂₀ halogenated alkyl group, a C₃-C₂₀ cycloalkyl group, a C₆-C₂₀ aryl group, a C₁-C₂₀ heteroaryl group, or any combination thereof,
two adjacent groups from among R₂ to R₅, R₅ₐ and R_{5b} may optionally bond to each other to form a ring,
A₄₁ and A₄₂ may each independently be a C₁-C₃₀ cyclic alkyl group that optionally includes one or more heteroatoms or a C₁-C₃₀ aryl group that optionally includes one or more heteroatoms,
R₄₁ and R₄₂ may each independently be hydrogen, deuterium, a halogen, a hydroxyl group, a cyano group, a nitro group, a C₁-C₂₀ alkyl group, a C₁-C₂₀ halogenated alkyl group, a C₃-C₂₀ cycloalkyl group, a C₆-C₂₀ aryl group, or a C₁-C₂₀ heteroaryl group,
b41 and b42 may each independently be an integer from 1 to 10 (inclusively), and
* is a bonding site to a neighboring atom of Formula 2.

In some example embodiments, Z₂ in Formula 2 may be represented by one of Formulae 4-11 to 4-50:

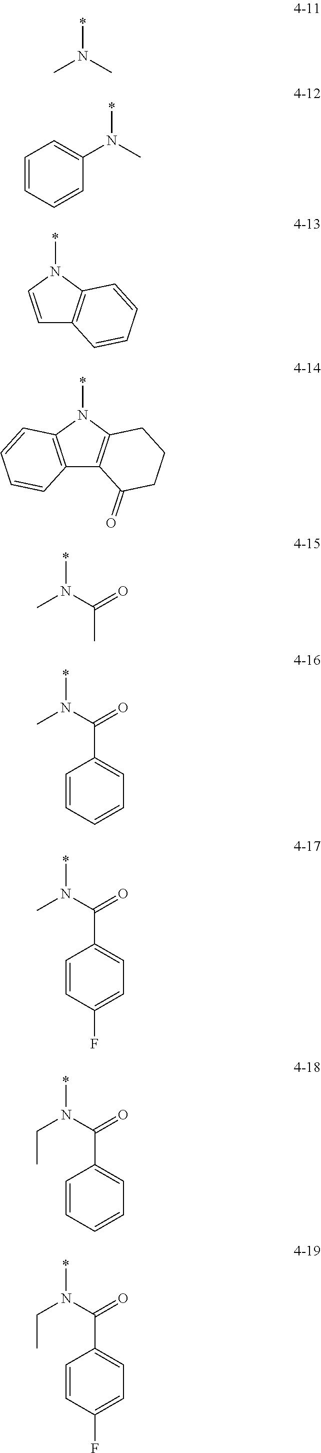

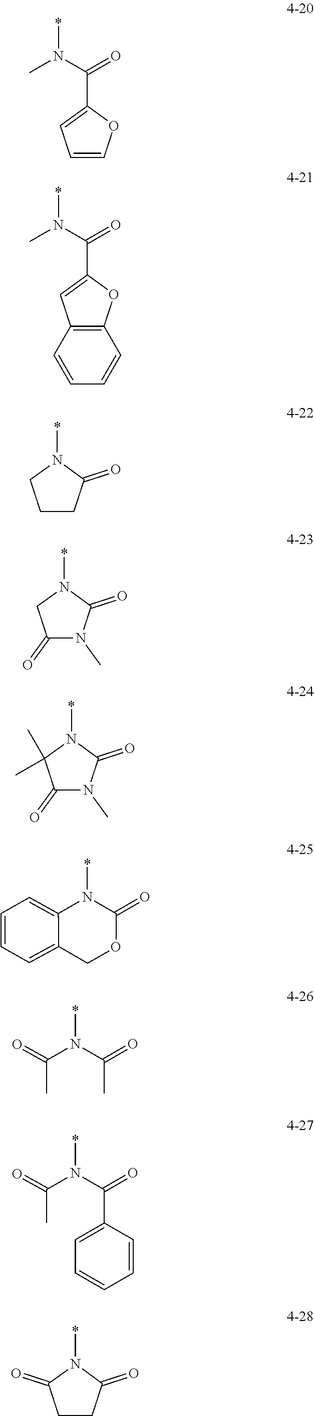

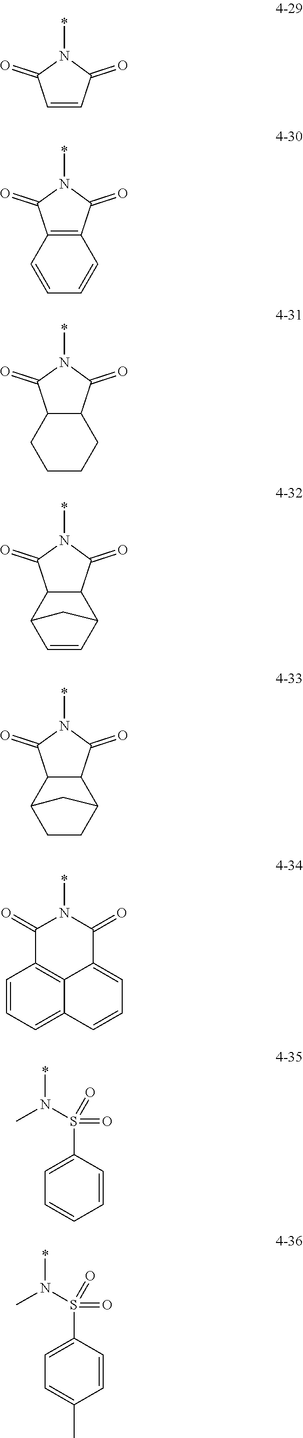

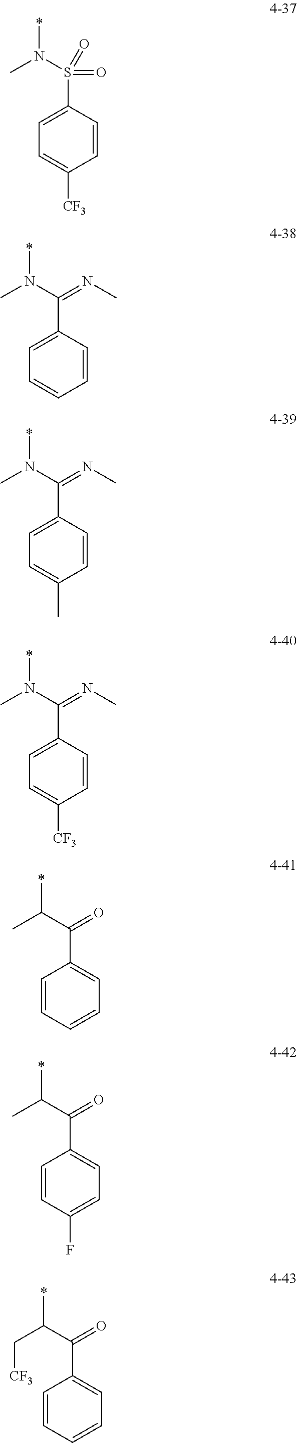

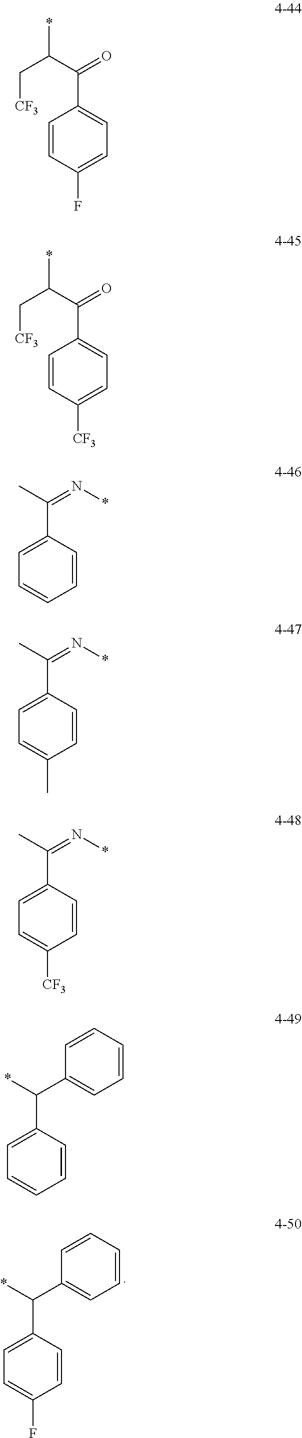

In Formulae 4-11 to 4-50,
* is a bonding site to a neighboring atom of Formula 2.

In some example embodiments, at least one of Z₂ in Formula 2 may include an electron withdrawing group.

In some example embodiments, in Formula 2, at least one of R₂ to R₄ may be an electron withdrawing group.

In some example embodiments, at least one of R₂ to R₄ in Formula 2 may be selected from: a halogen, a cyano group, a nitro group, —C(═O)R₅; —C(R₅)=NR₆, —S(═O)₂R₅, a C₁-C₃₀ alkyl group, a C₃-C₃₀ cycloalkyl group, a C₂-C₃₀ alkenyl group, a C₃-C₃₀ cycloalkenyl group, a C₂-C₃₀ alkynyl group, a C₆-C₃₀ aryl group, and a C₇-C₃₀ arylalkyl group. Each of the C₁-C₃₀ alkyl group, the C₃-C₃₀ cycloalkyl group, the C₂-C₃₀ alkenyl group, the C₃-C₃₀ cycloalkenyl group, the C₂-C₃₀ alkynyl group, the C₆-C₃₀ aryl group, and the C₇-C₃₀ arylalkyl group may be substituted with a halogen, a cyano group, a nitro group, a C₁-C₂₀ halogenated alkyl group, or any combination thereof,
R₅ and R₆ may each independently be selected from: hydrogen, deuterium, a C₁-C₃₀ alkyl group, a C₃-C₃₀ cycloalkyl group, a C₂-C₃₀ alkenyl group, a C₃-C₃₀ cycloalkenyl group, a C₂-C₃₀ alkynyl group, a C₆-C₃₀ aryl group, and a C₇-C₃₀ arylalkyl group. Each of the C₁-C₃₀ alkyl group, the C₃-C₃₀ cycloalkyl group, the C₂-C₃₀ alkenyl group, the C₃-C₃₀ cycloalkenyl group, the C₂-C₃₀ alkynyl group, the C₆-C₃₀ aryl group, and the C₇-C₃₀ arylalkyl group may be unsubstituted or substituted with deuterium, a halogen, a cyano group, a nitro group, a carbonyl moiety, a C₁-C₂₀ alkyl group, a C₁-C₂₀ halogenated alkyl group, a C₃-C₂₀ cycloalkyl group, a C₆-C₂₀ aryl group, a C₁-C₂₀ heteroaryl group, or any combination thereof.

In some example embodiments, b2 in Formula 2 may be 1.

In some example embodiments, the additive represented by Formula 2 may be selected from Group II:

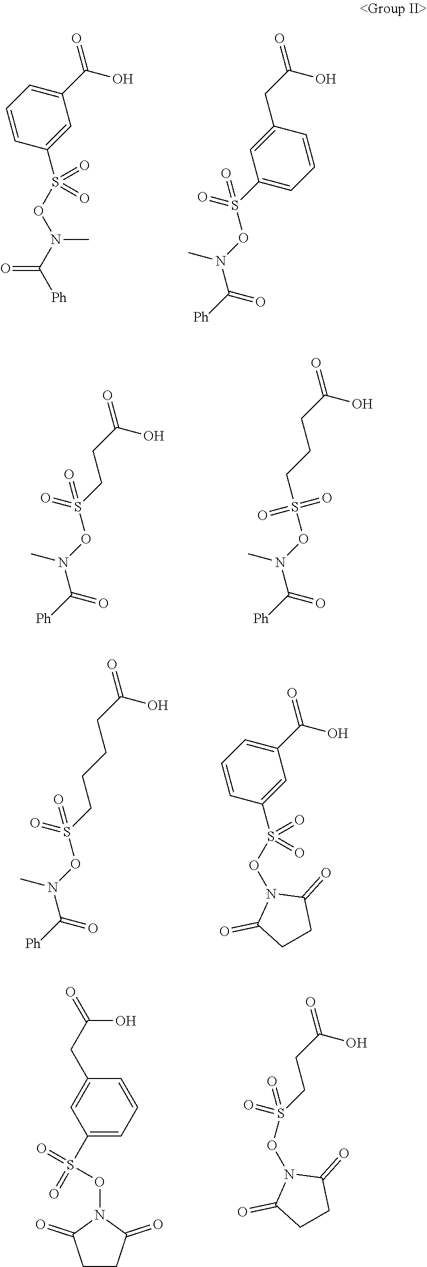

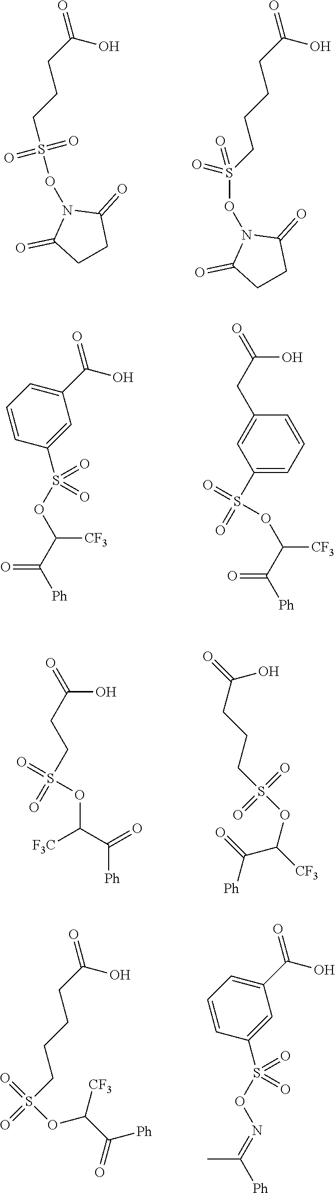

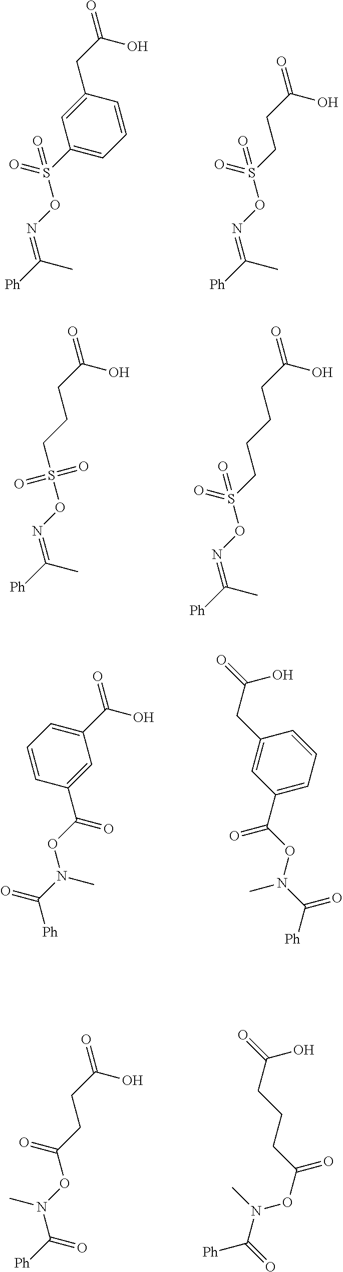

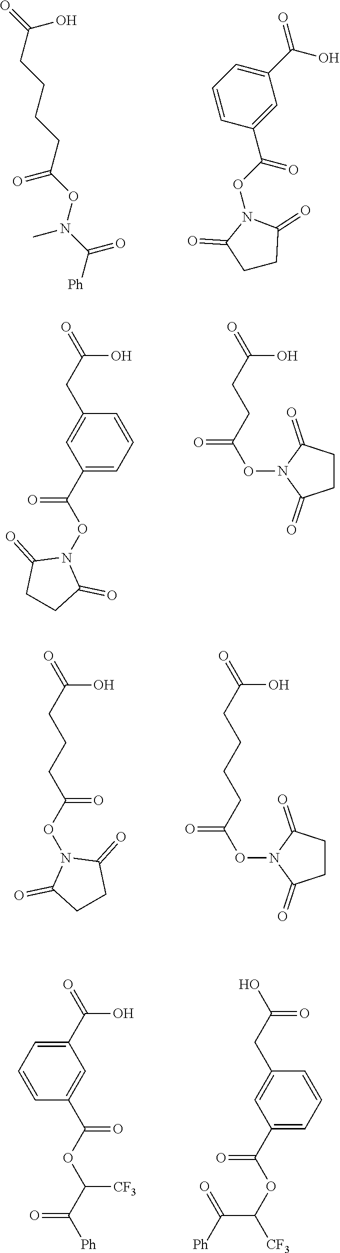

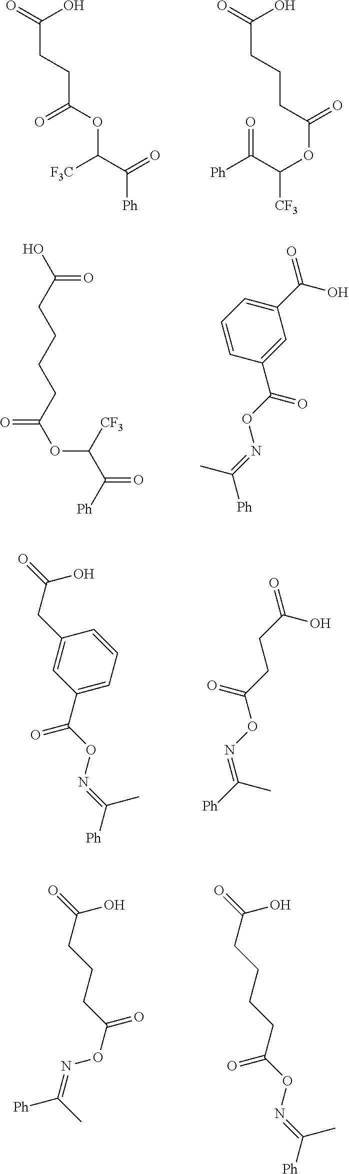

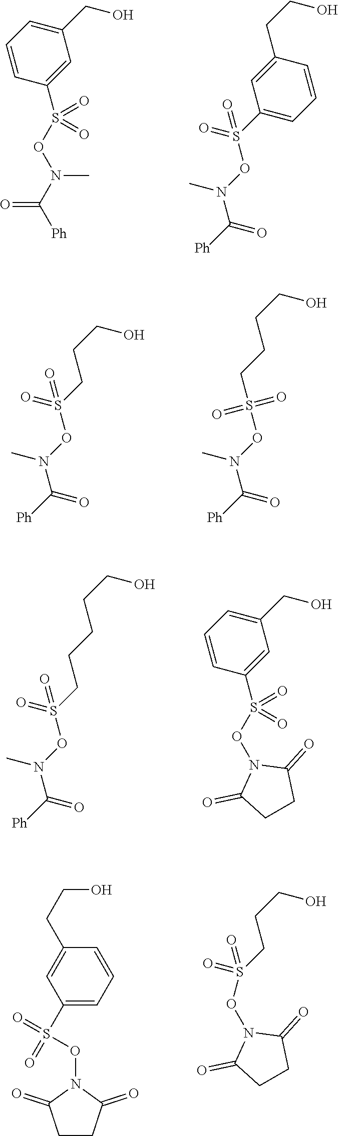

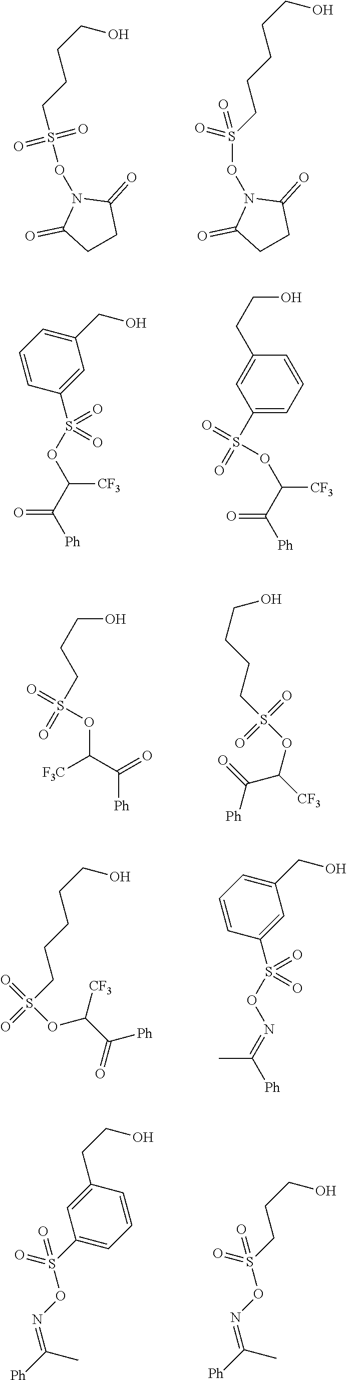

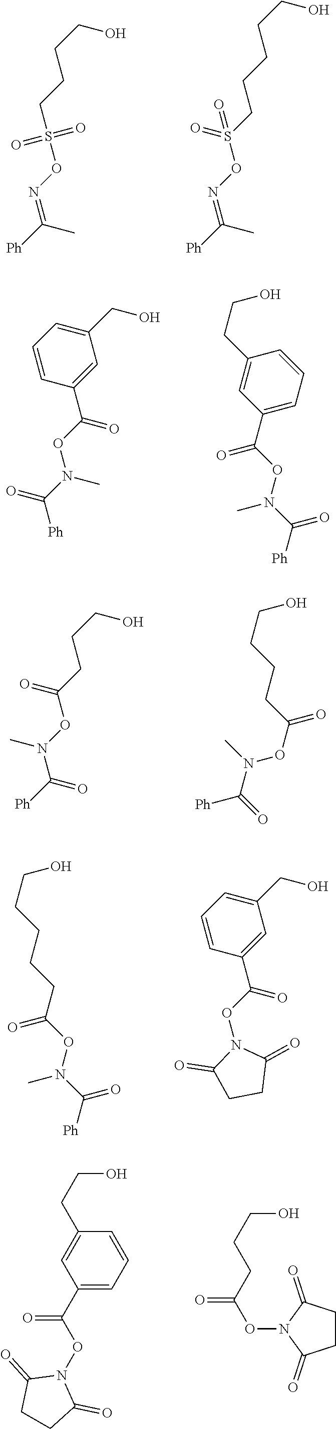

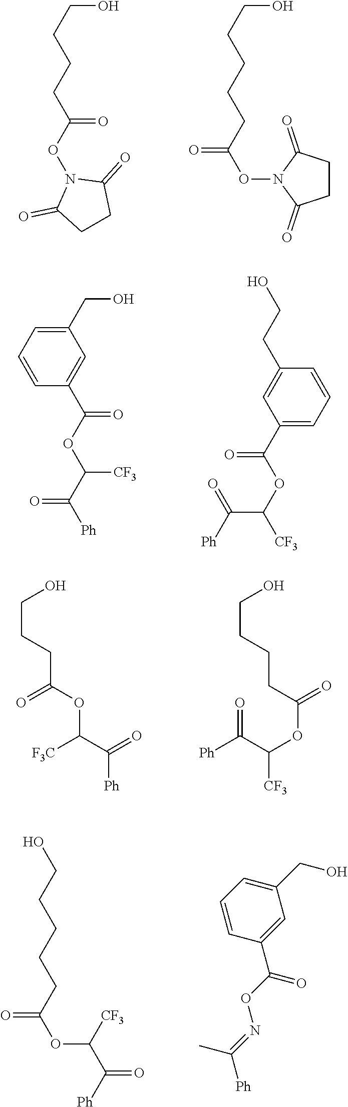

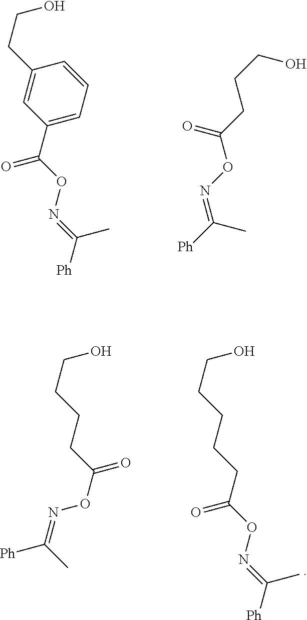 [SMILES: C/C(=N\OC(=O)c1cccc(CCO)c1)c1ccccc1 ; C/C(=N\OC(=O)CCCO)c1ccccc1 ; C/C(=N\OC(=O)CCCCO)c1ccccc1 ; C/C(=N\OC(=O)CCCCCO)c1ccccc1]

Regarding Group II, Ph is a phenyl group.

The additive may be any one compound represented by Formula 2, or a mixture of two or more such compounds may be used.

The additive may improve the chemical stability of the organometallic compound represented by Formula 1 by being exchanged with the ligand of the organometallic compound.

In the resist composition, the organometallic compound may be about 0.01 parts by weight to about 100 parts by weight, for example, 0.2 or more, 0.5 or more, 1 or more, 1.5 or more, 90 or less, or 80 or less parts by weight, based on 100 parts by weight of the resist composition. When these ranges are satisfied, chemical bonds between organometallic compounds are sufficiently formed and side reactions are suppressed, thereby providing a resist composition with improved sensitivity and/or resolution.

In the resist composition, the additive may be about 0.01 parts by weight to about 100 parts by weight, for example, 0.2 or more, 0.5 or more, 1 or more, 1.5 or more, 90 or less, or 80 or less parts by weight, based on 100 parts by weight of the resist composition. When these ranges are satisfied, chemical bonds between organometallic compounds are sufficiently formed and side reactions are suppressed, thereby providing a resist composition with improved sensitivity and/or resolution.

In the resist composition, the additive may be included in an amount of about 0.1 parts by weight to about 100,000 parts by weight based on 100 parts by weight of the organometallic compound. In some example embodiments, the additive may be included in an amount of about 10 parts by weight to about 1,000 parts by weight based on 100 parts by weight of the organometallic compound. When these ranges are satisfied, the resist composition may significantly improve storage stability while maintaining the photosensitivity at the level of a resist composition without the additive.

In view of at least the above, the resist composition may have a composition which has improved storage stability and/or the resist composition may be configured to change one or more physical properties even by exposure to incident light (e.g., high-energy rays), in order to overcome limitations of chemically amplified resists which may cause a formed acid to diffuse to an unexposed region. As a result, the resist composition may be configured to reduce, minimize, or prevent the likelihood of a reduction in uniformity of patterns and/or an increase in surface roughness when the resist composition is used in a pattern formation method, based on avoiding such formed acid diffusion, while simultaneously providing improved resist composition chemical stability (and thereby reduced, minimized, or prevented risk of chemical deterioration) in normal usage environments at room temperature and/or while simultaneously changing physical properties even by exposure to a small amount (e.g., small intensity) of incident light (e.g., high-energy rays).

Since the resist composition is a non-chemically amplified type, the resist composition may substantially not include a photoacid generator.

Since the physical properties of the organometallic compound change upon exposure to light, the resist composition may not include or substantially include compounds with a molecular weight of about 1,000 or more other than the organometallic compound.

Exposure to high-energy rays changes solubility of the resist composition in a developer. The resist composition may be a negative resist composition in which unexposed portions of the resist film are dissolved and removed to form a negative resist pattern, or may be a positive resist composition in which exposed portions of the resist film are dissolved and removed to form a positive resist pattern. The resist composition may be modified in various ways, such as negative or positive, depending on the exposure intensity and/or the type of developer.

In addition, the resist composition may be for a distilled water developing process using distilled water (DI) for the developing process when forming a resist pattern, for an alkaline developing process using an alkaline developer, or for a solvent developing process using a developer containing an organic solvent (hereinafter, also referred to as an organic developer) for the developing process. In some example embodiments, the resist composition may be for a distilled water developing process or a solvent developing process.

In some example embodiments, when distilled water, an alkaline developer, or any combination thereof is used as a developer, the exposed portion may be washed away and removed by the developer, and the unexposed portion remains without being washed away by the developer. As a result, the characteristics of a positive resist composition may be obtained. Meanwhile, when an organic solvent is used as a developer, the unexposed portion may be washed away and removed by the developer, and the exposed portion remains without being washed away by the developer. As a result, the characteristics of a negative resist composition may be obtained. That is, the resist composition may be a negative resist composition or a positive resist composition, depending on the polarity of the developer.

Without being limited to a particular theory, the organometallic compound may react with an additive such that a ligand of the organometallic compound, for example, an Rₓ ligand, is substituted with the additive. Next, the organometallic compound in which the ligand is substituted with the additive may undergo a change in polarity due to dissociation of specific bonds, for example, bonds within a photoreactive unit, by high-energy rays.

In some example embodiments, an organometallic compound having a ligand substituted with an additive may generate radicals from a photoreactive unit by high-energy rays, and optionally, in an atmosphere where water is present, the radicals may react to generate polar functional groups. Accordingly, the physical properties of the organometallic compound, particularly the solubility thereof in a developer, may be changed by high-energy rays.

The organometallic compound and the additive may be prepared by any appropriate method, or commercially available products may be used therefor.

The structure (composition) of the organometallic compound and additive may be confirmed by Fourier transform infrared spectroscopy (FT-IR) analysis, nuclear magnetic resonance (NMR) analysis, X-ray fluorescence (XRF) analysis, mass spectrometry, ultra violet (UV) Spectrometer analysis, single crystal X-ray structural analysis, powder X-ray diffraction (PXRD) analysis, liquid chromatography analysis, size exclusion chromatography (SEC) analysis, thermal analysis, etc. A detailed confirmation method is as described in Examples below.

### <Solvent>

The resist composition may further include a solvent.

The solvent included in the resist composition may not be particularly limited as long as it is capable of dissolving or dispersing the organometallic compound, an additive, and optional components contained as necessary. The solvent may be used alone or in combination with two or more different types.

The solvent may include non-polar solvents, polar aprotic solvents, or a combination thereof.

In some example embodiments, the solvent may be polar aprotic solvents.

Non-polar solvents may include ether-based solvents, hydrocarbon-based solvents, and a combination thereof.

Polar aprotic solvents may include ether-based solvents, ketone-based solvents, amide-based solvents, ester-based solvents, sulfoxide-based solvents, and a combination thereof.

Examples of ether-based solvents are dialkyl ether solvents such as diethyl ether, dipropyl ether, dibutyl ether, diethylene glycol dimethyl ether, and dipropylene glycol dimethyl ether; cyclic ether solvents such as 1,4-dioxane, tetrahydrofuran and tetrahydropyran; and aromatic ring-containing ether solvents such as diphenyl ether and anisole.

Examples of ketone-based solvents are linear ketone solvents such as acetone, methyl ethyl ketone, methyl-n-propyl ketone, methyl-n-butyl ketone, methyl-n-pentyl ketone, diethyl ketone, methyl isobutyl ketone, 2-heptanone, ethyl-n-butyl ketone, methyl-n-hexyl ketone, diisobutyl ketone, and trimethylnonanone; cyclic ketone solvents such as cyclopentanone, cyclohexanone, cycloheptanone, cyclooctanone, and methylcyclohexanone; and other ketone solvents such as 2,4-pentanedione, acetonylacetone, and acetophenone.

Examples of amide-based solvents are cyclic amide solvents such as N,N′-dimethylimidazolidinone and N-methyl-2-pyrrolidone; and linear amide solvents such as N-methylformamide, N,N-dimethylformamide, N,N-diethylformamide, acetamide, N-methylacetamide, N,N-dimethylacetamide, and N-methylpropionamide.

Examples of ester-based solvents are acetate ester solvents such as methyl acetate, ethyl acetate, n-propyl acetate, isopropyl acetate, n-butyl acetate, isobutyl acetate, sec-butyl acetate, t-butyl acetate, n-pentyl acetate, isopentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, and n-nonyl acetate; polyhydric alcohol-containing ether carboxylate solvents such as ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate (PGMEA), propylene glycol monoethyl ether acetate, propylene glycol monopropyl ether acetate, propylene glycol monobutyl ether acetate, dipropylene glycol monomethyl ether acetate, and dipropylene glycol monoethyl ether acetate; lactone solvents such as γ-butyrolactone and δ-valerolactone; carbonate solvents such as dimethyl carbonate, diethyl carbonate, ethylene carbonate, and propylene carbonate; and other solvents such as ethylene glycol diacetate, methoxytriglycol acetate, ethyl propionate, n-butyl propionate, isoamyl propionate, diethyl oxalate, di-n-butyl oxalate, methyl acetoacetate, ethyl acetoacetate, diethyl malonate, dimethyl phthalate, and diethyl phthalate.

Examples of sulfoxide-based solvents are dimethyl sulfoxide and diethyl sulfoxide.

Examples of hydrocarbon-based solvents are aliphatic hydrocarbon solvents such as n-pentane, isopentane, n-hexane, isohexane, n-heptane, isoheptane, 2,2,4-trimethyl pentane, n-octane, isooctane, cyclohexane, and methylcyclohexane; and aromatic hydrocarbon solvents such as benzene, toluene, xylene, mesitylene, ethylbenzene, trimethylbenzene, methylethylbenzene, n-propylbenzene, isopropylbenzene, diethylbenzene, isobutylbenzene, triethylbenzene, diisopropylbenzene, and n-amylnaphthalene.

In some example embodiments, the solvent may be selected from ketone-based solvents, ester-based solvents, and a combination thereof.

In some example embodiments, the solvent may be selected from linear ketone-based solvents, cyclic ketone-based solvents, polyhydric alcohol-containing ethercarboxylate-based solvents, lactone-based solvents, acetate ester-based solvents, and a combination thereof.

In some example embodiments, the solvent may be selected from methyl ethyl ketone, cyclopentanone, cyclohexanone, cycloheptanone, propylene glycol monomethyl ether acetate, γ-butyrolactone, δ-valerolactone, n-butyl acetate, and a combination thereof.

The resist composition may be free or substantially free of water, and therefore, the solvent may also be free of water. In some example embodiments, the resist composition may contain 3 wt % or less of water (e.g., 0.01 wt % to 3 wt %, 0.1 wt % to 3 wt %, 1 wt % to 3 wt %, etc.), and the solvent may contain 3 wt % or less of water (e.g., 0.01 wt % to 3 wt %, 0.1 wt % to 3 wt %, 1 wt % to 3 wt %, etc.).

The solvent may be used in an amount of about 0 parts by weight to about 99.9 parts by weight based on 100 parts by weight of the resist composition (e.g., about 0.01 parts by weight to about 99.9 parts by weight, about 0.1 parts by weight to about 99.9 parts by weight, about 1 part by weight to about 99.9 parts by weight, etc.). The solvent may be used alone, or in combination with two or more different types.

### <Optional Component>

The resist composition may further include, as needed, a surfactant, a crosslinking agent, a leveling agent, a colorant, or a combination thereof.

The resist composition may further include a surfactant to improve properties such as coating and development. Examples of surfactants are non-ionic surfactants such as polyoxyethylene lauryl ether, polyoxyethylene stearyl ether, polyoxyethylene oleyl ether, polyoxyethylene n-octylphenyl ether, polyoxyethylene n-nonylphenyl ether, polyethylene glycol dilaurate, and polyethylene glycol distearate. The surfactant may be either commercially available or synthetically produced. Examples of commercially available surfactants are KP341 (product of Shin-Etsu Chemical Co., Ltd.), Polyflow No. 75 and Polyflow No. 95 (products of Kyoeisha Chemical Co., Ltd.), F-Top EF301, F-Top EF303, and F-Top EF352 (products of Mitsubishi Materials Electronic Chemicals Co., Ltd.), MEGAFACE® F171, MEGAFACE® F173, R40, R41, R43 (products of DIC Corporation), Fluorad® FC430 and Fluorad® FC431 (products of 3M), AsahiGuard AG710 (product of AGC Inc.), and Surflon® S-382, Surflon® SC-101, Surflon® SC-102, Surflon® SC-103, Surflon® SC-104, Surflon® SC-105, and Surflon® SC-106 (products of AGC Seimi Chemical Co., Ltd.).

The surfactant may be included in an amount of about 0 parts by weight to about 20 parts by weight based on 100 parts by weight of the resist composition. The surfactant may be used alone, or in combination with two or more different types.

The method for preparing the resist composition is not particularly limited and may include, for example, mixing the polymer and any optional components in an organic solvent. The temperature and duration of mixing is not particularly limited. If necessary, filtration may be performed after mixing.

### [Pattern Formation Method]

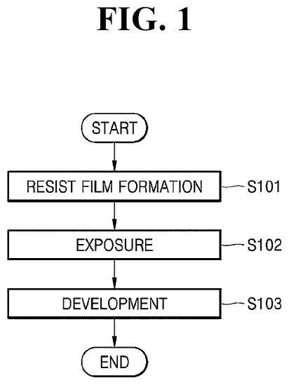

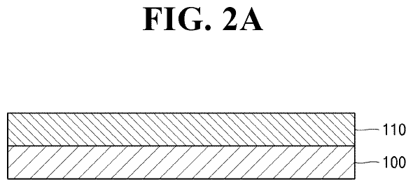

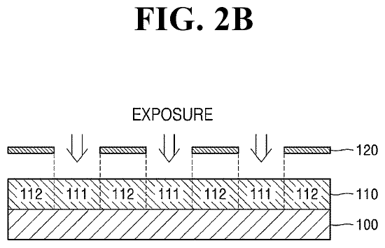

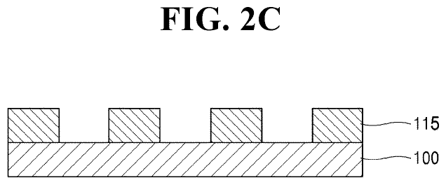

Hereinafter, the pattern forming method according to exemplary embodiments will be described in more detail with reference to FIGS. 1 and 2A to 2C. FIG. 1 is a flowchart showing a pattern forming method according to some example embodiments, and FIGS. 2A to 2C are side cross-sectional views showing the pattern forming method according to some example embodiments. Hereinafter, a specific example is given in which the resist composition is a positive resist composition, but the inventive concepts are not limited thereto.

Referring to FIG. 1, a pattern formation method may include: forming a resist film by applying a resist composition on a substrate (S101); exposing at least a portion of the resist film with high-energy rays to form an exposed resist film (S102); and developing an exposed resist film based on using a developer (S103). The operations may be omitted if necessary, and they may be performed in a different order.

First, referring to FIG. 1 and FIG. 2A, a substrate 100 is prepared. The substrate 100 may be, for example, a semiconductor substrate such as a silicon substrate or a germanium substrate, glass, quartz, ceramic, or copper. In some example embodiments, the substrate 100 may include Group Ill-V compounds such as GaP, GaAs or GaSb.

The resist composition may be applied to the substrate 100 to form a resist film 110 with a target thickness specifically by a coating method. The applied resist composition may be the resist composition as described herein according to any of the example embodiments. Accordingly, the resist film 110 may include the resist composition according to any of the example embodiments. If needed, a post application bake (PAB) may be performed to remove any organic solvent remaining on the resist film 110.

The coating method may use spin coating, dipping, roller coating or other common coating methods. Among these, particularly, spin coating may be used, and by adjusting the viscosity, concentration, and/or spin speed of the resist composition, the resist film 110 may have a target thickness. In some example embodiments, the thickness of the resist film 110 may be about 10 nm to about 300 nm. In some example embodiments, the thickness of the resist film 110 may be about 30 nm to about 200 nm.

The lower limit of the temperature of the PAB may be 60° C. or higher, for example, 80° C. or higher. In some example embodiments, the upper limit of the temperature of the PAB may be 150° C. or less, for example, 140° C. or less. The lower limit of the PAB time may be 5 seconds or more, for example, 10 seconds or more. The upper limit of the PAB time may be 600 seconds or less, for example, 300 seconds or less.

Before applying the resist composition to the substrate 100, a sacrificial layer (not shown) for etching purposes may also be formed on the substrate 100. The sacrificial layer may refer to a layer where an image is transferred from the resist pattern, thereby transforming into a desired pattern. In some example embodiments, the sacrificial layer may be formed to include insulating materials such as silicon oxide, silicon nitride, or silicon oxynitride. In some example embodiments, the sacrificial layer may be formed to include conductive materials such as metals, metal nitrides, metal silicides, or metal silicide nitride films. In some example embodiments, the sacrificial layer may be formed to include a semiconductor material such as polysilicon.

In some example embodiments, an anti-reflection film may be further formed on the substrate 100 to increase or maximize the efficiency of the resist. The anti-reflection film may be an organic or inorganic anti-reflection film.

In some example embodiments, a protective film may be further provided on the resist film 110 to reduce effects of alkaline impurities included in operations. In some example embodiments, in the case of immersion exposure, for example, a protective film for immersion may be provided on the resist film 110 to avoid direct contact between an immersion medium and the resist film 110.

Next, referring to FIG. 1 and FIG. 2B, at least a portion of the resist film 110 may be exposed to high-energy rays, thereby establishing an exposed resist film. In some example embodiments, high-energy rays passing through a mask 120 may be irradiated onto at least a portion of the resist film 110. For this reason, based on the exposing, the resist film 110 (e.g., the exposed resist film) may have an exposed portion 111 and an unexposed portion 112.

Although not confined to a particular theory, radicals may be generated in the exposed portion 111 through exposure. From the radicals, polar functional groups may be produced, resulting in potentially altering the physical properties of the resist composition.

Accordingly, the exposed portion 111 and the unexposed portion 112 may have different water contact angles, and the difference between the water contact angle of the unexposed portion 112 and the water contact angle of the exposed portion 111 may be 25° or more, for example, 40° or more, for example, 50° or more, and for example, 60° or more and may be 180° or less, for example 120° or less, for example 90° or less.

In some example embodiments, the exposure dose of the exposure may be 100 mJ/cm² or less, for example, 80 mJ/cm² or less, for example, 60 mJ/cm² or less, for example, 50 mJ/cm² or less and may be greater than 0 mJ/cm², for example 0.01 mJ/cm² or more, for example 0.1 mJ/cm² or more, for example 1 mJ/cm² or more, and the difference between the water contact angle of the unexposed portion 112 and the water contact angle of the exposed portion 111 may be 25° or more, for example, 40° or more, for example, 50° or more, for example, 60° or more and may be 180° or less, for example 120° or less, for example 90° or less.

When the exposure dose of the exposure is 100 mJ/cm² or less and greater than 0 mJ/cm², for example 0.01 mJ/cm² to 100 mJ/cm², for example 0.1 mJ/cm² to 100 mJ/cm², for example 1 mJ/cm² to 100 mJ/cm², the difference between the water contact angle of the unexposed portion 112 and the water contact angle of the exposed portion 111 may be 25° or more, for example, 30° or more and may be 180° or less, for example 120° or less, for example 90° or less, and in particular, when the exposure dose of the exposure is 80 mJ/cm² or less and greater than 0 mJ/cm², for example 0.01 mJ/cm² to 80 mJ/cm², for example 0.1 mJ/cm² to 80 mJ/cm², for example 1 mJ/cm² to 80 mJ/cm², the difference between the water contact angle of the unexposed portion 112 and the water contact angle of the exposed portion 111 may be 25° or more, for example, 30° or more and may be 180° or less, for example 120° or less, for example 90° or less.

In some cases, the exposure may be performed by (e.g., based on) irradiating high-energy rays through a mask 120 with a certain pattern using a liquid such as water as a medium. Examples of the high-energy rays are: electromagnetic waves, such as ultraviolet ray, far-ultraviolet rays (DUV), extreme ultraviolet rays (EUV rays, wavelength of 13.5 nm), X-rays, γ-rays, and the like; charged particle beams, such as electron beams (Ebs), α rays, and the like; and the like. Irradiation of these high-energy rays may be collectively referred to as “exposure.”

As the exposure light sources, various options may be utilized: lasers radiating light in the ultraviolet region, such as a KrF excimer laser (wavelength 248 nm), an ArF excimer laser (wavelength 193 nm), an F₂ excimer laser (wavelength 157 nm); radiating harmonic laser light in the deep ultraviolet region or vacuum ultraviolet region by wavelength conversion of laser light from solid-state laser sources (such as YAG or semiconductor lasers); and irradiating Ebs or extreme ultraviolet (EUV) radiation. During exposure, the exposure may be usually performed through a mask corresponding to a desired pattern, but when exposure light is an EB, the exposure may be performed through direct writing without using a mask.

The integrated dose of high-energy rays, for example, when using extreme ultraviolet rays as high-energy rays, may be 2000 mJ/cm² or less, for example, 500 mJ/cm² or less. In addition, when Ebs are used as the high-energy rays, the integral dose may be 5,000 μC/cm² or less, or 1,000 μC/cm² or less.

Additionally, post exposure bake (PEB) may be performed. The lower limit of the temperature of PEB may be 50° C. or more, for example, 80° C. or more. The upper limit of the PEB temperature may be 250° C. or lower, for example, 200° C. or lower. The lower limit of the time of the PEB time may be 5 seconds or more, for example, 10 seconds or more. The upper limit of the time of the PEB may be 600 seconds or less, for example, 300 seconds or less.

Next, referring to FIG. 1 and FIG. 2C, the resist film 110 which has been exposed may be developed by using a developer. The unexposed portion 112 or the exposed portion 111 may be washed away and removed by the developer, and the remaining portion of the exposed resist film 110 (which may be the unexposed portion 112 or the exposed portion 111) may remain without being washed away by the developer. The resultant structure as shown in FIG. 2C may be and/or may define a resist pattern 115.

Examples of the developer are distilled water, an alkaline developer, and a developer containing an organic solvent (hereinafter also referred to as “organic developer”). Examples of a developing method are a dipping method, a puddle method, a spray method, a dynamic injection method, and the like. A developing temperature may be, for example, about 5° C. or more and about 60° C. or less, and a developing time may be, for example, about 5 seconds or more and about 300 seconds or less.

The alkaline developer may include, for example, an alkaline aqueous solution in which one or more alkaline compounds such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethyamine, ethyldimethylamine, triethanolamine, tetramethyl ammonium hydroxide (TMAH), pyrrole, piperidine, choline, 1,8-diazabicyclo[5.4.0]-7-undecene (DBU), and 1,5-diazabicyclo[4.3.0]-5-nonene (DBN) are dissolved. The alkaline developer may further include a surfactant.

A lower limit of an amount of the alkaline compound included in the alkaline developer may be 0.1 wt % or more, 0.5 wt % or more, or 1 wt % or more. Additionally, an upper limit of the amount of the alkaline compound included in the alkaline developer may be 20 wt % or less, 10 wt % or less, or 5 wt % or less.

Examples of the organic solvent included in the organic developer are the same organic solvents as those exemplified in the part of <Solvent> of [Resist composition].

Alternatively, as an organic solvent, alcohol-based solvents or lactate-based solvents may be used.

Examples of alcohol-based solvents are: monoalcohol solvents such as methanol, ethanol, n-propanol, isopropanol, 1-methoxy-2-propanol, 1-ethoxy-2-propanol, n-butanol, isobutanol, sec-butanol, tert-butanol, n-pentanol, isopentanol, 2-methylbutanol, sec-pentanol, tert-pentanol, 3-methoxybutanol, 3-methyl-3-methoxybutanol, n-hexanol, 2-methylpentanol, sec-hexanol, 2-ethylbutanol, 4-methyl-2-pentanol (MIBC), sec-heptanol, 3-heptanol, n-octanol, 2-ethylhexanol, sec-octanol, n-nonylalcohol, 2,6-dimethyl-4-heptanol, n-decanol, sec-undecyl alcohol, trimethylnonyl alcohol, sec-tetradecyl alcohol, sec-heptadecyl alcohol, furfuryl alcohol, phenol, cyclohexanol, methylcyclohexanol, 3,3,5-trimethylcyclohexanol, benzyl alcohol, and diacetone alcohol; polyhydric alcohol solvents such as ethylene glycol, 1,2-propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol, and tripropylene glycol; and polyhydric alcohol-containing ether solvents, such as ethylene glycol monomethyl ether, ethylene glycol monoethyl ether, ethylene glycol monopropyl ether, ethylene glycol monobutyl ether, ethylene glycol monohexyl ether, ethylene glycol monophenyl ether, ethylene glycol mono-2-ethylbutyl ether, diethylene glycol monomethyl ether, diethylene glycol monoethyl ether, diethylene glycol monopropyl ether, diethylene glycol monobutyl ether, diethylene glycol monohexyl ether, propylene glycol monomethyl ether (PGME), propylene glycol monoethyl ether, propylene glycol monopropyl ether, propylene glycol monobutyl ether, dipropylene glycol monomethyl ether, dipropylene glycol monoethyl ether, and dipropylene glycol monopropyl ether.

Examples of lactate-based solvents are methyl lactate, ethyl lactate, n-butyl lactate, and n-amyl lactate.

In some example embodiments, nBA (n-butyl acetate), PGME, PGMEA, ethyl lactate, GBL (γ-butyrolactone), and IPA (isopropanol) may be used as the organic developer. The organic developer may further include organic acids such as acetic acid, formic acid, and citric acid.

The lower limit of the organic solvent content in the organic developer may be 80 wt % or more, for example, 90 wt % or more, for example, 95 wt % or more, for example, 99 wt % or more.

In some example embodiments, the developer may include distilled water, an alkaline developer, or any combination thereof, and the exposed portion 111 may be removed by the developer.

The organic developer may include a surfactant. In some example embodiments, the organic developer may include trace amounts of moisture. In some example embodiments, during development, the development process may be stopped by substituting a different type of solvent for the organic developer.

The resist pattern after development may be further cleaned. Cleaning liquids such as ultrapure water and a rinse solution may be used. There are no particular restrictions on the rinse solution as long as the resist pattern is not dissolved, and solutions containing common organic solvents are used. In some example embodiments, the rinse liquid may be an alcohol-based solvent or an ester-based solvent. After cleaning, any remaining rinse solution on the substrate and pattern may be removed. When ultrapure water is used, any remaining water on the substrate and pattern may be removed.

In addition, the developer may be used alone or in combination of two or more types.

As described above, after forming the resist pattern, a patterned wiring substrate may be obtained by etching. The etching method may be performed by known methods such as dry etching using plasma gas, and wet etching using alkaline solutions, copper (II) chloride solutions, or iron (II) chloride solutions.

After forming the resist pattern, plating may also be performed. The plating method is not particularly limited, but examples thereof are copper plating, solder plating, nickel plating, and gold plating.

The remaining resist pattern after etching may be stripped using an organic solvent. The organic solvent is not particularly limited, and examples thereof are PGMEA, PGME, ethyl lactate (EL), and the like. The stripping method is not particularly limited and examples thereof are immersion methods and spray methods. Additionally, the wiring substrate with the resist pattern formed may be a multilayer wiring substrate and may have small-diameter through holes.

In some example embodiments, the wiring substrate is formed by depositing metal in a vacuum after forming the resist pattern, and then dissolving the resist pattern in a solution, a method known as the lift-off method.

Although not shown, the resist composition may be a negative composition. When the resist composition is a negative composition, the developer contains an organic solvent, and the unexposed portion 112 may be removed by the developer.

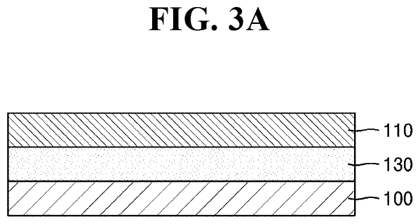

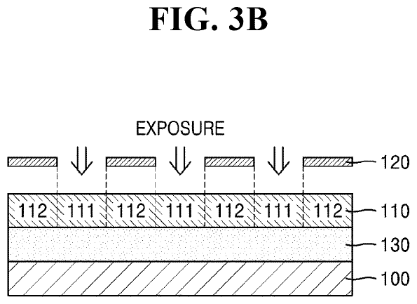

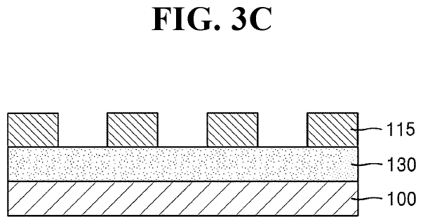

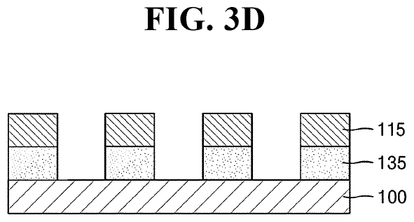

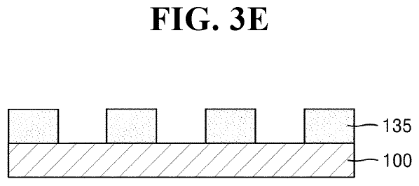

FIGS. 3A, 3B, 3C, 3D, and 3E are side cross-sectional views showing a method of forming a patterning structure according to some example embodiments.

As shown in FIG. 3A, a material layer 130 may be formed on the substrate 100 before forming the resist film 110 on the substrate 100. The resist film 110 may be formed on top of the material layer 130. The material layer 130 may include an insulating material (for example, silicon oxide, silicon nitride), a semiconductor material (for example, silicon), or a metal (for example, copper). In some example embodiments, the material layer 130 may have a multi-layer structure. The material of the material layer 130 may be different from the material of the substrate 100.

As shown in FIG. 3B, the resist film 110 may undergo a prebake process before exposure and then be exposed to high-energy rays through the mask 120, and subsequently the resist film 110 may include an exposed portion 111 and an unexposed portion 112.

As shown in FIG. 3C, the resist film 110 which is exposed may be developed using a developer. The exposed portion 111 may be washed away by the developer, while the unexposed portion 112 remains intact to define the resist pattern 115.

As shown in FIG. 3D, the pattern of the resist film (e.g., resist pattern 115) may act as a mask for etching the exposed portions of the material layer 130 to form the material pattern 135 on the substrate 100.

As shown in FIG. 3E, the pattern of the resist film (e.g., resist pattern 115) may be removed.

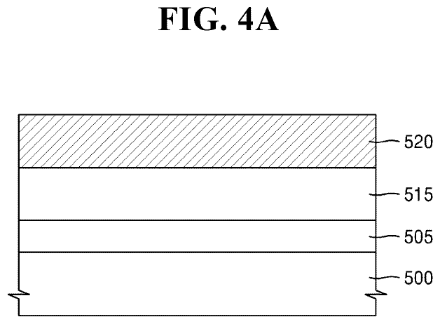

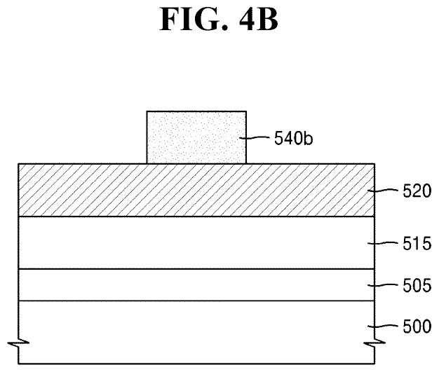

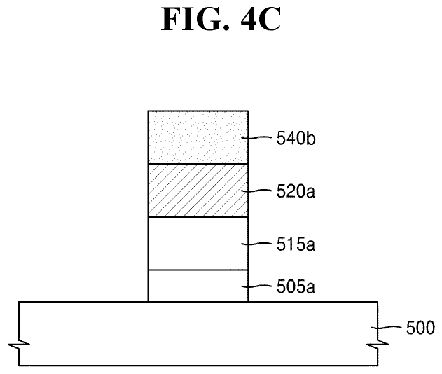

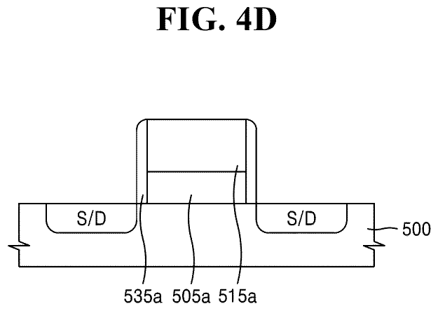

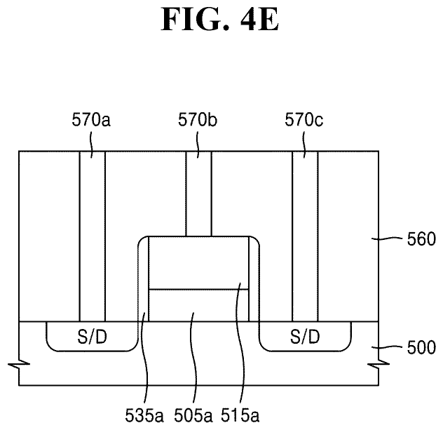

FIGS. 4A, 4B, 4C, 4D, and 4E are side cross-sectional views showing a method of forming a semiconductor device according to some example embodiments.

As shown in FIG. 4A, a gate dielectric 505 (for example, silicon oxide) may be formed on the substrate 500. The substrate 500 may be a semiconductor substrate such as a silicon substrate. A gate layer 515 (for example, doped polysilicon) may be formed on gate dielectric 505. A hard mask layer 520 may be formed on the gate layer 515.

As shown in FIG. 4B, a resist pattern 540b may be formed on the hard mask layer 520. The resist pattern 540b may be formed using a resist composition according to some example embodiments. The resist composition may include an organic solvent.

As shown in FIG. 4C, the gate layer 515 and the gate dielectric 505 may be etched to form a hard mask pattern 520a, a gate electrode pattern 515a, and a gate dielectric pattern 505a.

As shown in FIG. 4D, a spacer layer may be formed on the gate electrode pattern 515a and the gate dielectric pattern 505a. The spacer layer may be formed using a deposition process (for example, CVD). The spacer layer may be etched to form spacers 535a (for example, silicon nitride) on the sidewalls of the gate electrode pattern 515a and the gate dielectric pattern 505a. After forming the spacers 535a, ions may be implanted into the substrate 500 to form source/drain impurity regions (S/D).

As shown in FIG. 4E, an interlayer insulating film 560 (for example, an oxide) may be formed on the substrate 500, covering the gate electrode pattern 515a, gate dielectric pattern 505a, and spacers 535a. Subsequently, the interlayer insulating film 560 may have electrical contacts 570a, 570b, and 570c formed to connect with the gate electrode pattern 515a and the S/D regions. The electrical contacts 570a, 570b, and 570c may include a conductive material (for example, metal). Although not shown, a barrier layer may be formed between the sidewalls of the interlayer insulating film 560 and the electrical contacts 570a, 570b, and 570c.

FIGS. 4A to 4E show examples of forming transistors, but the inventive concepts are not limited thereto.

The resist composition according to some example embodiments may be used in the patterning process to form other types of semiconductor devices.

While the inventive concepts will be described in more detail using the following examples and comparative examples, the technical scope of the inventive concepts are not limited to these examples.

### EXAMPLES

### Synthesis Example 1: Synthesis of M1

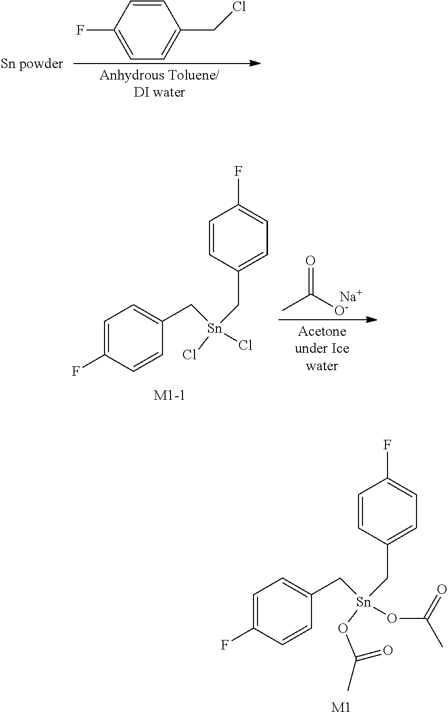

### (1) Synthesis of M1-1

8.2 g (69.2 mmol) of Sn powder and 120 ml of dry toluene were placed in a 250 ml three-necked flask, and the temperature was raised to 90° C. After adding about 1.0 ml of deionized water, 10.0 g (69.2 mmol) of 4-fluorobenzyl chloride was added dropwise over 10 minutes. The mixture was stirred while heating under reflux at 130° C. for 4 hours, and then unreacted Sn powder was filtered out using a Buchner funnel. Simultaneously, as the filtered solution cooled, the product, white crystals M1-1, was obtained in the amount of 6.5 g (yield of 36%).

### (2) Synthesis of M1

1.5 g (3.7 mmol) of M1-1 and 21.0 ml of dry acetone were placed in a 50 ml single-neck flask, and the temperature of the mixture was lowered to 0° C. After adding 0.6 g (7.4 mmol) of sodium acetate, the mixture was stirred for about 12 hours. The solution was filtered using a 0.45 μm filter to remove the NaCl salt formed in the solution. The filtered solution was then concentrated by rotary evaporation and vacuum-dried to obtain 1.6 g of M1 with a yield of 74%.

1H-NMR (500 MHz, DMSO-d6): δ ˜6.9 (8H), ˜2.6 (4H), ˜1.6 (6H)

### Synthesis Example 2: Synthesis of M2

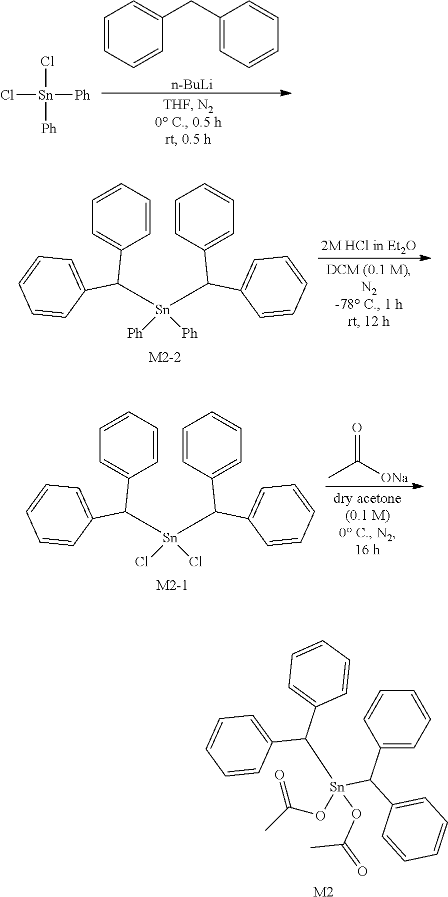

### (1) Synthesis of M2-2

In an N₂-substituted 2-necked round-bottom flask, diphenylmethane (4.89 g, 29.1 mmol) was added and diluted therein with THE (30 ml). n-BuLi (2.5 M in hexane, 29.1 mmol) was added dropwise into the round-bottom flask at −78° C. and stirred at 0° C. for 0.5 hours. Dichlorodiphenylstannane (5 g, 14.5 mmol) was added into a vial and diluted therein with THE (28 ml, total THE (58 ml, 0.25 M)). The solution in the vial was added dropwise into the round-bottom flask at −78° C. and stirred for 0.5 hours. Then, the reaction temperature was raised to room temperature, and the mixed solution was further stirred for 0.5 hours. After confirming the completion of the reaction, the solvent was removed, filtered with silica/celite, and purified by column chromatography (ethyl acetate (EA): n-hexane (EA 5 v %)) to obtain M2-2 (6.8 g, 77%).

### (2) Synthesis of M2-1

M2-2 (6.2 g, 10.2 mmol) was placed in a round bottom flask and substituted with N₂. After diluting with dichloromethane (102 ml, 0.1 M), 2M HCl in Et₂O solution (15.3 ml, 30.67 mmol) was added dropwise at −78° C. The mixture was stirred for 1 hour at −78° C., then warmed to room temperature and reacted for another 12 hours. After removing the solvent, the precipitate was washed with methyl t-butyl ether:n-hexane (5 ml:100 ml) and dried under vacuum to obtain M2-1 (4.3 g, 80%).

### (3) Synthesis of M2

M2-1 (1.0 g, 1.91 mmol) was placed in a round bottom flask and substituted with N₂. After diluting with acetone (19 ml, 0.1 M), sodium acetate (0.31 g, 3.82 mmol) was added at 0° C. The reaction was carried out for 16 hours at 0° C., then the reaction product was filtered using celite. After removing the solvent, recrystallization was performed (methyl t-butyl ether: n-hexane=3 ml:30 ml). After filtration, the precipitate was dried under vacuum to obtain M2 (0.54 g, 50%).

¹H NMR (500 MHz, CD₂Cl₂) δ 7.42-6.98 (m, 20H), 4.71 (s, 2H), 1.64 (s, 6H).

¹³C NMR (126 MHz, CD₂Cl₂) δ 182.13, 138.99, 129.41, 128.78, 126.68, 57.91, 19.88.

¹¹⁹Sn NMR (186 MHz, CD₂Cl₂) δ −345.10.

### Preparation Example: Preparation of Casting Solution

The organometallic compounds synthesized in Synthetic Examples 1 and 2 and additives were dissolved in cyclopentanone at 2 wt % to prepare casting solutions A-1 and A-2. In this regard, the weight ratio of the organometallic compound to the additive is 1:1.5.

Additionally, casting solution B-1 was prepared having the same composition as casting solution A-1 except that any additives are not included therein.

TABLE 1

| No. of | | | Organometallic | |
|---|---|---|---|---|
| casting | Organometallic | | compounds: additives | Casting |
| solution | compound | Additive | (weight ratio) | solvent |
| A-1 | M1 | A1 | 1:1.5 | Cyclo- |
| | | | | pentanone |
| A-2 | M2 | A1 | 1:1.5 | Cyclo- |
| | | | | pentanone |
| B-1 | M1 | — | — | Cyclo- |
| | | | | pentanone |

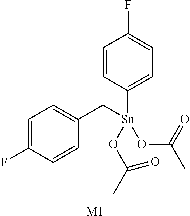

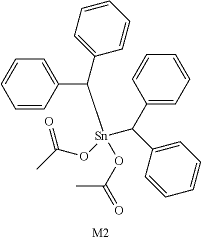

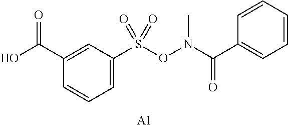 [SMILES: CN(OS(=O)(=O)c1cccc(C(=O)O)c1)C(=O)c1ccccc1 ; "A1"]

### Evaluation Example 1: FT-IR Analysis

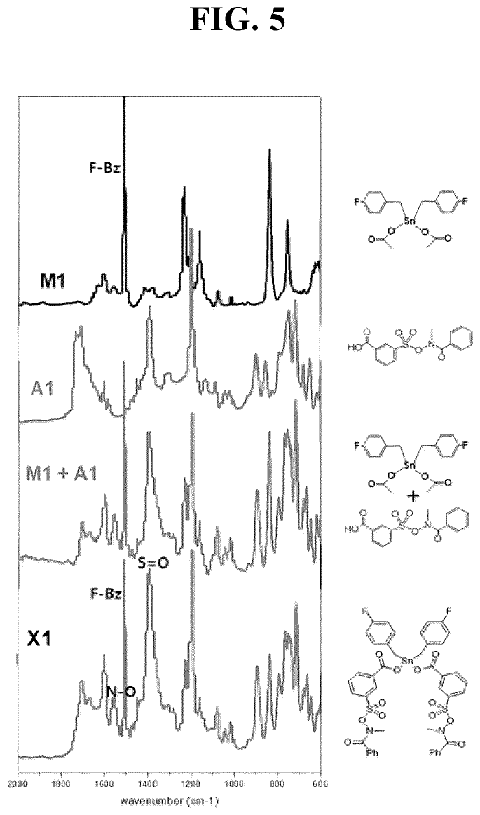

A solution of compound M1, compound A1, a mixture of compound M1 and compound A1, and compound X1 each dissolved in cyclopentanone was applied onto an Au-coated Si wafer to a thickness of 50 nm, and then dried to prepare a sample, after which FT-IR analysis was performed. Results thereof are shown in FIG. 5.

Referring to FIG. 5, the characteristic peaks of M1 and A1 were also observed in both the mixture of M1 and A1 and in X₁. As a result, it was confirmed that the ligand of M1 was exchanged with A1 in the mixture of M1 and A1 to form X₁.

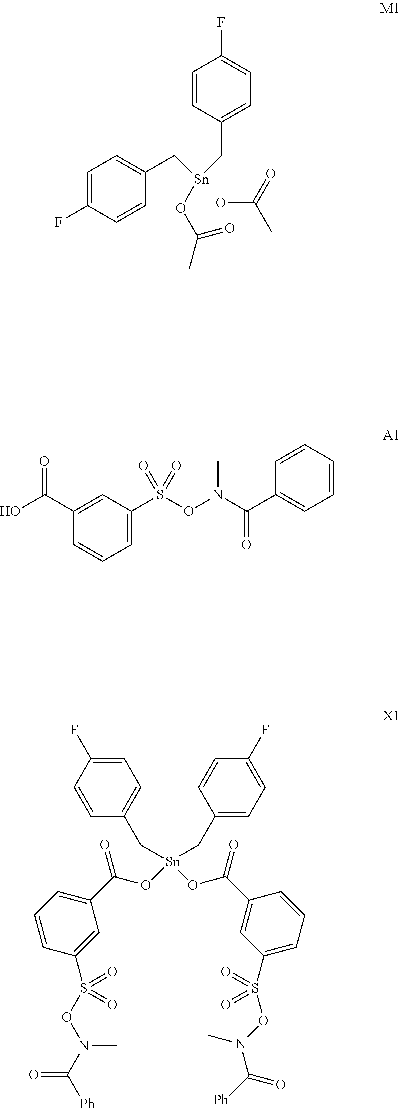

### Evaluation Example 2: Thin Film Stability Evaluation

A silicon wafer with an 8-inch diameter was cut into quarters, then treated with O₂ plasma for 30 minutes. Casting solutions A-1, A-2, and B-1 were each used for spin-coating at 1200 rpm for 1 minute, followed by PAB at 100° C. for 1 minute to create films with the following preset initial thicknesses. Then, the thickness of these films was measured again after 5, 10, 20, and 30 days, and the thicknesses were expressed as relative values to the initial thickness in Table 2 below.

TABLE 2

| No. of | Initial | 5 | 10 | 20 | 30 |
|---|---|---|---|---|---|
| casting | thickness | days | days | days | days |
| solution | (%) | (%) | (%) | (%) | (%) |
| A-1 | 100 | 99.2 | 99.7 | 99.5 | 99.5 |
| A-2 | 100 | 100.3 | 100.0 | 100.0 | 100.0 |
| B-1 | 100 | 83.1 | 82.3 | 78.6 | 74.8 |

Referring to Table 2 above, in the case of B-1 without additives, the thin film thickness significantly decreased over time after coating, confirming low thin film stability. However, in the cases of A-1 and A-2 with additives, the thin film thickness remained the same or substantially the same over time after coating, confirming relatively high thin film stability.

### Evaluation Example 3: Thin Film Development Evaluation

### (1) Terminology

For Examples 1-1 and 1-2, E₀ refers to the exposure dose at which the thin film is completely developed (the film thickness no longer decreases), and E₁ refers to the exposure dose at which the thin film begins to develop.

For Comparative Examples 1-1, 1-2, and Example 2-1, E₀ refers to the exposure dose at which the thin film begins to cure, and E₁ refers to the exposure dose at the saturation point where the film no longer thickens.

γ is the contrast curve, calculated using the following Equation 1.

$$γ = {[ log ( \frac{{E}_{0}}{{E}_{1}} ) ]}^{- 1} \qquad 〈 Equation 1 〉$$

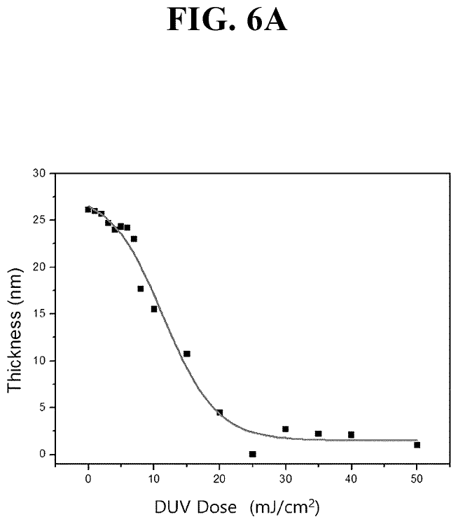

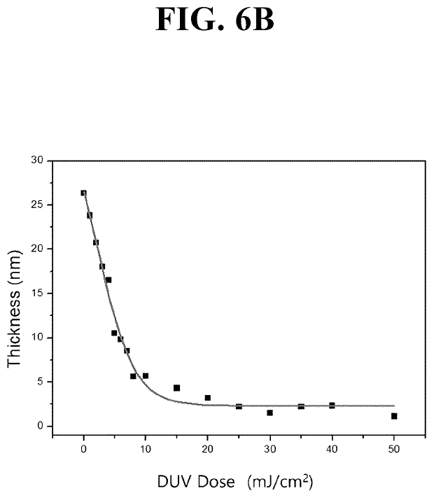

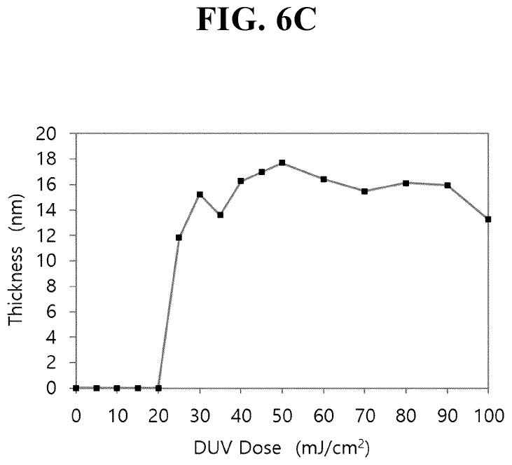

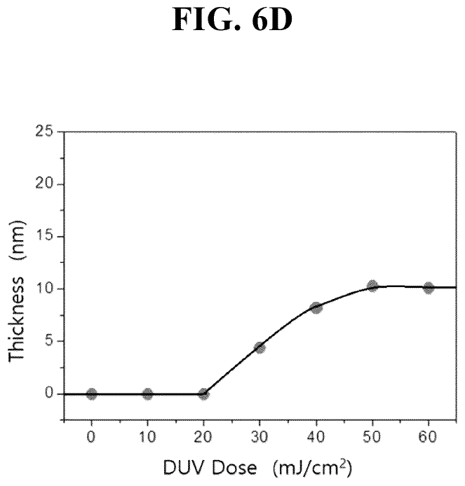

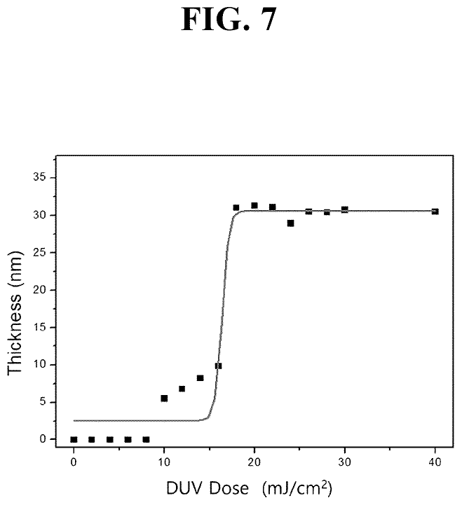

A silicon wafer with an 8-inch diameter was cut into quarters, then treated with O₂ plasma for 30 minutes. Casting solutions A-1, A-2, and B-1 were each used for spin-coating at 1200 rpm for 1 minute, followed by PAB at 100° C. for 1 minute to create films with the following preset initial thicknesses. Subsequently, a 1 cm thick mask (4 cm x 4 cm) with rectangular holes (1 cm×1 cm) was placed thereon, and each hole was exposed to 254 nm wavelength DUV rays with doses ranging from 0 mJ/cm² to 100 mJ/cm², followed by PEB at 100° C. for 1 minute. The dried films were immersed in deionized water (DC), PGME:PGMEA (98:2 wt %), or PGMEA as developers for 60 seconds at 25° C. The remaining film thicknesses were measured and shown in FIGS. 6A to 6D and 7. FIG. 6A represents Example 1-1, FIG. 6B represents Example 1-2, FIG. 6C represents Comparative Example 1-1, FIG. 6D represents Comparative Example 1-2, and FIG. 7 represents Example 2-1, showing the changes in film thickness after development according to the dose.

TABLE 3

| | | Organo- | | | Coating | | | | | | | |
|---|---|---|---|---|---|---|---|---|---|---|---|---|
| | Casting | metallic | | PAB | speed | | PEB | | | | | |
| | solution | compound | Additive | (° C.) | (rpm) | Developer | (° C.) | tone | E₀ | E₁ | γ | Graph |
| Example 1-1 | A-1 | M1 | A1 | 100 | 1500 | DI | 100 | PTD | 21 | 8 | 2.4 | FIG. |
| | | | | | | | | | | | | 6A |
| Example 1-2 | A-2 | M2 | A1 | 100 | 1500 | DI | 100 | PTD | 16 | 2 | 1.1 | FIG. |
| | | | | | | | | | | | | 6B |
| Comparative | B-1 | M1 | — | 100 | 1200 | PGMEA:AA | 180 | NTD | 20 | 30 | −5.7 | FIG. |
| Example 1-1 | | | | | | (98:2 wt %) | | | | | | 6C |
| Comparative | B-1 | M1 | — | 100 | 1200 | PGMEA:AA | 160 | NTD | 20 | 50 | −2.5 | FIG. |
| Example 1-2 | | | | | | (98:2 wt %) | | | | | | 6D |
| Example 2-1 | A-1 | M1 | A1 | 100 | 1200 | PGMEA | 100 | NTD | 15 | 20 | −8.0 | FIG. |
| | | | | | | | | | | | | 7 |

Referring to FIGS. 6A to 6D and 7, casting solutions A-1 and A-2 containing additives showed characteristics of either positive-type or negative-type resist compositions depending on the polarity of the developer. In contrast, casting solution B-1 without additives did not allow removal of the exposed areas even when the polarity of the developer was changed.

### Evaluation Example 4: Water Contact Angle (WCA) Evaluation

A silicon wafer with an 8-inch diameter was cut into quarters, treated with O₂ plasma, and then casting solutions A-1 and A-2 were each used for spin-coating at 1200 rpm for 1 minute, followed by drying (PAB) at 100° C. for 1 minute to create a film with the initial thickness of 40 nm. Subsequently, a 1 cm-thick mask (4 cm×4 cm) with rectangular holes (1 cm×1 cm) was placed thereon, and each hole was exposed to 254 nm wavelength DUV rays with doses ranging from 0 mJ/cm² to 100 mJ/cm², followed by drying (PEB) at 170° C. for 90 seconds. Then, 3 μL of water was dropped onto each hole, and the water contact angle (unit: °) was measured. The results (e.g., the respective water contact angles (unit: °) for the films formed from casting solutions A-1 and A-2) are shown in Table 4 below.

TABLE 4
Water Contact Angles for films formed from casting solutions according to DUV ray dosage

| | Organo- | | | | | | | | | | | | |
|---|---|---|---|---|---|---|---|---|---|---|---|---|---|
| Casting | metallic | | Dose (mJ/cm²) | | | | | | | | | | |
| solution | compound | Additive | 0 | 10 | 20 | 30 | 40 | 50 | 60 | 70 | 80 | 90 | 100 |
| A-1 | M1 | A1 | 82.4° | 69.7° | 63.9° | 62° | 63.9° | 43.6° | 36.9° | 24.5° | 22.5° | 20.5° | 18.4° |
| A-2 | M2 | A1 | 79.5° | Not | Not | Not | Not | Not | Not | Not | Not | Not | <10 |
| | | | | avail- | avail- | avail- | avail- | avail- | avail- | avail- | avail- | avail- | |
| | | | | able | able | able | able | able | able | able | able | able | |

Referring to Table 4, resist compositions A-1 containing M1 and A1 and resist compositions A-2 containing M2 and A1 each showed a significant change in water contact angle values before and after DUV irradiation, confirming that a change in polarity had occurred in the organometallic compounds.

Some example embodiments of the inventive concepts can provide a resist composition with improved storage stability and enhanced sensitivity, offering patterns with improved resolution, thereby enabling the formation of a semiconductor device having improved pattern resolutions, thereby enabling miniaturization of semiconductor devices with improved device reliability based on the reduced likelihood of device defects due to reduced likelihood of defects resulting from low pattern resolution.

It should be understood that example embodiments described herein should be considered in a descriptive sense only and not for purposes of limitation. Descriptions of features or aspects within each example embodiment should typically be considered as available for other similar features or aspects in other example embodiments. While some example embodiments have been described with reference to the drawings, it will be understood by those of ordinary skill in the art that various changes in form and details may be made therein without departing from the spirit and scope as defined by the following claims.

What is claimed is:

1. A resist composition, comprising:
an organometallic compound represented by Formula 1; and
an additive represented by Formula 2: 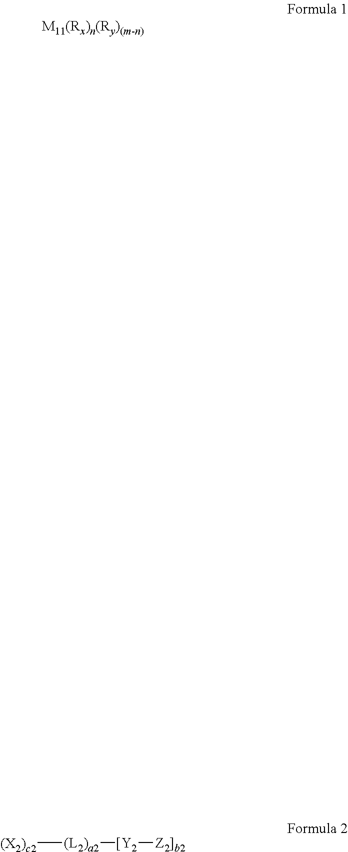
wherein, in Formulae 1 and 2,
M₁₁ is indium (In), tin (Sn), antimony (Sb), tellurium (Te), thallium (Tl), lead (Pb), bismuth (Bi), or polonium (Po),
Rₓ is *—X₁—Y₁,
R_{y} is *-(L₁)ₐ₁-(R₁)_{b1},
n is an integer from 1 to 6,
m is an integer from 1 to 6,
m-n is 0 or more,
Formula 1 optionally includes a plurality of Rₓ based on n being greater than 1, the plurality of Rₓ identical to or different from each other,
Formula 1 optionally includes a plurality of R_{y} based on m-n being greater than 1, the plurality of R_{y} identical to or different from each other,
X₁ is O, OC(═O), C(═O)O, OS(═O), S(═O)O, OS(═O)₂, S(═O)₂O, S, SC(═O), or C(═O)S,
Y₁ is hydrogen, deuterium, or a linear, branched, or cyclic C₁-C₃₀ monovalent hydrocarbon group that optionally includes a heteroatom,
L₁ is a linear, branched, or cyclic C₁-C₃₀ divalent hydrocarbon group that optionally includes a heteroatom,
a1 is an integer from 0 to 4,
R₁ is a linear, branched, or cyclic C₁-C₃₀ monovalent hydrocarbon group that optionally includes a heteroatom,
b1 is an integer from 1 to 4, wherein Formula 1 optionally includes a plurality of R₁ based on b1 being greater than 1, two adjacent groups among the plurality of R₁ optionally bonded to each other to form a ring,
X₂ is OH, SH, C(═O)OH, S(═O)OH, S(═O)₂OH, or P(═O)(OH)₂,
c2 is an integer from 1 to 4,
each L₂ is independently a linear, branched, or cyclic C₁-C₃₀ divalent hydrocarbon group that optionally includes a heteroatom,
a2 is an integer from 0 to 4,
Y₂—Z₂ is a photo-reactive unit,
b2 is an integer from 1 to 4, and
* is a bonding site to a neighboring atom of Formula 1.

2. The resist composition of claim 1, wherein, in Formula 1,
M₁₁ is Sn, Sb, Te, or Bi.

3. The resist composition of claim 1, wherein, in Formula 1,
X₁ is O, OC(═O), C(═O)O, S, SC(═O), or C(═O)S, and
Y₁ is selected from: hydrogen, deuterium, a C₁-C₃₀ alkyl group, a C₁-C₃₀ halogenated alkyl group, a C₁-C₃₀ alkoxy group, a C₁-C₃₀ alkylthio group, a C₁-C₃₀ halogenated alkoxy group, a C₁-C₃₀ halogenated alkylthio group, a C₃-C₃₀ cycloalkyl group, a C₃-C₃₀ cycloalkoxy group, a C₃-C₃₀ cycloalkylthio group, a C₃-C₃₀ heterocycloalkyl group, a C₂-C₃₀ alkenyl group, a C₃-C₃₀ cycloalkenyl group, a C₃-C₃₀ heterocycloalkenyl group, a C₂-C₃₀ alkynyl group, a C₆-C₃₀ aryl group, a C₆-C₃₀ aryloxy group, a C₆-C₃₀ arylthio group, a C₇-C₃₀ arylalkyl group, a C₁-C₃₀ heteroaryl group, a C₁-C₃₀ heteroaryloxy group, a C₁-C₃₀ heteroarylthio group, and a C₂-C₃₀ heteroarylalkyl group, wherein each of the C₁-C₃₀ alkyl group, the C₁-C₃₀ halogenated alkyl group, the C₁-C₃₀ alkoxy group, the C₁-C₃₀ alkylthio group, the C₁-C₃₀ halogenated alkoxy group, the C₁-C₃₀ halogenated alkylthio group, the C₃-C₃₀ cycloalkyl group, the C₃-C₃₀ cycloalkoxy group, the C₃-C₃₀ cycloalkylthio group, the C₃-C₃₀ heterocycloalkyl group, the C₂-C₃₀ alkenyl group, the C₃-C₃₀ cycloalkenyl group, the C₃-C₃₀ heterocycloalkenyl group, the C₂-C₃₀ alkynyl group, the C₆-C₃₀ aryl group, the C₆-C₃₀ aryloxy group, the C₆-C₃₀ arylthio group, the C₇-C₃₀ arylalkyl group, the C₁-C₃₀ heteroaryl group, the C₁-C₃₀ heteroaryloxy group, the C₁-C₃₀ heteroarylthio group, and the C₂-C₃₀ heteroarylalkyl group is unsubstituted or substituted with deuterium, a halogen, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or any combination thereof.

4. The resist composition of claim 1, wherein, in Formula 1,
L₁ is a single bond, a substituted or unsubstituted C₁-C₃₀ alkylene group, a substituted or unsubstituted C₃-C₃₀ cycloalkylene group, a substituted or unsubstituted C₃-C₃₀ heterocycloalkylene group, a substituted or unsubstituted C₂-C₃₀ alkenylene group, a substituted or unsubstituted C₃-C₃₀ cycloalkenylene group, a substituted or unsubstituted C₃-C₃₀ heterocycloalkenylene group, a substituted or unsubstituted C₆-C₃₀ arylene group, or a substituted or unsubstituted C₁-C₃₀ heteroarylene group,
a1 is 0, 1, or 2, and
R₁ is selected from a C₁-C₃₀ alkyl group, a C₃-C₃₀ cycloalkyl group, a C₃-C₃₀ heterocycloalkyl group, a C₂-C₃₀ alkenyl group, a C₃-C₃₀ cycloalkenyl group, a C₃-C₃₀ heterocycloalkenyl group, a C₂-C₃₀ alkynyl group, a C₆-C₃₀ aryl group, a C₇-C₃₀ arylalkyl group, a C₁-C₃₀ heteroaryl group, and a C₂-C₃₀ heteroarylalkyl group, wherein each of the C₁-C₃₀ alkyl group, the C₃-C₃₀ cycloalkyl group, the C₃-C₃₀ heterocycloalkyl group, the C₂-C₃₀ alkenyl group, the C₃-C₃₀ cycloalkenyl group, the C₃-C₃₀ heterocycloalkenyl group, the C₂-C₃₀ alkynyl group, the C₆-C₃₀ aryl group, the C₇-C₃₀ arylalkyl group, the C₁-C₃₀ heteroaryl group, and the C₂-C₃₀ heteroarylalkyl group is unsubstituted or substituted with deuterium, a halogen, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or any combination thereof.

5. The resist composition of claim 1, wherein
the organometallic compound represented by Formula 1 is selected from Group I: 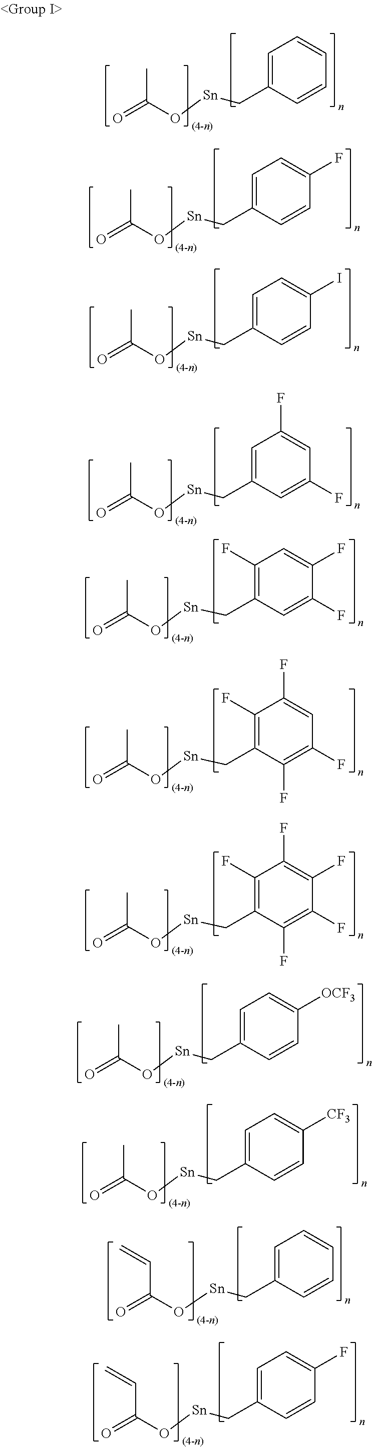 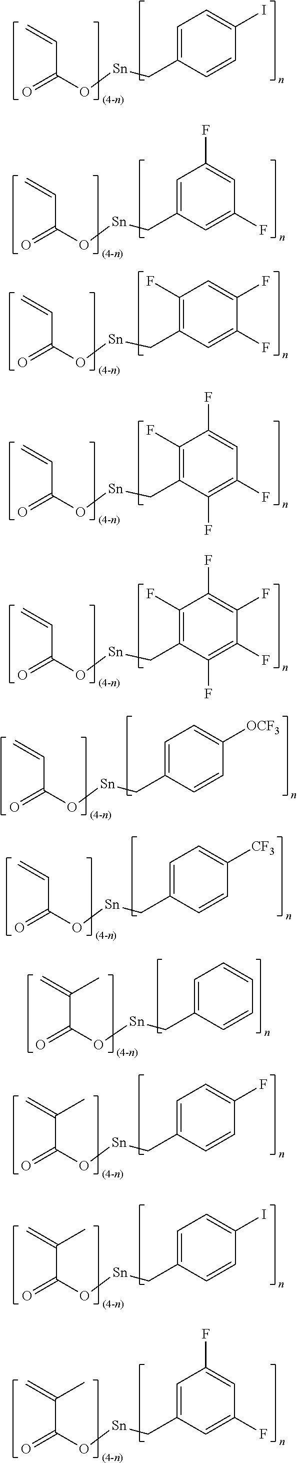 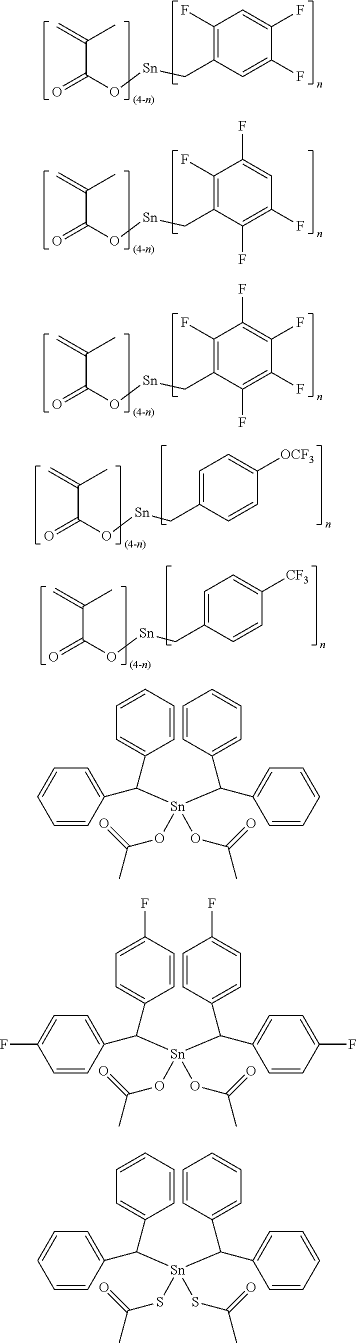 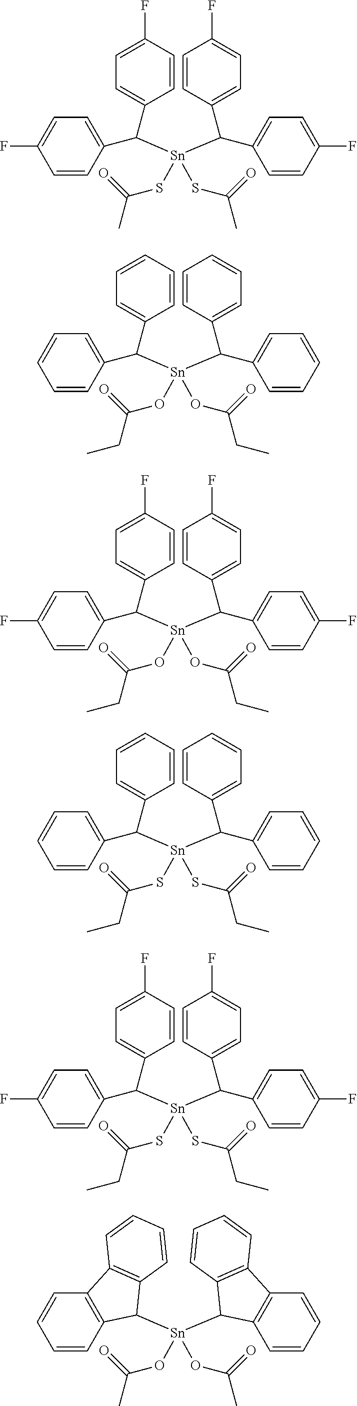 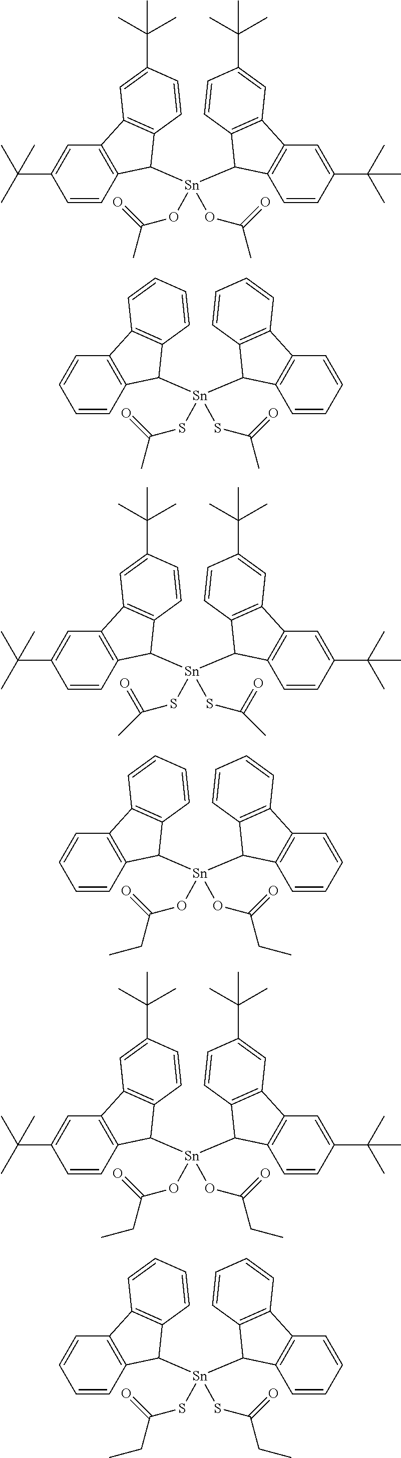 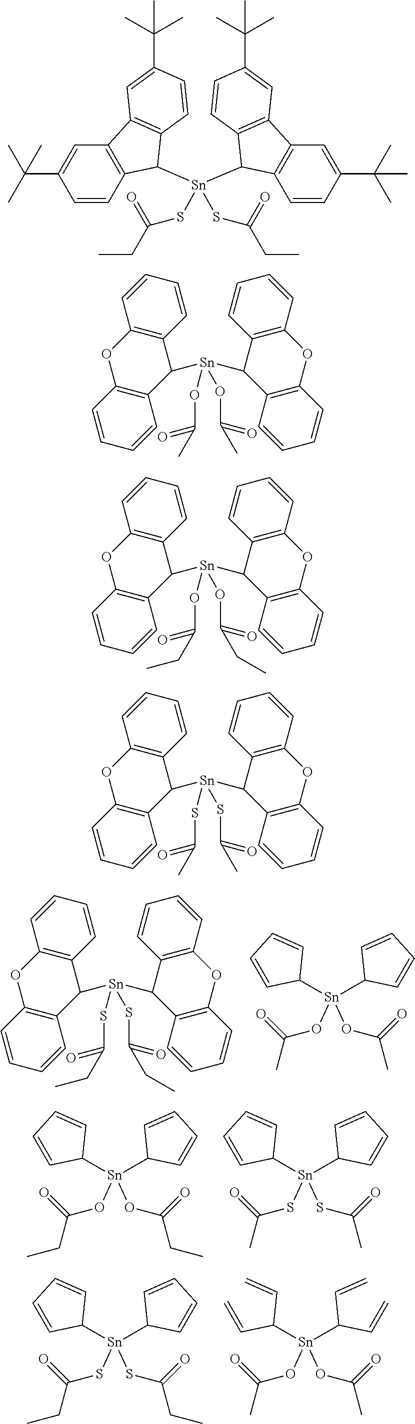 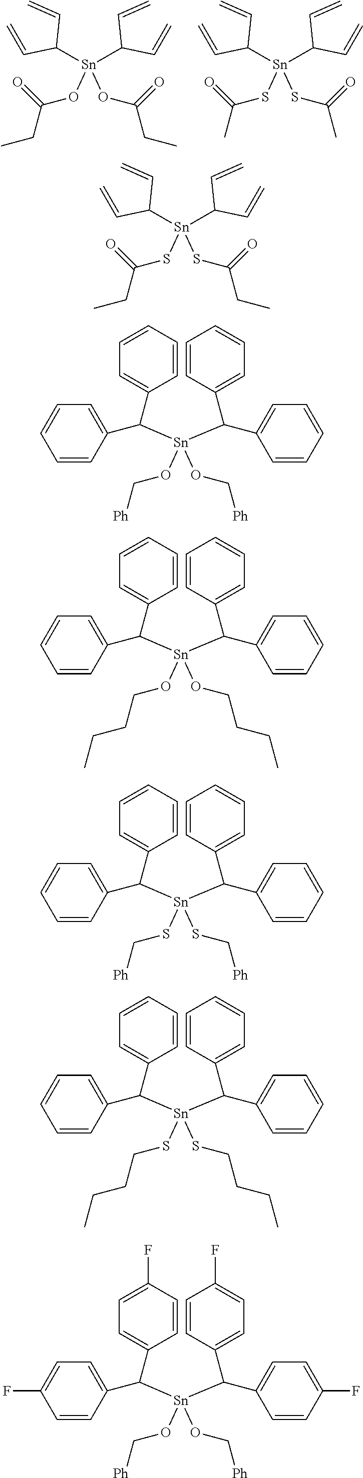 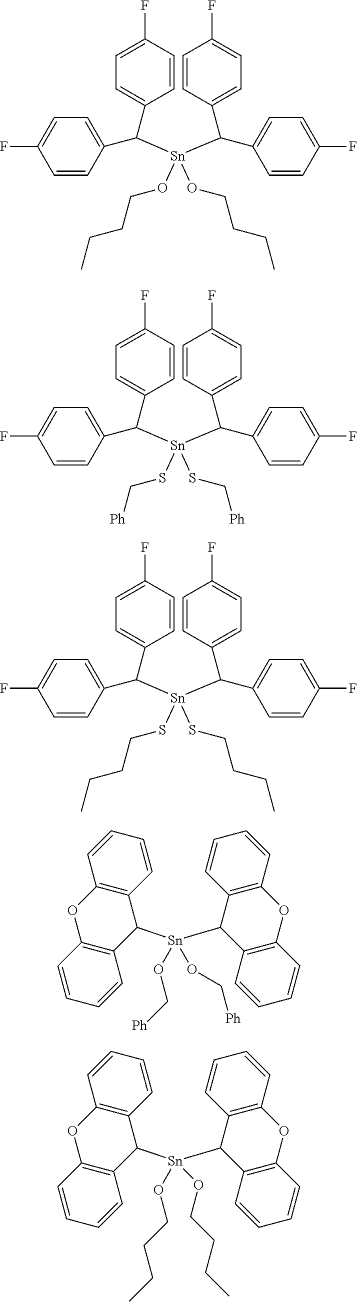 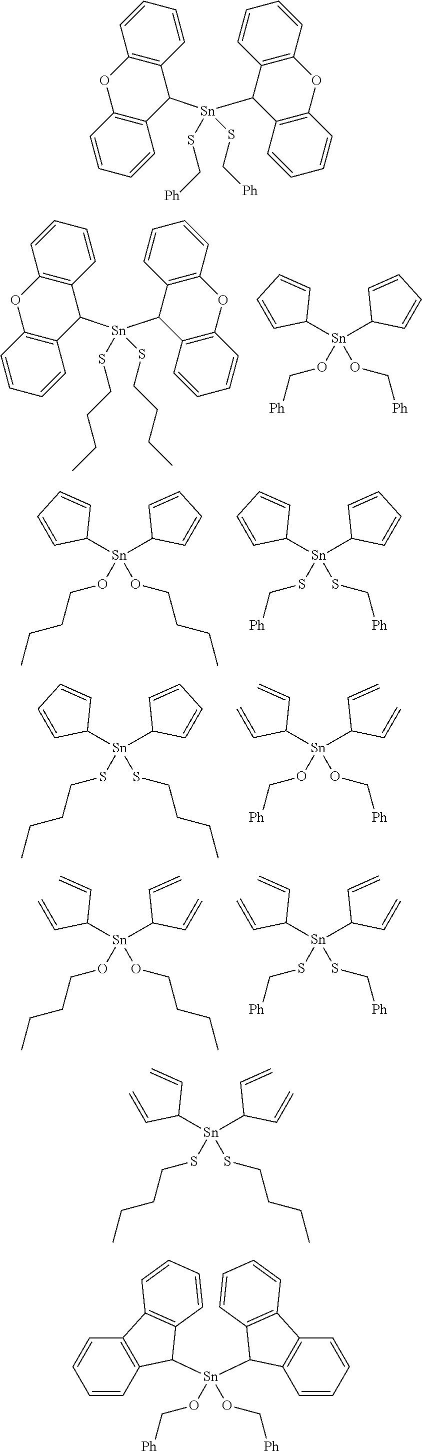 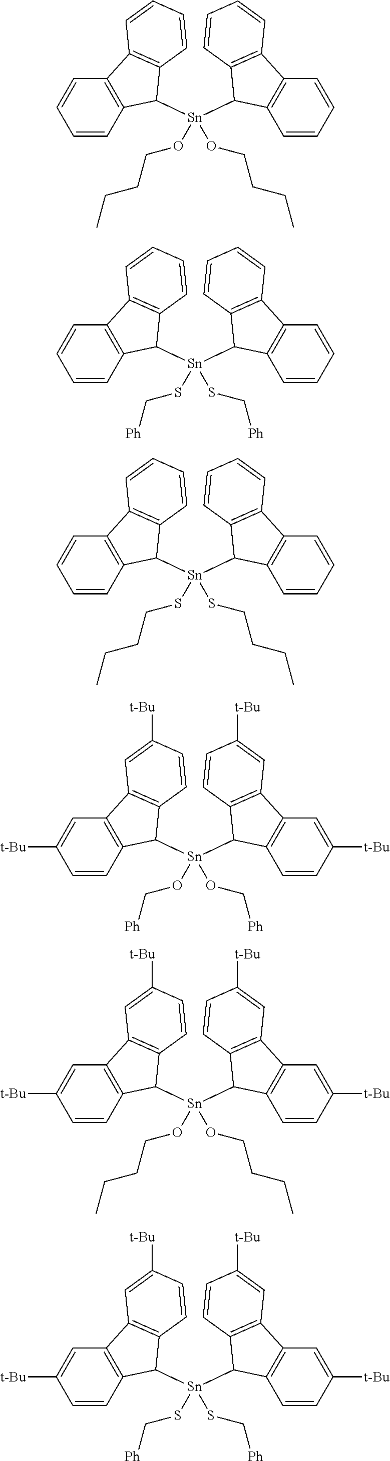 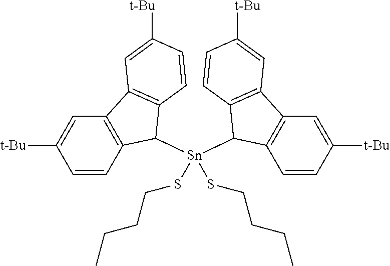 [SMILES: CCCC[S][Sn]([S]CCCC)([CH]1c2ccc(C(C)(C)C)cc2-c2cc(C(C)(C)C)ccc21)[CH]1c2ccc(C(C)(C)C)cc2-c2cc(C(C)(C)C)ccc21]
wherein n in Group I is an integer from 0 to 3.

6. The resist composition of claim 1, wherein, in Formula 2,
X₂ is OH or C(═O)OH.

7. The resist composition of claim 1, wherein, in Formula 2,
(L₂)ₐ₂ is represented by any one of Formulae 5-1 to 5-7: 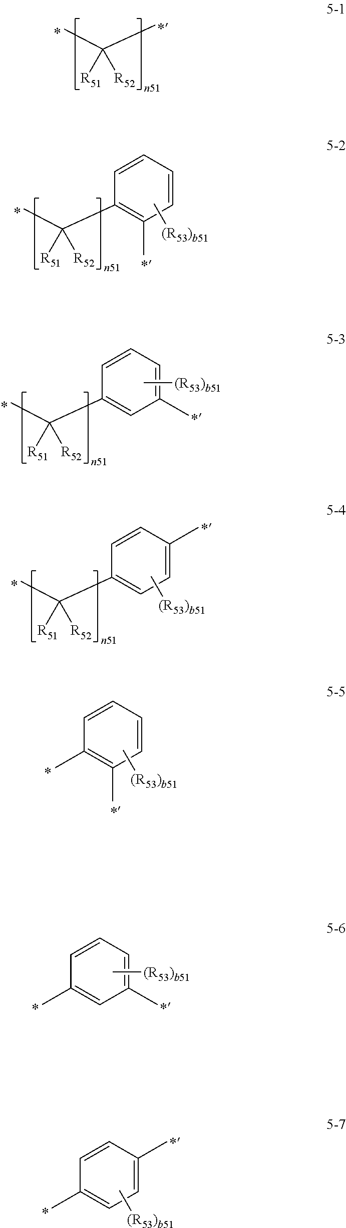
wherein, in Formulae 5-1 to 5-7,
R₅₁ to R₅₃ are each independently hydrogen, deuterium, a halogen, a hydroxyl group, a cyano group, a C₁-C₄ alkyl group, or a C₁-C₄ halogenated alkyl group,
b51 is an integer from 1 to 4,
n51 is an integer from 1 to 4, and
* and *′ each indicate a binding site to a neighboring atom of Formula 2.

8. The resist composition of claim 1, wherein, in Formula 2,
Y₂ is OC(═O), C(═O)O, OS(═O)₂, or S(═O)₂O,
Z₂ is *—C(R₂)(R₃)(R₄), *—C(R₂)═N(R₃), *—N═C(R₂)(R₃), or *—N(R₂)(R₃),
R₂ to R₄ are each independently hydrogen, deuterium, a halogen, a cyano group, a nitro group, a hydroxyl group, —C(═O)R₅, —C(R₅)=NR₆, —ORS, —S(═O)R₅, —S(═O)₂R₅, —S(═O)₂OR₅, a substituted or unsubstituted C₁-C₃₀ alkyl group, a substituted or unsubstituted C₁-C₃₀ halogenated alkyl group, a substituted or unsubstituted C₁-C₃₀ alkoxy group, a substituted or unsubstituted C₁-C₃₀ alkylthio group, a substituted or unsubstituted C₁-C₃₀ halogenated alkoxy group, a substituted or unsubstituted C₁-C₃₀ halogenated alkylthio group, a substituted or unsubstituted C₃-C₃₀ cycloalkyl group, a substituted or unsubstituted C₃-C₃₀ cycloalkoxy group, a substituted or unsubstituted C₃-C₃₀ cycloalkylthio group, a substituted or unsubstituted C₃-C₃₀ heterocycloalkyl group, a substituted or unsubstituted C₃-C₃₀ heterocycloalkoxy group, a substituted or unsubstituted C₃-C₃₀ heterocycloalkylthio group, a substituted or unsubstituted C₂-C₃₀ alkenyl group, a substituted or unsubstituted C₂-C₃₀ alkenyloxy group, a substituted or unsubstituted C₂-C₃₀ alkenylthio group, a substituted or unsubstituted C₃-C₃₀ cycloalkenyl group, a substituted or unsubstituted C₃-C₃₀ cycloalkenyloxy group, a substituted or unsubstituted C₃-C₃₀ cycloalkenylthio group, a substituted or unsubstituted C₃-C₃₀ heterocycloalkenyl group, a substituted or unsubstituted C₃-C₃₀ heterocycloalkenyloxy group, a substituted or unsubstituted C₃-C₃₀ heterocycloalkenylthio group, a substituted or unsubstituted C₂-C₃₀ alkynyl group, a substituted or unsubstituted C₂-C₃₀ alkynyloxy group, a substituted or unsubstituted C₂-C₃₀ alkynylthio group, a substituted or unsubstituted C₆-C₃₀ aryl group, a substituted or unsubstituted C₆-C₃₀ aryloxy group, a substituted or unsubstituted C₆-C₃₀ arylthio group, a substituted or unsubstituted C₁-C₃₀ heteroaryl group, a substituted or unsubstituted C₁-C₃₀ heteroaryloxy group, or a substituted or unsubstituted C₁-C₃₀ heteroarylthio group,
R₅ and R₆ are each independently hydrogen, deuterium, a hydroxyl group, a substituted or unsubstituted C₁-C₃₀ alkyl group, a substituted or unsubstituted C₁-C₃₀ halogenated alkyl group, a substituted or unsubstituted C₁-C₃₀ alkoxy group, a substituted or unsubstituted C₁-C₃₀ alkylthio group, a substituted or unsubstituted C₁-C₃₀ halogenated alkoxy group, a substituted or unsubstituted C₁-C₃₀ halogenated alkylthio group, a substituted or unsubstituted C₃-C₃₀ cycloalkyl group, a substituted or unsubstituted C₃-C₃₀ cycloalkoxy group, a substituted or unsubstituted C₃-C₃₀ cycloalkylthio group, a substituted or unsubstituted C₃-C₃₀ heterocycloalkyl group, a substituted or unsubstituted C₃-C₃₀ heterocycloalkoxy group, a substituted or unsubstituted C₃-C₃₀ heterocycloalkylthio group, substituted or unsubstituted C₂-C₃₀ alkenyl group, a substituted or unsubstituted C₂-C₃₀ alkenyloxy group, a substituted or unsubstituted C₂-C₃₀ alkenylthio group, a substituted or unsubstituted C₃-C₃₀ cycloalkenyl group, a substituted or unsubstituted C₃-C₃₀ cycloalkenyloxy group, a substituted or unsubstituted C₃-C₃₀ cycloalkenylthio group, a substituted or unsubstituted C₃-C₃₀ heterocycloalkenyl group, a substituted or unsubstituted C₃-C₃₀ heterocycloalkenyloxy group, a substituted or unsubstituted C₃-C₃₀ heterocycloalkenylthio group, a substituted or unsubstituted C₂-C₃₀ alkynyl group, a substituted or unsubstituted C₂-C₃₀ alkynyloxy group, a substituted or unsubstituted C₂-C₃₀ alkynylthio group, a substituted or unsubstituted C₆-C₃₀ aryl group, a substituted or unsubstituted C₆-C₃₀ aryloxy group, a substituted or unsubstituted C₆-C₃₀ arylthio group, a substituted or unsubstituted C₁-C₃₀ heteroaryl group, a substituted or unsubstituted C₁-C₃₀ heteroaryloxy group, or a substituted or unsubstituted C₁-C₃₀ heteroarylthio group, and
* is a bonding site to a neighboring atom of Formula 2.

9. The resist composition of claim 1, wherein
The additive represented by Formula 2 is selected from Group II: 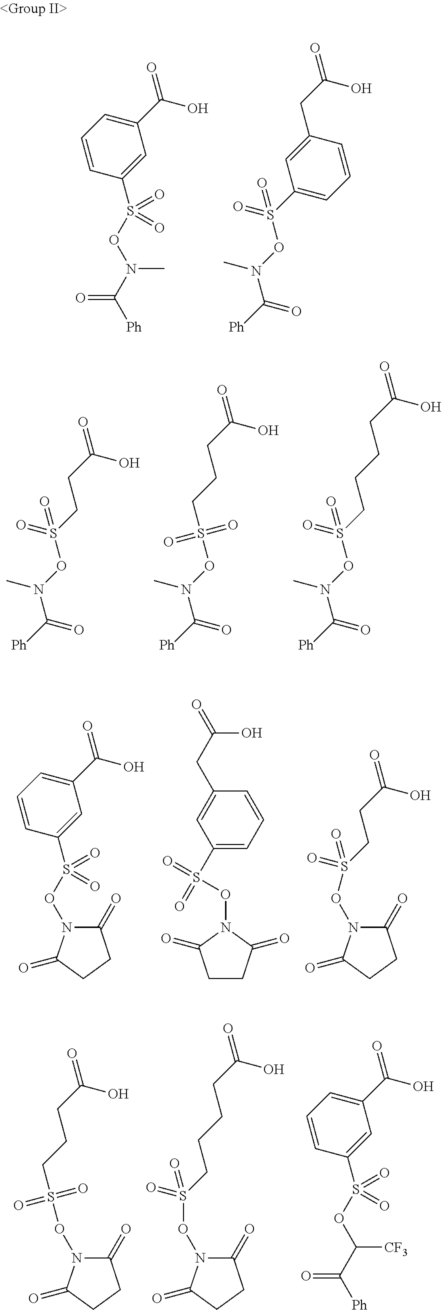 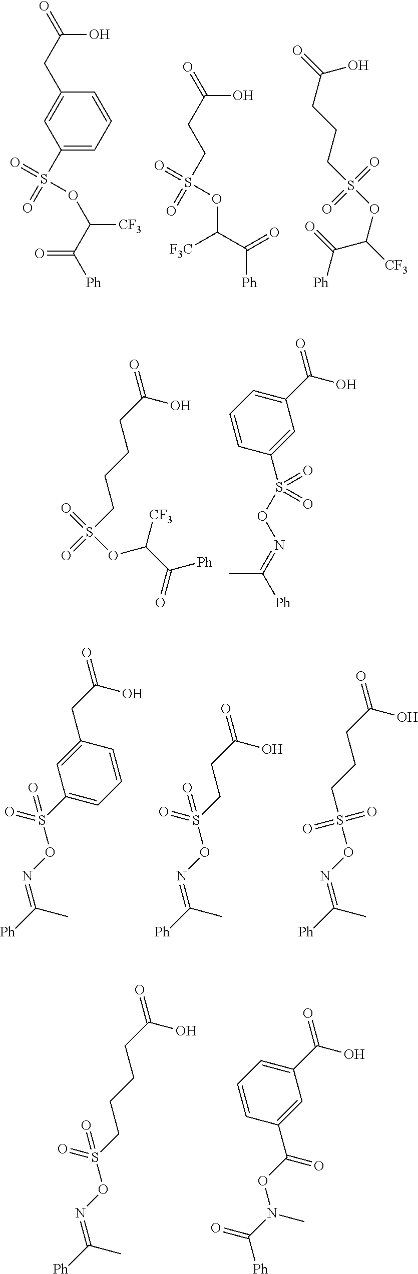 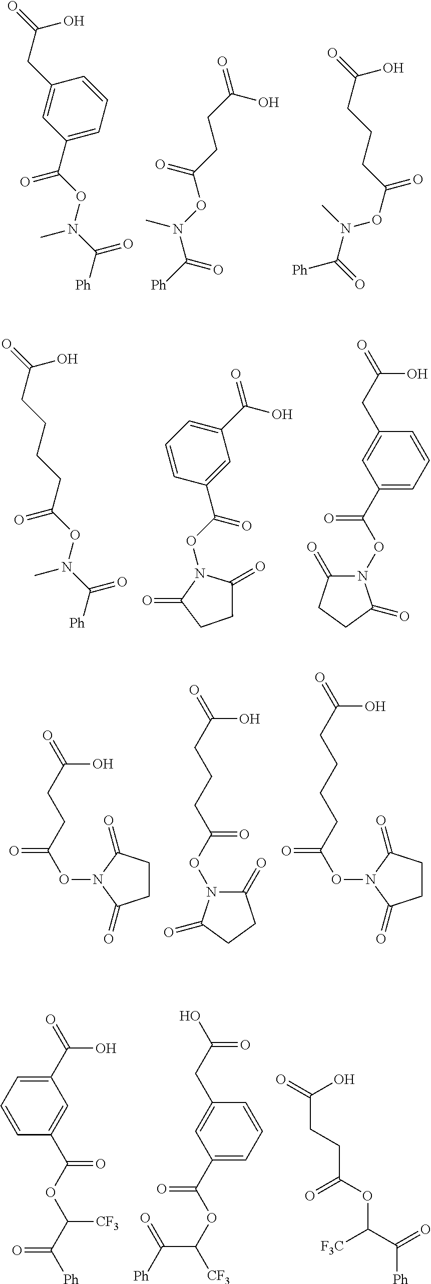 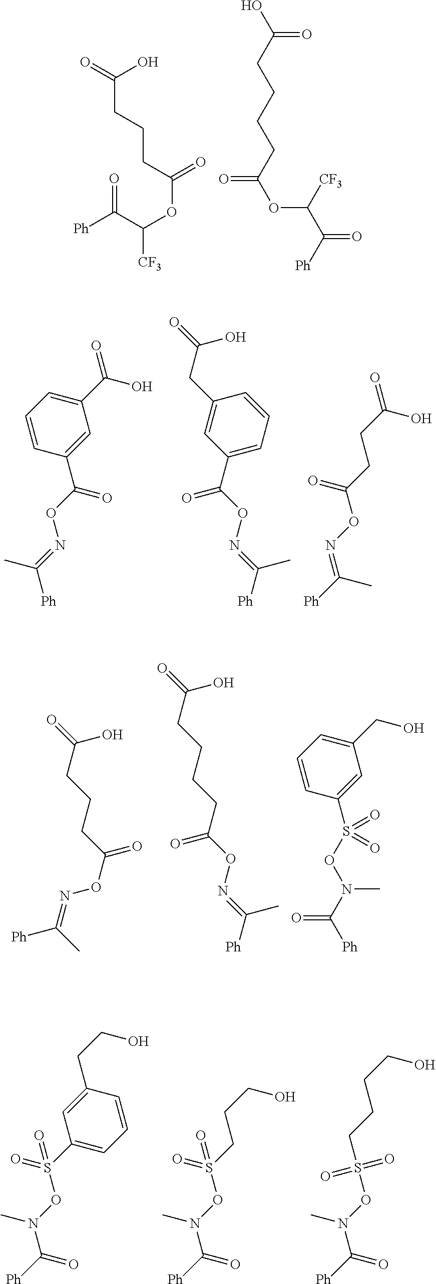 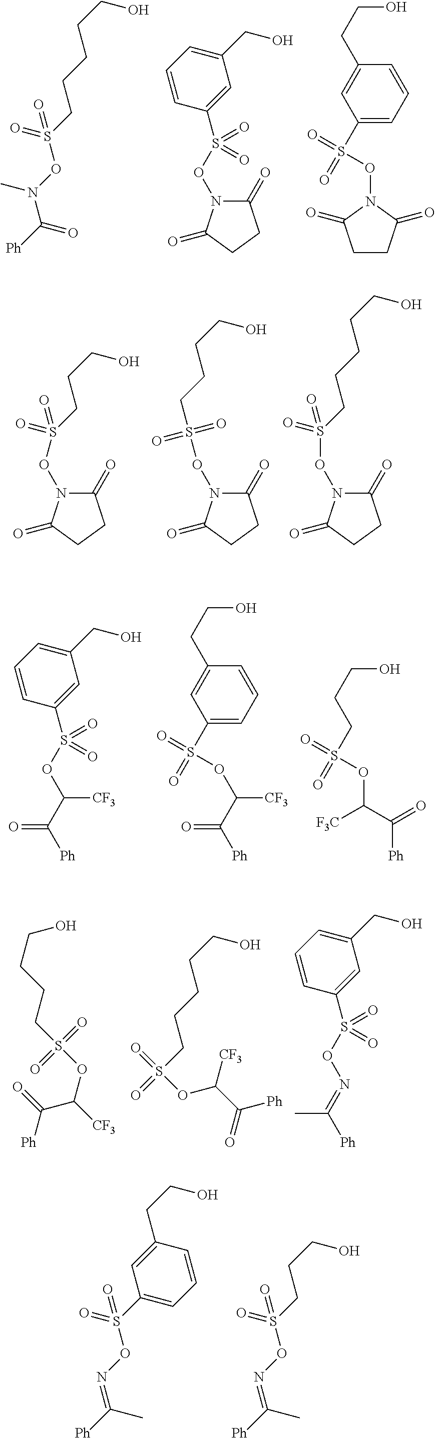 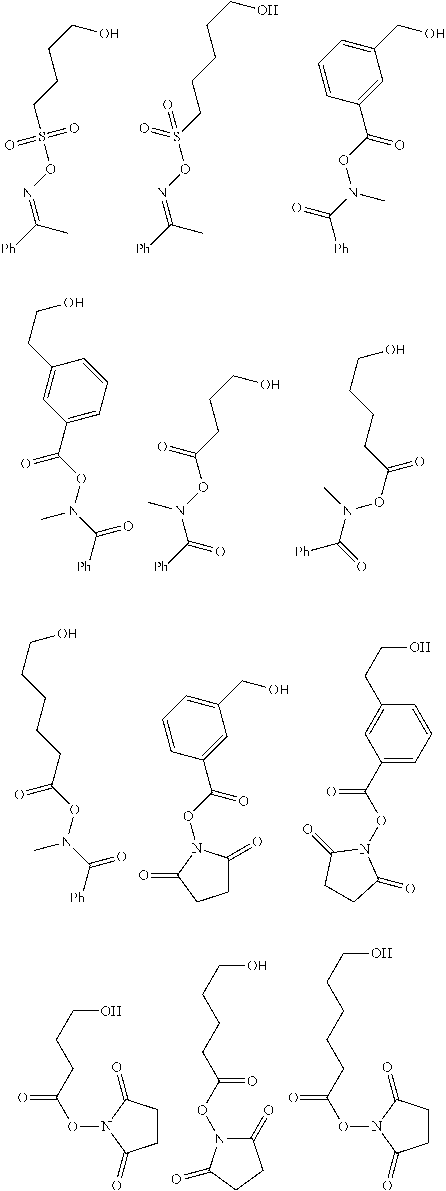 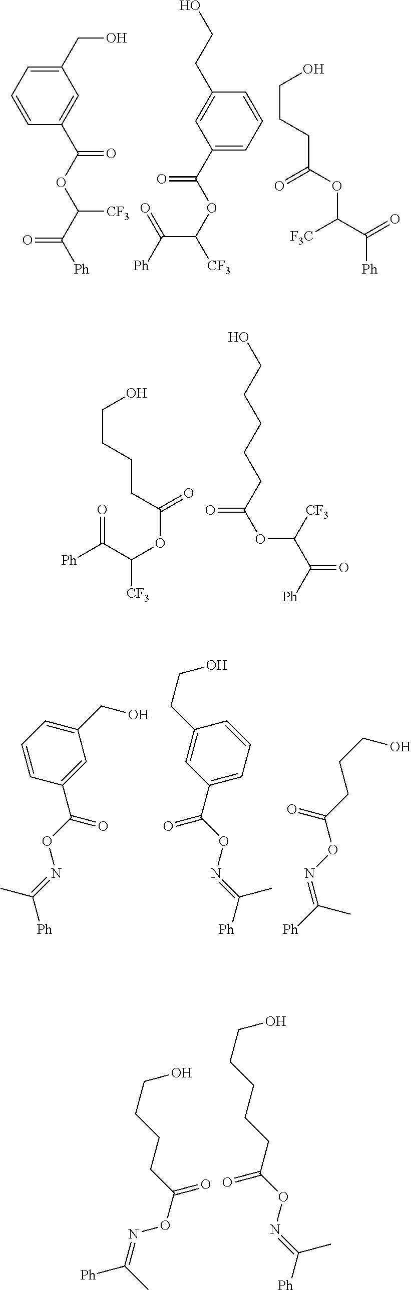
wherein Ph in Group II is a phenyl group.

10. The resist composition of claim 1, wherein
the additive is included in the resist composition in an amount of about 0.1 parts by weight to about 100,000 parts by weight, based on 100 parts by weight of the organometallic compound.

11. The resist composition of claim 1, further comprising:
a solvent.

12. The resist composition of claim 11, wherein
the solvent is a polar aprotic solvent.

13. The resist composition of claim 11, wherein
the solvent is selected from ketone-based solvents, ester-based solvents, and any combination thereof.

14. The resist composition of claim 11, wherein
the solvent is selected from linear ketone solvents, cyclic ketone solvents, polyhydric alcohol-containing ethercarboxylate solvents, lactone solvents, acetate ester solvents, and any combination thereof.

15. The resist composition of claim 11, wherein
the solvent is methyl ethyl ketone, cyclopentanone, cyclohexanone, cycloheptanone, propylene glycol monomethyl ether acetate, γ-butyrolactone, b-valerolactone, n-butyl acetate, or any combination thereof.

16. A pattern formation method comprising:
forming a resist film by applying the resist composition of claim 1 onto a substrate;
exposing at least a portion of the resist film to high-energy rays to form an exposed resist film; and
developing the exposed resist film based on using a developer.

17. The pattern formation method of claim 16, wherein
the exposing is performed based on irradiating at least one of ultraviolet rays, deep ultraviolet rays (DUV), extreme ultraviolet rays (EUV), X-rays, γ-rays, electron beams (EBs), or α-rays.

18. The pattern formation method of claim 16, wherein
based on the exposing at least the portion of the resist film, the exposed resist film includes an exposed portion and an unexposed portion, and
a difference between a water contact angle of the unexposed portion and a water contact angle of the exposed portion is 25° or more.

19. The pattern formation method of claim 16, wherein
based on the exposing at least the portion of the resist film, the exposed resist film includes an exposed portion and an unexposed portion,
the developer comprises distilled water, an alkaline developer, or any combination thereof, and
the developing the exposed resist film includes removing the exposed portion.

20. The pattern formation method of claim 16, wherein
based on the exposing at least the portion of the resist film, the exposed resist film includes an exposed portion and an unexposed portion,
the developer comprises an organic solvent, and
the developing the exposed resist film includes removing the unexposed portion.
